(19) United States
(12) Patent Application Publication
(10) Pub. No.: US 2024/0099043 A1
(43) Pub. Date: Mar. 21, 2024

(54) QLED AND PREPARATION METHOD THEREOF

(71) Applicant: TCL TECHNOLOGY GROUP CORPORATION, Huizhou (CN)

(72) Inventors: Longjia WU, Huizhou (CN); Tianshuo ZHANG, Huizhou (CN); Junjie LI, Huizhou (CN); Yulin GUO, Huizhou (CN); Kai TONG, Huizhou (CN)

(21) Appl. No.: 18/270,628

(22) PCT Filed: Dec. 30, 2021
(86) PCT No.: PCT/CN2021/143435

§ 371 Date: Jun. 30, 2023

(30) Foreign Application Priority Data
Dec. 31, 2020 (CN) 202011637282.8
Dec. 31, 2020 (CN) 202011637666.X
Dec. 31, 2020 (CN) 202011640040.4
Dec. 31, 2020 (CN) 202011640071.X
Dec. 31, 2020 (CN) 202011640399.1
Dec. 31, 2020 (CN) 202011642134.5

(51) Int. Cl. H10K 50/115; H10K 50/16; H10K 71/00

(52) U.S. Cl. CPC H10K 50/115; H10K 50/166; H10K 71/00

(57) ABSTRACT

The present disclosure provides a quantum dot light-emitting diode (QLED) and a preparation method thereof. The QLED includes an anode and a cathode that are oppositely arranged, a quantum dot luminescent layer arranged between the anode and the cathode, and an electron transport layer (ETL) arranged between the quantum dot luminescent layer and the cathode. The ETL includes a first ETL, and the first ETL is a zinc oxide film with a surface hydroxyl content of less than or equal to 0.4. Alternatively, the ETL includes zinc oxide, and at least a part of a surface of the zinc oxide includes an amino ligand and/or a carboxyl ligand with 3 to 7 carbon atoms. In the present application, the QLED improves a service life of a QLED-based device effectively.

### CROSS REFERENCE TO RELATED APPLICATIONS

The present application is a 35 U.S.C. § 371 national stage application of PCT patent application No. PCT/CN2021/143435, filed on Dec. 30, 2021, which claims priority to the Chinese Patent Application No. 202011640071.X, filed with the China National Intellectual Property Administration (CNIPA) on Dec. 31, 2020, and entitled “QUANTUM DOT LIGHT-EMITTING DIODE (QLED) AND PREPARATION METHOD THEREOF”, claims priority to the Chinese Patent Application No. 202011637282.8, filed with the CNIPA on Dec. 31, 2020, and entitled “PREPARATION METHOD OF QUANTUM DOT LIGHT-EMITTING DIODE (QLED)”, claims priority to the Chinese Patent Application No. 202011637666.X, filed with the CNIPA on Dec. 31, 2020, and entitled “PREPARATION METHOD OF QUANTUM DOT LIGHT-EMITTING DIODE (QLED)”, claims priority to the Chinese Patent Application No. 202011642134.5, filed with the CNIPA on Dec. 31, 2020, and entitled “PREPARATION METHOD OF QUANTUM DOT LIGHT-EMITTING DIODE (QLED)”, claims priority to the Chinese Patent Application No. 202011640399.1, filed with the CNIPA on Dec. 31, 2020, and entitled “QUANTUM DOT LIGHT-EMITTING DIODE (QLED) AND PREPARATION METHOD THEREOF”, and claims priority to the Chinese Patent Application No. 202011640040.4, filed with the CNIPA on Dec. 31, 2020, and entitled “PREPARATION METHOD OF QUANTUM DOT LIGHT-EMITTING DIODE (QLED)”, which are incorporated herein by reference in their entirety.

### FIELD

The present disclosure relates to the field of display technology, in particular to a quantum dot light-emitting diode (QLED) and a preparation method thereof.

### DESCRIPTION OF RELATED ART

Quantum dots (QDs) are a class of nanomaterials composed of a small number of atoms. QDs have radii that are generally smaller than or adjacent to the exciton Bohr radius, exhibit significant quantum confinement effects, and have unique optical properties. Recently, with the continuous development of display technology, quantum dot light-emitting diodes (QLEDs) using QD materials as a luminescent layer have attracted more and more attentions. The QLED has high luminous efficiency, controllable luminous color, excellent color purity, and desirable device stability, and can be used for flexible applications. Therefore, the QLED illustrates great application prospects in the fields of display technology, solid-state lighting and the like.

A QLED mainly includes a cathode, an anode, and a quantum dot luminescent layer. In order to improve performances of the device, one or more of a hole injection layer (HIL), a hole transport layer (HTL), an electron transport layer (ETL), and an electron injection layer (EIL) may further be introduced into the QLED as a functional layer on this basis. Zinc oxide (ZnO) is a commonly used ETL material in QLEDs. The ZnO has a desirable energy level matching relationship with the cathode and the quantum dot luminescent layer, thus significantly reducing an injection barrier of electrons from the cathode to the quantum dot luminescent layer. Moreover, the ZnO has a deep valence-band energy level and can effectively block holes. In addition, ZnO materials also have excellent electron transport capabilities with an electron mobility of as high as 10⁻³ cm²/V·S. Due to these characteristics, ZnO materials have become the first choice for ETL in QLED-based devices to significantly improve the stability and luminous efficiency of such devices.

QLED display technology is similar to organic light-emitting diode (OLED) display technology in luminescence principle. Accordingly, the interpretation of device physics as well as the selection and matching principles for energy levels of functional layer materials in QLED devices are currently in accordance with the existing theoretical systems in OLEDs. For example, in order to obtain a higher device performance in OLED devices, it is necessary to fine-tune the carrier injection of holes and electrons on both sides of the OLED devices to achieve a balance of carrier injection in the luminescent layer of the device. When applying the classical physical conclusions of OLED devices to a QLED device system, it is considered that an electron mobility of the ZnO layer is generally higher than a hole mobility of the HTL. As a result, in order to achieve a better carrier injection balance in QLED devices, it is necessary to reduce the electron mobility of the ZnO layer by inserting an electron blocking layer (EBL) between the quantum dot luminescent layer and the ZnO layer. When the aforesaid technical means are applied to the QLED device, the performances of QLED devices, especially an efficiency of QLED devices, have indeed been significantly improved. An external quantum efficiency (EQE) of QLED devices reaches more than 20% by the above method, and is adjacent to an upper limit of theoretical value.

However, problems have been encountered in the process of trying to improve and enhance another key performance (i.e., device service life) of QLED devices, with the above strategies. The classic ideas and strategies formed in OLED are not prone to effectively improve the service life of QLED devices currently. Moreover, although high efficiency of QLED devices has been obtained through classical ideas and strategies, it is generally found that the device service life of these high-efficiency QLED devices is significantly worse than that of similar devices with lower efficiency. Moreover, the research on a mechanism of QLED devices is gradually conducted and deepened. It is found that in the QLED device system, due to the use of nanomaterials with special material surfaces, such as QDs and ZnO nanoparticles, the QLED has some special mechanisms different from those of the OLED device system. These mechanisms are closely related to the performances of QLED devices, especially the device service life. In view of this, the existing QLED device structure designed based on the OLED device theory system cannot meet the requirements in improving the performance of QLED devices, especially the device life. Corresponding to the unique device mechanism of the QLED device system, it is necessary to develop a new and more targeted new QLED device structure.

### SUMMARY

One of the objectives of the embodiments of the present disclosure is to provide a QLED and a preparation method thereof.

The embodiments of the present disclosure adopt the following technical solutions.

In a first aspect, a quantum dot light-emitting diode (QLED) is provided, the QLED includes an anode and a cathode that are oppositely arranged, a quantum dot luminescent layer arranged between the anode and the cathode, and an electron transport layer (ETL) arranged between the quantum dot luminescent layer and the cathode; where
the ETL includes a first ETL, and the first ETL is a zinc oxide film with a surface hydroxyl content of less than or equal to 0.4; alternatively,
the ETL includes zinc oxide, and at least a part of a surface of the zinc oxide includes an amino ligand and/or a carboxyl ligand with 3 to 7 carbon atoms.

In some embodiments, the ETL includes the first ETL having the zinc oxide, and a surface of the zinc oxide forming the first ETL includes the amino ligands and/or the carboxyl ligands with 3 to 7 carbon atoms.

In some embodiments, the ETL is the first ETL, and the zinc oxide in the first ETL is metal-doped or metal-undoped zinc oxide.

In some embodiments, the ETL further includes a second ETL; the second ETL is arranged on a surface of one side of the first ETL adjacent to the cathode or the quantum dot luminescent layer; and the second ETL is a zinc oxide film or a metal-doped zinc oxide layer with a surface hydroxyl content of greater than or equal to 0.6.

In some embodiments, the ETL includes the first ETL and the second ETL, and the first ETL is closer to the quantum dot luminescent layer than the second ETL.

In some embodiments, the ETL includes n film lamination units, each of the film lamination units includes the first ETL and the second ETL, and n is greater than or equal to 2.

In some embodiments, the ETL further includes a third ETL.

In some embodiments, the third ETL is the zinc oxide film with the surface hydroxyl content of less than or equal to 0.4; alternatively, the third ETL is the zinc oxide film with the surface containing the amino ligands and/or the carboxyl ligands with 3 to 7 carbon atoms.

In some embodiments, the third ETL is arranged on the surface of one side of the second ETL facing away from the first ETL, and the second ETL is a zinc oxide film with a surface hydroxyl content of greater than or equal to 0.6.

In some embodiments, the third ETL is arranged on the surface of one side of the second ETL facing away from the first ETL, and the second ETL is a metal-doped zinc oxide film.

In some embodiments, the second ETL is a zinc oxide film with a surface hydroxyl content of greater than or equal to 0.6, the third ETL is a zinc oxide film with a surface hydroxyl content of less than or equal to 0.4, and the third ETL is arranged on the surface of one side of the second ETL facing away from the first ETL.

In some embodiments, the second ETL is a metal-doped zinc oxide film, the third ETL is a zinc oxide film with a surface hydroxyl content of less than or equal to 0.4, and the third ETL is arranged on the surface of one side of the second ETL facing away from the first ETL.

In some embodiments, the second ETL is a zinc oxide film with a surface hydroxyl content of greater than or equal to 0.6, the third ETL is the zinc oxide film with the surface containing the amino ligands and/or the carboxyl ligands with 3 to 7 carbon atoms, and the third ETL is arranged on the surface of one side of the second ETL facing away from the first ETL.

In some embodiments, the second ETL is a metal-doped zinc oxide film, the third ETL is the zinc oxide film with the surface containing the amino ligands and/or the carboxyl ligands with 3 to 7 carbon atoms, and the third ETL is arranged on the surface of one side of the second ETL facing away from the first ETL.

In some embodiments, the third ETL is a zinc oxide film with a surface hydroxyl content of greater than or equal to 0.6.

In some embodiments, the second ETL is a zinc oxide film with a surface hydroxyl content of greater than or equal to 0.6, and the third ETL is arranged on a surface of one side of the first ETL facing away from the second ETL.

In some embodiments, the second ETL is a metal-doped zinc oxide film, and the third ETL is arranged on a surface of one side of the first ETL facing away from the second ETL.

In some embodiments, the second ETL is a metal-doped zinc oxide film, and the third ETL is arranged on the surface of one side of the second ETL facing away from the first ETL.

In some embodiments, the third ETL is a metal-doped zinc oxide film.

In some embodiments, the second ETL is a zinc oxide film with a surface hydroxyl content of greater than or equal to 0.6, and the third ETL is arranged on a surface of one side of the first ETL facing away from the second ETL.
the second ETL is a metal-doped zinc oxide film, and the third ETL is arranged on a surface of one side of the first ETL away from the second ETL.

In some embodiments, the amino ligands and/or the carboxyl ligands with 3 to 7 carbon atoms is selected from at least one of propionic acid, propylamine, butyric acid, butylamine, hexanoic acid, and hexylamine.

In some embodiments, the amino ligands and/or the carboxyl ligands with 3 to 7 carbon atoms and the zinc oxide are at a molar ratio of 1:4 to 4:1 in the zinc oxide film with the surface containing the amino ligands and/or the carboxyl ligands with 3 to 7 carbon atoms.

In some embodiments, the ETL has a thickness of 10 nm to 100 nm.

In some embodiments, the zinc oxide film with the surface hydroxyl content of less than or equal to 0.4 has a thickness of 20 nm to 60 nm.

In some embodiments, the first ETL has a thickness of 10 nm to 80 nm.

In some embodiments, the second ETL has a thickness of 10 nm to 30 nm.

In some embodiments, the zinc oxide film with a surface hydroxyl content of greater than or equal to 0.6 has a thickness of 10 nm to 30 nm.

In some embodiments, the metal-doped zinc oxide film has a thickness of 10 nm to 30 nm.

In some embodiments, a quantum dot in the quantum dot luminescent layer is selected from the group consisting of a single-core quantum dot and a core-shell quantum dot; and a core compound and a shell compound of the quantum dot are each independently selected from at least one of CdS, CdSe, CdTe, ZnO, ZnS, ZnSe, ZnTe, GaAs, GaP, GaSb, HgS, HgSe, HgTe, InAs, InP, InSb, AlAs, AlP, CuInS, and CuInSe, and a core-shell quantum dot or an alloy quantum dot formed by the above substances; and/or
in some embodiments, a material of the anode is selected from at least one of zinc oxide, indium oxide, tin oxide, indium tin oxide, indium zinc oxide, and fluorine-doped tin oxide.

In some embodiments, a material of the cathode is selected from the group consisting of Ag, Al, Au, Mg, Ca, Yb, and Ba, and an alloy thereof.

In some embodiments, the quantum dot light-emitting diode further includes a hole functional layer arranged in the anode and the quantum dot luminescent layer, and the hole functional layer at least includes at least one of a hole injection layer (HIL) and a hole transport layer (HTL).

In some embodiments, a material of the HIL is selected from at least one of poly(3, 4-ethylenedioxythiophene):poly(styrene sulfonate) (PEDOT:PSS), HTL-1, and HTL-2.

In some embodiments, a material of the HTL is selected from at least one of 4,4′-N,N′-dicarbazolyl-biphenyl, poly[(9, 9′-dioctylfluorene-2, 7-diyl)-co-(4, 4′-(N-(4-sec-butylphenyl)diphenylamine))], poly(4-butylphenyl-diphenylamine), 4, 4′, 4′-tris(N-carbazolyl)-triphenylamine, and poly(N-vinylcarbazole), and a derivative thereof.

In some embodiments, a material of the HIL is selected from at least one of poly(3, 4-ethylenedioxythiophene):poly(styrene sulfonate) (PEDOT:PSS), HTL-1, and HTL-2. A material of the HTL is selected from at least one of 4, 4′-N, N′-dicarbazolyl-biphenyl, poly[(9, 9′-dioctylfluorene-2, 7-diyl)-co-(4, 4′-(N-(4-sec-butylphenyl)diphenylamine))], poly(4-butylphenyl-diphenylamine), 4, 4′, 4′-tris(N-carbazolyl)-triphenylamine, and poly(N-vinylcarbazole), and a derivative thereof.

In some embodiments, a doping metal in the metal-doped zinc oxide film is selected from at least one of Mg²⁺ and Mn²⁺.

In some embodiments, the doping metal in the metal-doped zinc oxide film is selected from at least one of Al³⁺, Y³⁺, La³⁺, Li⁺, Gd³⁺, Zr⁴⁺, and Ce⁴⁺.

In some embodiments, the doping metal has a doping content as follows:
when the doping metal is the Mg²⁺, the Mg²⁺ has a doping molar concentration of 0.1% to 35% in the metal-doped zinc oxide film;
when the doping metal is the Mn²⁺, the Mn²⁺ has a doping molar concentration of 0.1% to 30% in the metal-doped zinc oxide film;
when the doping metal is the Al³⁺, the Al³⁺ has a doping molar concentration of 0.1% to 15% in the metal-doped zinc oxide film;
when the doping metal is the Y³⁺, the Y³⁺ has a doping molar concentration of 0.10% to 10% in the metal-doped zinc oxide film;
when the doping metal is the La³⁺, the La³⁺ has a doping molar concentration of 0.1% to 7% in the metal-doped zinc oxide film;
when the doping metal is the Li⁺, the Li⁺ has a doping molar concentration of 0.10% to 45% in the metal-doped zinc oxide film;
when the doping metal is the Gd³⁺, the Gd³⁺ has a doping molar concentration of 0.01% to 8% in the metal-doped zinc oxide film;
when the doping metal is the Zr⁴⁺, the Zr⁴⁺ has a doping molar concentration of 0.1% to 45% in the metal-doped zinc oxide film; and
when the doping metal is the Ce⁴⁺, the Ce⁴⁺ has a doping molar concentration of 0.1% to 10% in the metal-doped zinc oxide film.

In a second aspect, preparation methods of a QLED are provided.

A first preparation method of a QLED is provided, where the QLED includes an anode and a cathode that are oppositely arranged, a quantum dot luminescent layer arranged between the anode and the cathode, and an ETL arranged between the quantum dot luminescent layer and the cathode; the ETL includes a first ETL, and the first ETL is a zinc oxide film with a surface hydroxyl content of less than or equal to 0.4; and
a preparation method of the zinc oxide film with the surface hydroxyl content of less than or equal to 0.4 includes the following steps:
mixing a zinc salt solution with a alkaline solution for a reaction, adding a precipitant into a mixed solution after the reaction, and collecting a precipitate; cleaning the precipitate using a reaction solvent twice or more than twice, and dissolving an obtained white precipitate to obtain a zinc oxide colloidal solution; and
coating the zinc oxide colloidal solution on a prefabricated substrate for preparing the zinc oxide film with the surface hydroxyl content of less than or equal to 0.4, and removing the reaction solvent to obtain the zinc oxide film with the surface hydroxyl content of less than or equal to 0.4.

In some embodiments, an alkali in the alkaline solution has a K_{b} value of greater than 10⁻¹, and the cleaning is conducted at least 3 times; alternatively,
the alkali in the alkaline solution has a K_{b} value of less than 10⁻¹, and the cleaning is conducted at least 2 times.

In some embodiments, the alkali having a K_{b} value of greater than 10⁻¹ is selected from at least one of potassium hydroxide, sodium hydroxide, and lithium hydroxide; and the alkali having a K_{b} value of less than 10⁻¹ is selected from at least one of tetramethylammonium hydroxide (TMAH), ammonia water, ethanolamine, and ethylenediamine.

In some embodiments, the reaction solvent is selected from at least one of water, an organic alcohol, an organic ether, and a sulfone.

In some embodiments, the reaction solvent is selected from at least one of water, methanol, ethanol, propanol, butanol, ethylene glycol, 2-methoxyethanol, and dimethylsulfoxide (DMSO).

In some embodiments, the zinc salt solution is mixed with the alkaline solution according to a molar ratio of hydroxide ions to zinc ions ranging from 1.5:1 to 2.5:1.

In some embodiments, the zinc oxide film with the surface hydroxyl content of less than or equal to 0.4 is a metal-doped zinc oxide film, and the zinc salt solution includes a doping metal ion.

In some embodiments, the doping metal ion is selected from at least one of Mg²⁺ and Mn²⁺; alternatively,
the doping metal ion is selected from at least one of Al³⁺, Y³⁺, La³⁺, Li⁺, Gd³⁺, Zr⁴⁺, and Ce⁴⁺.

In some embodiments, the doping metal has a doping content as follows:
when the doping metal ion is the Mg²⁺, a molar content of the Mg²⁺ takes a proportion of 0.1% to 35% of a total molar weight of metal ions in the zinc salt solution;
when the doping metal ion is the Mn²⁺, a molar content of the Mn²⁺ takes a proportion of 0.1% to 30% of a total molar weight of metal ions in the zinc salt solution;
when the doping metal ion is the Al³⁺, a molar content of the Al³⁺ takes a proportion of 0.1% to 15% of a total molar weight of metal ions in the zinc salt solution;
when the doping metal ion is the Y³⁺, a molar content of the Y^{3′} takes a proportion of 0.10% to 10% of a total molar weight of metal ions in the zinc salt solution;
when the doping metal ion is the La³⁺, a molar content of the La³⁺ takes a proportion of 0.1% to 7% of a total molar weight of metal ions in the zinc salt solution;
when the doping metal ion is the Li⁺, a molar content of the Li⁺ takes a proportion of 0.10% to 45% of a total molar weight of metal ions in the zinc salt solution;
when the doping metal ion is the Gd³⁺, a molar content of the Gd³⁺ takes a proportion of 0.010% to 8% of a total molar weight of metal ions in the zinc salt solution;
when the doping metal ion is the Zr⁴⁺, a molar content of the Zr⁴⁺ takes a proportion of 0.1% to 45% of a total molar weight of metal ions in the zinc salt solution; and
when the doping metal ion is the Ce⁴⁺, a molar content of the Ce⁴⁺ takes a proportion of 0.1% to 10% of a total molar weight of metal ions in the zinc salt solution.

In some embodiments, in the step of mixing the zinc salt solution and the alkaline solution, the addition amount of the zinc salt solution and the alkaline solution satisfies: a product of the molar weight of the metal ions and a valence number and a molar weight of the hydroxide ions are at a ratio of 0.75:1 to 1.25:1.

A second preparation method of a QLED is provided, where the QLED includes an anode and a cathode that are oppositely arranged, a quantum dot luminescent layer arranged between the anode and the cathode, and an ETL arranged between the quantum dot luminescent layer and the cathode; the ETL includes a first ETL, and the first ETL is a zinc oxide film with a surface hydroxyl content of less than or equal to 0.4; and
a preparation method of the zinc oxide film with the surface hydroxyl content of less than or equal to 0.4 includes the following steps:
mixing a zinc salt solution with a alkaline solution for a reaction, to obtain zinc oxide nanoparticles; dissolving the zinc oxide nanoparticles to obtain a zinc oxide colloidal solution; adding an acid solution to the zinc oxide colloidal solution to adjust a pH value of the zinc oxide colloidal solution to 7 to 8, to obtain a zinc oxide solution; and
coating the zinc oxide solution on a prefabricated substrate for preparing the zinc oxide film with the surface hydroxyl content of less than or equal to 0.4, and removing a solvent to obtain the zinc oxide film with the surface hydroxyl content of less than or equal to 0.4.

In some embodiments, during adding the acid solution to the zinc oxide colloidal solution to adjust the pH value of the zinc oxide colloidal solution to 7 to 8, the acid solution is added to the zinc oxide colloidal solution such that an obtained mixed solution has a pH value of 7.2 to 7.8.

In some embodiments, during adding the acid solution to the zinc oxide colloidal solution to adjust the pH value of the zinc oxide colloidal solution to 7 to 8, the acid solution is added to the zinc oxide colloidal solution such that an obtained mixed solution has a pH value of 7.3 to 7.6.

In some embodiments, an acid in the acid solution is selected from at least one of hydrochloric acid, sulfuric acid, nitric acid, hydrofluoric acid, formic acid, acetic acid, propionic acid, oxalic acid, and acrylic acid.

In some embodiments, the alkaline solution is prepared by at least one of potassium hydroxide, sodium hydroxide, lithium hydroxide, TMAH, ammonia water, ethanolamine, and ethylenediamine.

In some embodiments, a solvent in the zinc salt solution and a solvent in the alkaline solution are each independently selected from at least one of water, an organic alcohol, an organic ether, and a sulfone.

In some embodiments, a solvent in the acid solution is selected from at least one of water, methanol, ethanol, propanol, butanol, ethylene glycol, 2-methoxyethanol, and DMSO.

In some embodiments, the zinc oxide film with the surface hydroxyl content of less than or equal to 0.4 is a metal-doped zinc oxide film, and the zinc salt solution includes a doping metal ion.

In some embodiments, the doping metal ion is selected from at least one of Mg2+ and Mn2+; alternatively,
the doping metal ion is selected from at least one of Al3+, Y3+, La3+, Li+, Gd3+, Zr4+, and Ce4+.

In some embodiments, the doping metal has a doping content as follows:
when the doping metal ion is the Mg²⁺, a molar content of the Mg2+ takes a proportion of 0.1% to 35% of a total molar weight of metal ions in the zinc salt solution;
when the doping metal ion is the Mn²⁺, a molar content of the Mn²⁺ takes a proportion of 0.1% to 30% of a total molar weight of metal ions in the zinc salt solution;
when the doping metal ion is the Al³⁺, a molar content of the Al³⁺ takes a proportion of 0.1% to 15% of a total molar weight of metal ions in the zinc salt solution;
when the doping metal ion is the Y³⁺, a molar content of the Y³⁺ takes a proportion of 0.10% to 10% of a total molar weight of metal ions in the zinc salt solution;
when the doping metal ion is the La³⁺, a molar content of the La³⁺ takes a proportion of 0.1% to 7% of a total molar weight of metal ions in the zinc salt solution;
when the doping metal ion is the Li⁺, a molar content of the Li⁺ takes a proportion of 0.1% to 45% of a total molar weight of metal ions in the zinc salt solution;
when the doping metal ion is the Gd³⁺, a molar content of the Gd³⁺ takes a proportion of 0.01% to 8% of a total molar weight of metal ions in the zinc salt solution;
when the doping metal ion is the Zr⁴⁺, a molar content of the Zr⁴⁺ takes a proportion of 0.1% to 45% of a total molar weight of metal ions in the zinc salt solution; and
when the doping metal ion is the Ce⁴⁺, a molar content of the Ce⁴⁺ takes a proportion of 0.10% to 10% of a total molar weight of metal ions in the zinc salt solution.

In some embodiments, in the step of mixing the zinc salt solution and the alkaline solution, the addition amount of the zinc salt solution and the alkaline solution satisfies: a product of the molar weight of the metal ions and a valence number and a molar weight of the hydroxide ions are at a ratio of 0.75:1 to 1.25:1.

A third preparation method of a QLED is provided, where the QLED includes an anode and a cathode that are oppositely arranged, a quantum dot luminescent layer arranged between the anode and the cathode, and an ETL arranged between the quantum dot luminescent layer and the cathode; the ETL includes a first ETL, and the first ETL is a zinc oxide film with a surface hydroxyl content of less than or equal to 0.4; and
a preparation method of the zinc oxide film with the surface hydroxyl content of less than or equal to 0.4 includes the following steps:
preparing a prefabricated zinc oxide film on a prefabricated substrate for preparing the zinc oxide film with the surface hydroxyl content of less than or equal to 0.4; and
depositing an acid solution on a surface of the prefabricated zinc oxide film, and drying to obtain the zinc oxide film.

In some embodiments, the acid solution has a concentration of 0.05 mmol/L to 0.5 mmol/L.

In some embodiments, a volume of 50 μL to 1,000 μL of the acid solution is deposited on per 5 mg of the prefabricated zinc oxide film.

In some embodiments, an acid in the acid solution is a strong inorganic acid, and the acid solution has a concentration of 0.05 mmol/L to 0.1 mmol/L.

In some embodiments, a volume of 50 μL to 200 μL of the acid solution is deposited on per 5 mg of the prefabricated zinc oxide film.

In some embodiments, the strong inorganic acid is selected from at least one of hydrochloric acid, sulfuric acid, nitric acid, and hydrofluoric acid.

In some embodiments, an acid in the acid solution is an organic carboxylic acid, and the acid solution has a concentration of 0.2 mmol/L to 0.4 mmol/L.

In some embodiments, a volume of 100 μL to 500 μL of the acid solution is deposited on per 5 mg of the prefabricated zinc oxide film.

In some embodiments, the organic carboxylic acid is selected from at least one of formic acid, acetic acid, propionic acid, oxalic acid, and acrylic acid.

In some embodiments, the drying process is conducted at 10° C. to 100° C. for 10 min to 2 hours.

In some embodiments, the zinc oxide film with the surface hydroxyl content of less than or equal to 0.4 is a metal-doped zinc oxide film, and the zinc salt solution includes a doping metal ion.

In some embodiments, the doping metal ion is selected from at least one of Mg2+ and Mn^{2+.}

In some embodiments, the doping metal ion is selected from at least one of Al3+, Y3+, La3+, Li+, Gd3+, Zr4+, and Ce4+.

In some embodiments, the doping metal has a doping content as follows:
when the doping metal ion is the Mg²⁺, a molar content of the Mg2+ takes a proportion of 0.1% to 35% of a total molar weight of metal ions in the zinc salt solution;
when the doping metal ion is the Mn²⁺, a molar content of the Mn²⁺ takes a proportion of 0.1% to 30% of a total molar weight of metal ions in the zinc salt solution;
when the doping metal ion is the Al³⁺, a molar content of the Al³⁺ takes a proportion of 0.1% to 15% of a total molar weight of metal ions in the zinc salt solution;
when the doping metal ion is the Y³⁺, a molar content of the Y³⁺ takes a proportion of 0.10% to 10% of a total molar weight of metal ions in the zinc salt solution;
when the doping metal ion is the La³⁺, a molar content of the La³⁺ takes a proportion of 0.1% to 7% of a total molar weight of metal ions in the zinc salt solution;
when the doping metal ion is the Li⁺, a molar content of the Li⁺ takes a proportion of 0.1% to 45% of a total molar weight of metal ions in the zinc salt solution;
when the doping metal ion is the Gd³⁺, a molar content of the Gd³⁺ takes a proportion of 0.01% to 8% of a total molar weight of metal ions in the zinc salt solution;
when the doping metal ion is the Zr⁴⁺, a molar content of the Zr⁴⁺ takes a proportion of 0.1% to 45% of a total molar weight of metal ions in the zinc salt solution; and
when the doping metal ion is the Ce⁴⁺, a molar content of the Ce⁴⁺ takes a proportion of 0.1% to 10% of a total molar weight of metal ions in the zinc salt solution.

A fourth preparation method of a QLED is provided, where the QLED includes an anode and a cathode that are oppositely arranged, a quantum dot luminescent layer arranged between the anode and the cathode, and an ETL arranged between the quantum dot luminescent layer and the cathode; the ETL includes a first ETL with zinc oxide, and a surface of the zinc oxide forming the first ETL includes an amino ligand and/or a carboxyl ligand with 3 to 7 carbon atoms; and
a preparation method of the first ETL includes the following steps:
preparing a zinc oxide colloidal solution by a solution method using a zinc salt solution, a alkaline solution, and the amino ligands and/or the carboxyl ligands with 3 to 7 carbon atoms as raw materials; where the surface of the zinc oxide in the zinc oxide colloidal solution is bonded with the amino ligands and/or the carboxyl ligands with 3 to 7 carbon atoms; and
coating the zinc oxide colloidal solution on a prefabricated substrate for preparing the first ETL, and removing a solvent to obtain the first ETL.

In some embodiments, a process of preparing the zinc oxide colloidal solution by the solution method includes:
mixing the zinc salt solution, the alkaline solution, and the amino ligands and/or the carboxyl ligands with 3 to 7 carbon atoms for a reaction, to obtain zinc oxide nanoparticles having surfaces bonded with the amino ligands and/or the carboxyl ligands with 3 to 7 carbon atoms; and
dissolving the zinc oxide nanoparticles to obtain the zinc oxide colloidal solution.

In some embodiments, a process of preparing the zinc oxide colloidal solution by the solution method includes:
mixing the zinc salt solution and the alkaline solution, and then adding the amino ligands and/or the carboxyl ligands with 3 to 7 carbon atoms for a reaction for greater than or equal to 10 min, to obtain zinc oxide nanoparticles having surfaces bonded with the amino ligands and/or the carboxyl ligands with 3 to 7 carbon atoms; and
dissolving the zinc oxide nanoparticles to obtain the zinc oxide colloidal solution.

In some embodiments, a process of preparing the zinc oxide colloidal solution by the solution method includes:
mixing the zinc salt solution and the alkaline solution for a reaction to obtain zinc oxide nanoparticles, and then adding the amino ligands and/or the carboxyl ligands with 3 to 7 carbon atoms to continue the reaction, to obtain zinc oxide nanoparticles having surfaces bonded with the amino ligands and/or the carboxyl ligands with 3 to 7 carbon atoms; and
dissolving the zinc oxide nanoparticles to obtain the zinc oxide colloidal solution.

In some embodiments, a process of preparing the zinc oxide colloidal solution by the solution method includes:
mixing the zinc salt solution and the alkaline solution for a reaction, collecting a reaction product, and cleaning the reaction product to obtain zinc oxide nanoparticles; and
dissolving the zinc oxide nanoparticles, adding the amino ligands and/or the carboxyl ligands with 3 to 7 carbon atoms for a reaction, such that the amino ligands and/or the carboxyl ligands with 3 to 7 carbon atoms is bonded with the surface of the zinc oxide to obtain the zinc oxide colloidal solution.

In some embodiments, the reaction is conducted for 10 min to 2 hours after the amino ligands and/or the carboxyl ligands with 3 to 7 carbon atoms are added.

In some embodiments, the amino ligands and/or the carboxyl ligands with 3 to 7 carbon atoms is a ligand solution, and the ligand solution has a concentration of 0.2 mmol/L to 0.4 mmol/L.

In some embodiments, the amino ligands and/or the carboxyl ligands with 3 to 7 carbon atoms and a zinc salt in the zinc salt solution are at a molar ratio of 1:1 to 10:1.

In some embodiments, the amino ligands and/or the carboxyl ligands has 3 to 4 carbon atoms, and the amino ligands and/or the carboxyl ligands with 3 to 7 carbon atoms and the zinc salt in the zinc salt solution are at a molar ratio of 4:1 to 10:1; and
the amino ligands and/or the carboxyl ligands has 5 to 7 carbon atoms, and the amino ligands and/or the carboxyl ligands with 3 to 7 carbon atoms and the zinc salt in the zinc salt solution are at a molar ratio of 1:1 to 5:1.

In some embodiments, the amino ligands and/or the carboxyl ligands with 3 to 7 carbon atoms is a ligand solution, and the ligand solution has a concentration of 0.05 mmol/L to 0.1 mmol/L.

In some embodiments, the amino ligands and/or the carboxyl ligands with 3 to 7 carbon atoms and a zinc salt in the zinc salt solution are at a molar ratio of 1:4 to 4:1.

In some embodiments, the amino ligands and/or the carboxyl ligands has 3 to 4 carbon atoms, and the amino ligands and/or the carboxyl ligands with 3 to 7 carbon atoms and the zinc salt in the zinc salt solution are at a molar ratio of 1:1 to 4:1; and
the amino ligands and/or the carboxyl ligands has 5 to 7 carbon atoms, and the amino ligands and/or the carboxyl ligands with 3 to 7 carbon atoms and the zinc salt in the zinc salt solution are at a molar ratio of 1:4 to 2:1.

In some embodiments, the amino ligands and/or the carboxyl ligands with 3 to 7 carbon atoms is selected from at least one of propionic acid, propylamine, butyric acid, butylamine, hexanoic acid, and hexylamine.

A fifth preparation method of a QLED is provided, where the QLED includes an anode and a cathode that are oppositely arranged, a quantum dot luminescent layer arranged between the anode and the cathode, and an ETL arranged between the quantum dot luminescent layer and the cathode; the ETL includes a first ETL with zinc oxide, and at least a surface on one side of the first ETL includes an amino ligand and/or the carboxyl ligand with 3 to 7 carbon atoms; and
a preparation method of the first ETL includes the following steps:
preparing a prefabricated zinc oxide film on a prefabricated substrate for preparing the first ETL; and
depositing a solution of the amino ligands and/or the carboxyl ligands with 3 to 7 carbon atoms on a surface of the prefabricated zinc oxide film, and drying to obtain the first ETL.

In some embodiments, the solution of the amino ligands and/or the carboxyl ligands with 3 to 7 carbon atoms has a concentration of 0.05 mmol/L to 0.5 mmol/L.

In some embodiments, the amino ligands and/or the carboxyl ligands with 3 to 7 carbon atoms has 3 to 4 carbon atoms, and 100 μL to 500 μL of the solution of the amino ligands and/or the carboxyl ligands with 3 to 7 carbon atoms is deposited on per 5 mg of the prefabricated zinc oxide film.

In some embodiments, the amino ligands and/or the carboxyl ligands with 3 to 7 carbon atoms has 5 to 7 carbon atoms, and 50 μL to 400 μL of the solution of the amino ligands and/or the carboxyl ligands with 3 to 7 carbon atoms is deposited on per 5 mg of the prefabricated zinc oxide film.

In some embodiments, the amino ligands and/or the carboxyl ligands with 3 to 7 carbon atoms is selected from at least one of propionic acid, propylamine, butyric acid, butylamine, hexanoic acid, and hexylamine.

In some embodiments, the drying process is conducted at 10° C. to 100° C. for 10 min to 2 hours.

In some embodiments, the first ETL is a metal-doped zinc oxide film.

In some embodiments, the doping metal ion is selected from at least one of Mg²⁺ and Mn^{2+.}

In some embodiments, the doping metal ion is selected from at least one of Al³⁺, Y³⁺, La³⁺, Li⁺, Gd³⁺, Zr⁴⁺, and Ce⁴⁺.

In some embodiments, the doping metal has a doping content as follows:
when the doping metal ion is the Mg²⁺, a molar content of the Mg²⁺ takes a proportion of 0.1% to 35% of a total molar weight of metal ions in the zinc salt solution;
when the doping metal ion is the Mn²⁺, a molar content of the Mn²⁺ takes a proportion of 0.1% to 30% of a total molar weight of metal ions in the zinc salt solution;
when the doping metal ion is the Al³⁺, a molar content of the Al³⁺ takes a proportion of 0.1% to 15% of a total molar weight of metal ions in the zinc salt solution;
when the doping metal ion is the Y³⁺, a molar content of the Y³⁺ takes a proportion of 0.10% to 10% of a total molar weight of metal ions in the zinc salt solution;
when the doping metal ion is the La³⁺, a molar content of the La³⁺ takes a proportion of 0.1% to 7% of a total molar weight of metal ions in the zinc salt solution;
when the doping metal ion is the Li⁺, a molar content of the Li⁺ takes a proportion of 0.1% to 45% of a total molar weight of metal ions in the zinc salt solution;
when the doping metal ion is the Gd³⁺, a molar content of the Gd³⁺ takes a proportion of 0.01% to 8% of a total molar weight of metal ions in the zinc salt solution;
when the doping metal ion is the Zr⁴⁺, a molar content of the Zr⁴⁺ takes a proportion of 0.1% to 45% of a total molar weight of metal ions in the zinc salt solution; and
when the doping metal ion is the Ce⁴⁺, a molar content of the Ce⁴⁺ takes a proportion of 0.10% to 10% of a total molar weight of metal ions in the zinc salt solution.

In some embodiments, the prefabricated zinc oxide film is prepared by a solution method, including:
mixing a zinc salt solution mixed with a alkaline solution to obtain zinc oxide nanoparticles; dissolving the zinc oxide nanoparticles to obtain a zinc oxide colloidal solution; coating the zinc oxide colloidal solution on a prefabricated substrate for preparing the first ETL, and removing a solvent to obtain the prefabricated zinc oxide film.

In the present disclosure, the QLED uses a zinc oxide film with a surface hydroxyl content of less than or equal to 0.4 as a first ETL, or uses zinc oxide with the surface containing the amino ligands and/or the carboxyl ligands with 3 to 7 carbon atoms as a constituent material of ETL to reduce a hydroxyl content on the surface of zinc oxide nanoparticles (due to a short chain length of the coordinated amine/carboxyl ligands, a distance between the zinc oxide nanoparticles after film formation may not be significantly increased, thereby increasing the electron mobility of the zinc oxide ETL after film formation). In this way, the transmission of electrons to the quantum dot luminescent layer becomes smooth, and the electrons injected into the quantum dot luminescent layer increase. As a result, the injection rate of electrons into the quantum dot luminescent layer is higher than the injection rate of holes into the quantum dot luminescent layer, thus causing the quantum dots in the quantum dot luminescent layer to be negatively charged. This negatively charged state can be maintained due to a quantum dot core-shell structure and a binding effect of the electrically inert surface ligands. Meanwhile, a Coulomb repulsion effect makes the further injection of electrons into the quantum dot luminescent layer more and more difficult. When a QLED-based device continues to light up to a stable state, the negatively charged state of the quantum dots also tends to be stable. That is, the electrons newly captured and bound by the quantum dots and the electrons consumed by the radiative transition reach a dynamic balance, and the injection rate of electrons into the quantum dot luminescent layer is much lower than that in the initial stage. At this time, a lower electron injection rate and a hole injection rate just reach a carrier injection balance, such that the service life of the device is improved. In other words, at the initial stage of QLED-based device operation, a high electron injection rate may make the QLED-based device in a carrier injection unbalanced state, which can affect the device performance. However, when the QLED-based device continues to light up to a steady state, the reduced electron injection rate can form a carrier injection balance with the hole injection rate. In this way, the continuous maintenance of the efficiency of the device is realized, thereby effectively improving the service life of the QLED-based device.

The present disclosure further provides a preparation method of a QLED. The preparation method reduces the hydroxyl content on a surface of the zinc oxide nanoparticles, increases an electron mobility of the zinc oxide ETL after film formation, and thus effectively improves the service life of the QLED-based device.

### BRIEF DESCRIPTION OF THE DRAWINGS

To describe the technical solutions in the embodiments of the present application more clearly, the drawings required for describing the embodiments or the prior art are described briefly below. Apparently, the drawings in the following description merely show some embodiments of the present application, and those of ordinary skill in the art may still derive other drawings from these drawings without creative efforts.

FIG. 1 illustrates a schematic structural diagram of an ETL provided by an embodiment of the present disclosure;

FIG. 2 illustrates a schematic structural diagram of another ETL provided by an embodiment of the present disclosure;

FIG. 3 illustrates a schematic structural diagram of a light-emitting diode (LED) provided by an embodiment of the present disclosure;

FIG. 4 illustrates a schematic structural diagram of an upright LED provided by an embodiment of the present disclosure;

FIG. 5 illustrates a schematic structural diagram of an inverted LED provided by an embodiment of the present disclosure;

FIG. 6 illustrates a flowchart of a first preparation process of a zinc oxide film with a surface hydroxyl content of less than or equal to 0.4 provided by an embodiment of the present disclosure;

FIG. 7 illustrates a flowchart of a second preparation process of the zinc oxide film with the surface hydroxyl content of less than or equal to 0.4 provided by an embodiment of the present disclosure;

FIG. 8 illustrates a flowchart of a third preparation process of the zinc oxide film with the surface hydroxyl content of less than or equal to 0.4 provided by an embodiment of the present disclosure;

FIG. 9 illustrates a flowchart of a first preparation process of a first ETL provided by an embodiment of the present disclosure, using zinc oxide having an amino ligand and/or a carboxyl ligand with 3 to 7 carbon atoms as an electron transport material;

FIG. 10 illustrates a flowchart of a second preparation process of the first ETL provided by an embodiment of the present disclosure, using zinc oxide having an amino ligand and/or a carboxyl ligand with 3 to 7 carbon atoms as an electron transport material;

FIG. 11 illustrates a schematic diagram of a hydroxyl content obtained by measuring a peak area of hydroxyl oxygen and a peak area of lattice oxygen by X-ray photoelectron spectroscopy (XPS) and calculating a ratio of the two provided by an embodiment of the present disclosure;

FIG. 12 illustrates an external quantum efficiency (EQE)-brightness curve provided by an embodiment of the present disclosure;

FIG. 13 illustrates a schematic diagram of a characterizing device life provided by an embodiment of the present disclosure;

FIG. 14 illustrates a lifetime test result of QLEDs provided by Embodiment 1 and Comparative Example 1 of the present disclosure;

FIG. 15 illustrates a device EQE test result of QLEDs provided by Embodiment 2 and Comparative Example 1 of the present disclosure;

FIG. 16 illustrates a lifetime test result of QLEDs provided by Embodiment 2 and Comparative Example 1 of the present disclosure;

FIG. 17 illustrates a device EQE test result of QLEDs provided by Embodiment 3 and Comparative Example 1 of the present disclosure;

FIG. 18 illustrates a lifetime test result of QLEDs provided by Embodiment 3 and Comparative Example 1 of the present disclosure;

FIG. 19 illustrates a device EQE test result of QLEDs provided by Embodiment 4 and Comparative Example 1 of the present disclosure;

FIG. 20 illustrates a lifetime test result of QLEDs provided by Embodiment 4 and Comparative Example 1 of the present disclosure;

FIG. 21 illustrates a device EQE test result of QLEDs provided by Embodiment 5 and Comparative Example 1 of the present disclosure;

FIG. 22 illustrates a lifetime test result of QLEDs provided by Embodiment 5 and Comparative Example 1 of the present disclosure;

FIG. 23 illustrates a device EQE test result of QLEDs provided by Embodiment 6 and Comparative Example 1 of the present disclosure;

FIG. 24 illustrates a lifetime test result of QLEDs provided by Embodiment 6 and Comparative Example 1 of the present disclosure;

FIG. 25 illustrates a lifetime test result of QLEDs provided by Embodiment 7 and Comparative Example 2 of the present disclosure;

FIG. 26 illustrates a lifetime test result of QLEDs provided by Embodiment 8 and Comparative Example 2 of the present disclosure;

FIG. 27 illustrates a lifetime test result of QLEDs provided by Embodiment 9 and Comparative Example 2 of the present disclosure; and

FIG. 28 illustrates a lifetime test result of QLEDs provided by Embodiment 10 and Comparative Example 2 of the present disclosure.

### DETAILED DESCRIPTION OF THE EMBODIMENTS

In order to make the technical problems to be solved, the technical solutions, and the beneficial effects of the present application be clearer, the present application is further described in detail below with reference to embodiments. It should be understood that the specific embodiments described herein are merely intended to explain the present application, rather than to limit the present application.

In the description of this application, it should be understood that terms such as “first” and “second” are used merely for a descriptive purpose, and should not be construed as indicating or implying a relative importance, or implicitly indicating the number of indicated technical features. Thus, features defined with “first” and “second” may explicitly or implicitly include one or more of the features. In the description of the present application, “multiple” means two or more, unless otherwise said “multiple” is specifically defined.

In QLED-based devices, an electron mobility of the zinc oxide layer is generally higher than a hole mobility of the HTL. In order to achieve a better balance of carrier injection in QLED-based devices, the traditional scheme reduces the electron mobility of the zinc oxide layer by inserting EBL between the quantum dot luminescent layer and the zinc oxide layer, such that the injected electrons and holes in the quantum dot luminescent layer are balanced. However, a lower electron injection rate can only form an instantaneous balance of charge injection in the initial stage of QLED-based device operation, and achieve high device efficiency at the initial instant. As the device continues to work, the electron injection rate decreases until the device state reaches a dynamic equilibrium. This kind of carrier injection balance is quickly broken, and the high device efficiency is reduced and cannot be maintained. Moreover, this unbalanced state of carrier injection may continue to aggravate with continuous operation, so the service life of the device may also rapidly decay accordingly.

In view of this, an embodiment of the present disclosure realizes the regulation of electron injection rate by regulating the hydroxyl content on the surface of the zinc oxide film. In this way, the balance of carrier injection in a stable operation state is achieved, and the continuous maintenance of device efficiency is realized, thereby effectively improving a working life of QLED-based devices. Specifically, the QLED utilizes a zinc oxide film with less surface hydroxyl groups as an ETL. In this case, since the injection rate of electrons into the quantum dot luminescent layer is higher than that of holes, the quantum dots in the luminescent layer are negatively charged. This negatively charged state can be maintained due to a quantum dot core-shell structure and a binding effect of the electrically inert surface ligands. Meanwhile, a Coulomb repulsion effect makes the further injection of electrons into the quantum dot luminescent layer more and more difficult. When a QLED-based device continues to light up to a stable state, the negatively charged state of the quantum dots also tends to be stable. That is, the electrons newly captured and bound by the quantum dots and the electrons consumed by the radiative transition reach a dynamic balance, and the injection rate of electrons into the quantum dot luminescent layer is much lower than that in the initial stage. At this time, a lower electron injection rate and a hole injection rate just reach a carrier injection balance, such that the service life of the device is improved.

In a first aspect, an embodiment of the present disclosure provides a QLED, including an anode and a cathode that are oppositely arranged, a quantum dot luminescent layer arranged between the anode and the cathode, and an ETL arranged between the quantum dot luminescent layer and the cathode; where
the ETL includes a first ETL, and the first ETL is a zinc oxide film with a surface hydroxyl content of less than or equal to 0.4.

In a possible implementation, the ETL includes only a layer of film, and the film is a zinc oxide film with a surface hydroxyl content of less than or equal to 0.4, that is, the ETL is a first ETL. In this case, the electronic-oriented quantum dot luminescent layer in the ETL has a small transmission resistance, which is conducive to negative charge of the quantum dots in the quantum dot luminescent layer. Under the constraints of the quantum dot structure (quantum dot core-shell structure and electrically inert surface ligands), the quantum dot maintains a negative point state and Coulomb repulsion effect. This makes the negatively charged state of the quantum dots also tend to be stable when the QLED-based device continues to light up to a stable state. At this time, the electrons newly captured and bound by the quantum dots and the electrons consumed by the radiative transition reach a dynamic balance, and the injection rate of electrons into the quantum dot luminescent layer is much lower than that in the initial stage. As a result, a lower electron injection rate and a hole injection rate just reach a carrier injection balance, such that the service life of the device is improved.

When the ETL is the first ETL, zinc oxide in the first ETL is metal-doped or metal-undoped zinc oxide.

In some embodiments, the first ETL is a zinc oxide film that does not contain doping metal, that is, the ETL is made of zinc oxide, and the zinc oxide does not contain doping metal. In some embodiments, the undoped zinc oxide film has a surface hydroxyl content of less than or equal to 0.25; in some embodiments, the undoped zinc oxide film has a surface hydroxyl content of less than or equal to 0.15. It should be noted that the undoped ZnO film referred to in the embodiments of the present disclosure is a ZnO film relative to the metal-doped ZnO film. This means that the zinc oxide forming the zinc oxide film is not doped with other metal ions. That is, the undoped zinc oxide film is a pure zinc oxide film.

In some embodiments, the first ETL is a metal-doped zinc oxide film, that is, the zinc oxide in the ETL is metal-doped zinc oxide. It should be understood that the doping metal referred to in this application refers to other metal ions other than zinc ions doped into zinc oxide in the form of ions. When the doped zinc oxide obtained by doping metal elements in zinc oxide is used as the ETL material of QLED, it is beneficial for QLED-based devices to obtain higher device efficiency. However, the device service life is not ideal, even worse than that of QLEDs with undoped pure zinc oxide ETL. This is because the energy level/oxygen vacancies (electron mobility) of the doped ZnO ETL changes, and the doping ions enter the surface of the ZnO particles and preferentially fill the surface defects, which can passivate the defects to a certain extent. The newly filled doping ion sites can coordinate new surface hydroxyl groups, such that the total amount of surface hydroxyl groups will increase. Therefore, in this embodiment, the effective control of carrier injection is achieved by making the amount of hydroxyl groups on the surface of the metal-doped zinc oxide film less than or equal to 0.4. Specifically, compared with the adjustment of the hydroxyl content on the surface of the undoped zinc oxide film, when adjusting the hydroxyl content on the surface of the doped zinc oxide film. On the one hand, through the energy level matching optimization or electron mobility optimization of doped zinc oxide, the QLED-based device is already in a better carrier injection balance, and a higher external quantum efficiency (EQE) than that of QLED-based devices with undoped ZnO films as ETL can be obtained at the initial stage of device operation. On the other hand, due to the low hydroxyl content on the surface of the doped zinc oxide film, the QLED-based device can easily reach the carrier injection equilibrium state when it continues to operate to enter a stable state, and thus obtain a good device service life. Finally, QLEDs can obtain QLED-based devices with significantly improved service life while maintaining a high EQE.

In some embodiments, the metal-doped zinc oxide film has a surface hydroxyl content less than or equal to 0.25; in some embodiments, the metal-doped zinc oxide film has a surface hydroxyl content of less than or equal to 0.15.

In some embodiments, the doping metal in the metal-doped zinc oxide film is selected from at least one of Mg²⁺ and Mn²⁺. In this case, the doping metal ions and the zinc ions have the same valence state, but their oxides have metal ions with a different conduction band energy level. At this time, doping this metal ion can adjust the conduction band energy level of ZnO ETL, thereby optimizing the energy level matching between the quantum dot luminescent layer and ETL in QLED-based devices, and improving the EQE of the device.

In some embodiments, the doping metal in the metal-doped zinc oxide film is selected from at least one of Al³⁺, Y³⁺, La³⁺, Li⁺, Gd³⁺, Zr⁴⁺, and Ce⁴⁺. In this case, the doping metal ion has a different valence state of the metal ion than the zinc ion. Doping this metal ion can adjust the oxygen vacancies (electron mobility) of the zinc oxide ETL, thereby optimizing the carrier injection balance of the QLED device and improving the EQE of the device.

There is a certain difference between the ionic radius of the doping metal ion and the zinc ion radius, and the crystal structure of the two oxides is different (exemplarily, MgO and MnO are NaCl type cubic crystal system, ZrO₂ is monoclinic crystal system, and ZnO is wurtzite type hexagonal crystal system), such that the doping metal ion has a doping limit in the zinc oxide material. When the doping amount exceeds the doping limit, the doping metal ions may be precipitated from the surface of the zinc oxide material in the form of the second phase, which can affect the performance of the zinc oxide material. The comparison of the ionic radii of doping metal ions and zinc ions provided in the embodiments of the present disclosure is shown in Table 1.

TABLE 1

| | Zn²⁺ | Mg²⁺ | Mn²⁺ | Al³⁺ | Y³⁺ |
|---|---|---|---|---|---|
| Ionic radius (Å) | 0.60 | 0.57 | 0.66 | 0.39 | 0.90 |
| ${\vert \frac{{r}_{{M}^{n +}} + {r}_{{Zn}^{2 +}}}{{r}_{{Zn}^{2 +}}} \vert}_{( \% )}$ | | 5.0 | 10.0 | 35 | 50 |
| | La³⁺ | Li⁺ | Gd³⁺ | Ce⁴⁺ | Zr⁴⁺ |
| Ionic radius (Å) | 1.03 | 0.59 | 0.94 | 0.87 | 0.59 |
| ${\vert \frac{{r}_{{M}^{n +}} + {r}_{{Zn}^{2 +}}}{{r}_{{Zn}^{2 +}}} \vert}_{( \% )}$ | 72 | 1.7 | 56 | 45 | 1.7 |

In the embodiment of the present disclosure, the doping amount of the doping metal ions is regulated according to the difference in radius between the selected doping metal ion and the Zn²⁺ ion. Generally, the closer the ionic radius of doping metal ions is to the ionic radius of zinc ions and the more similar the crystal structures of the two oxides, the higher the doping limit of doping metal ions in zinc oxide materials. Exemplarily, when the doping metal is Mg²⁺, the doping molar concentration of Mg²⁺ in the zinc oxide film containing the doping metal is 0.1% to 35%. When the doping metal is Mn²⁺, the doping molar concentration of Mn²⁺ in the zinc oxide film containing the doping metal is 0.1% to 30%. When the doping metal is Al³⁺, the doping molar concentration of Al³⁺ in the zinc oxide film containing the doping metal is 0.1% to 15%. When the doping metal is Y³⁺, the doping molar concentration of Y³⁺ in the zinc oxide film containing the doping metal is 0.1% to 10%. When the doping metal is La³⁺, the doping molar concentration of La³⁺ in the zinc oxide film containing the doping metal is 0.1% to 7%. When the doping metal is Li⁺, the doping molar concentration of Li⁺ in the zinc oxide film containing the doping metal is 0.1% to 45%. When the doping metal is Gd³⁺, the doping molar concentration of Gd³⁺ in the zinc oxide film containing the doping metal is 0.01% to 8%. When the doping metal is Zr⁴⁺, the doping molar concentration of Zr⁴⁺ in the zinc oxide film containing the doping metal is 0.1% to 45%. When the doping metal is Ce⁴⁺, the doping molar concentration of Ce⁴⁺ in the zinc oxide film containing the doping metal is 0.1% to 10%.

In some embodiments, when the ETL is the first ETL, the first ETL (that is, the ETL) has a thickness of 10 nm to 100 nm.

In a possible implementation manner, the ETL further includes a second ETL, and the second ETL is a zinc oxide film with a surface hydroxyl content of greater than or equal to 0.6. That is to say, the ETL includes simultaneously a zinc oxide film with a surface hydroxyl content of less than or equal to 0.4 and a zinc oxide film with a surface hydroxyl content of greater than or equal to 0.6, which are stacked along a direction perpendicular to the quantum dot luminescent layer or the cathode. In this case, when bilayer zinc oxide electron transport is used, the zinc oxide film with high hydroxyl content on the surface can reduce the injection of electrons into the quantum dot luminescent layer. This makes the electron injection efficiency of the QLED-based device lower at the initial stage of operation, and realizes the injection balance of carriers in the QLED-based device. At this time, the device is in the state of the same balance of carriers, and has a high external quantum efficiency. However, when the QLED device continues to operate to enter a stable state, due to the existence of a zinc oxide film with a low surface hydroxyl content, the negatively charged state of the quantum dot luminescent layer may still occur, and it is easy to reach a dynamic equilibrium. Furthermore, the final electron injection efficiency is kept at a relatively low level, so as to form a carrier injection balance with the hole injection efficiency. Therefore, the service life of the obtained QLED-based devices can also be improved.

The first ETL and the second ETL are stacked, and the relative positions of the two can be flexibly set. In some embodiments, the second ETL is arranged on a surface of one side of the first ETL adjacent to the cathode. In this case, when the zinc oxide or metal-doped zinc oxide colloidal solution with less surface hydroxyl is deposited on the quantum dot luminescent layer, it is beneficial to obtain a flat zinc oxide film. In some embodiments, the second ETL is arranged on a surface of one side of the first ETL adjacent to the quantum dot luminescent layer.

In some embodiments, both the zinc oxide in the first ETL and the second ETL are undoped zinc oxide. That is, the first ETL and the second ETL are made of zinc oxide, which does not contain doping metals. In some embodiments, the ETL is composed of a zinc oxide film with a surface hydroxyl content of less than or equal to 0.4, that is, a first ETL and a second ETL with a surface hydroxyl content of greater than or equal to 0.6. In some embodiments, the first ETL has a surface hydroxyl content of less than or equal to 0.25, and the second ETL has a surface hydroxyl content of greater than or equal to 0.8, or even greater than or equal to 1.0; in some embodiments, the first ETL has a surface hydroxyl content of less than or equal to 0.15, and the second ETL has a surface hydroxyl content of greater than or equal to 0.8, or even greater than or equal to 1.0.

In some embodiments, the zinc oxide in at least one of the first ETL and the second ETL is metal-doped zinc oxide.

In some embodiments, the zinc oxide in the zinc oxide film with the surface hydroxyl content of less than or equal to 0.4 is metal-doped zinc oxide; the zinc oxide film with a surface hydroxyl content of greater than or equal to 0.6, that is, the second ETL is an undoped zinc oxide film. In this case, as mentioned above: on the one hand, the low hydroxyl content makes it easy for QLED-based devices to reach a carrier injection equilibrium state when they continue to operate to enter a stable state, thereby obtaining a good device service life. On the other hand, a high hydroxyl content can reduce the injected electrons in the quantum dot luminescent layer, and realize the balance of carrier injection in QLED-based devices, so as to finally obtain QLED-based devices with higher external quantum efficiency. In addition, metal ions are doped in zinc oxide with a surface hydroxyl content of less than or equal to 0.4 to achieve effective carrier injection regulation. In the early stage of device operation, a higher EQE can be obtained than that of a QLED-based device in which an undoped zinc oxide film is used as an ETL, while the second ETL has a surface hydroxyl content of greater than or equal to 0.6. The synergy of the above two can improve the EQE of QLED-based devices more effectively. In this embodiment, the carrier injection balance of the QLED-based device can be achieved by adjusting the hydroxyl content on the surface of the zinc oxide film. This does not require changing a structure of the device (inserting an EBL), nor does it require modification of the zinc oxide film by means such as doping. The whole process has simple operation, low cost, and good repeatability.

Exemplarily, the ETL is composed of a first ETL and an undoped zinc oxide film (second ETL) with a surface hydroxyl content of greater than or equal to 0.6, and the zinc oxide in the first ETL is metal-doped zinc oxide. In some embodiments, the first ETL has a surface hydroxyl content of less than or equal to 0.25, and the second ETL has a surface hydroxyl content of greater than or equal to 0.8, or even greater than or equal to 1.0; in some embodiments, the first ETL has a surface hydroxyl content of less than or equal to 0.15, and the second ETL has a surface hydroxyl content of greater than or equal to 0.8, or even greater than or equal to 1.0.

In some embodiments, the zinc oxide film with the surface hydroxyl content of less than or equal to 0.4, that is, the first ETL is an undoped zinc oxide film; the zinc oxide in the zinc oxide film with a surface hydroxyl content of greater than or equal to 0.6, that is, the second ETL is metal-doped zinc oxide. In this case: on the one hand, the low hydroxyl content makes it easy for QLED-based devices to reach a carrier injection equilibrium state when they continue to operate to enter a stable state, thereby obtaining a good device service life. On the other hand, a high hydroxyl content can significantly reduce the injected electrons in the quantum dot luminescent layer, and realize the balance of carrier injection in QLED-based devices, so as to finally obtain QLED-based devices with higher external quantum efficiency. In addition, metal ions are doped in zinc oxide with a surface hydroxyl content of greater than or equal to 0.6 to achieve effective carrier injection regulation. In the early stage of device operation, a higher EQE can be obtained than that of a QLED-based device in which an undoped zinc oxide film is used as an ETL, while the second ETL has a surface hydroxyl content of greater than or equal to 0.6. The synergy of the above two can improve the EQE of QLED-based devices more effectively.

Exemplarily, the ETL is composed of an undoped zinc oxide film (first ETL) with a surface hydroxyl content of less than or equal to 0.4 and a zinc oxide film (second ETL) with a surface hydroxyl content of greater than or equal to 0.6, and the zinc oxide in the second ETL is metal-doped zinc oxide. In some embodiments, the first ETL has a surface hydroxyl content of less than or equal to 0.25, and the second ETL has a surface hydroxyl content of greater than or equal to 0.8, or even greater than or equal to 1.0; in some embodiments, the first ETL has a surface hydroxyl content of less than or equal to 0.15, and the second ETL has a surface hydroxyl content of greater than or equal to 0.8, or even greater than or equal to 1.0.

In some embodiments, the zinc oxide in the zinc oxide film with the surface hydroxyl content of less than or equal to 0.4, that is, the first ETL is metal-doped zinc oxide; the zinc oxide in the zinc oxide film with a surface hydroxyl content of greater than or equal to 0.6, that is, the second ETL is metal-doped zinc oxide. In this case: on the one hand, the low hydroxyl content makes it easy for QLED-based devices to reach a carrier injection equilibrium state when they continue to operate to enter a stable state, thereby obtaining a good device service life. On the other hand, a high hydroxyl content can significantly reduce the injected electrons in the quantum dot luminescent layer, and realize the balance of carrier injection in QLED-based devices, so as to finally obtain QLED-based devices with higher external quantum efficiency. In addition, metal ions are doped in both zinc oxide with a surface hydroxyl content of greater than or equal to 0.6 and zinc oxide with a surface hydroxyl content of less than or equal to 0.4 to achieve effective carrier injection regulation. In the early stage of device operation, a higher EQE can be obtained than that of a QLED-based device in which an undoped zinc oxide film is used as an ETL, while the second ETL has a surface hydroxyl content of greater than or equal to 0.6. The synergy of the above three can significantly improve the EQE of QLED-based devices.

Exemplarily, the ETL is composed of a zinc oxide film (first ETL) with a surface hydroxyl content of less than or equal to 0.4 and a zinc oxide film (second ETL) with a surface hydroxyl content of greater than or equal to 0.6, and the zinc oxide in the first ETL and the second ETL are both metal-doped zinc oxide. In some embodiments, the first ETL has a surface hydroxyl content of less than or equal to 0.25, and the second ETL has a surface hydroxyl content of greater than or equal to 0.8, or even greater than or equal to 1.0; in some embodiments, the first ETL has a surface hydroxyl content of less than or equal to 0.15, and the second ETL has a surface hydroxyl content of greater than or equal to 0.8, or even greater than or equal to 1.0.

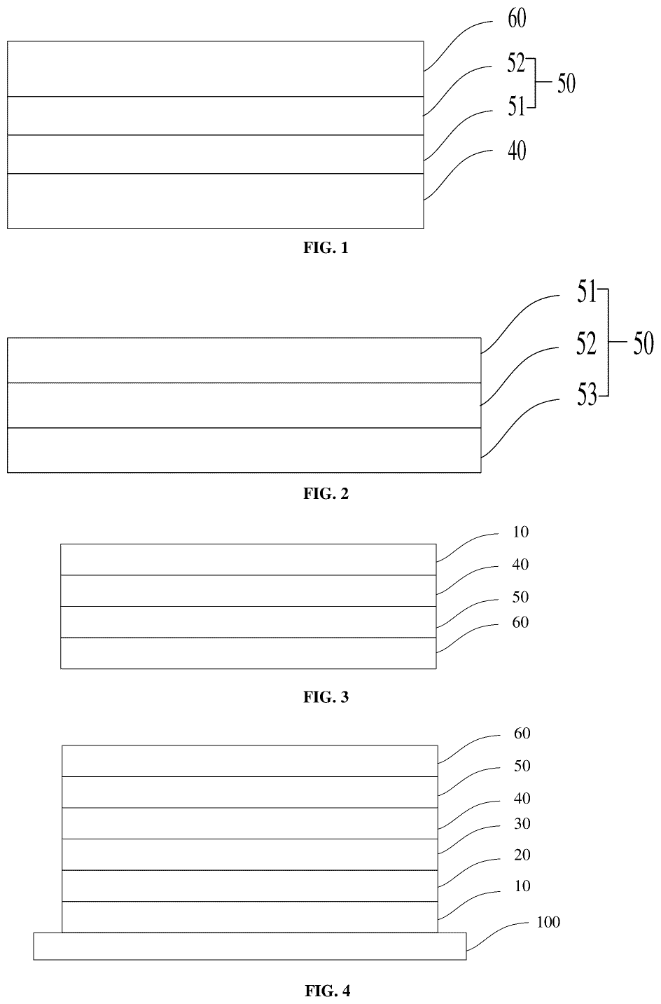

In an implementation manner of the embodiment, as shown in FIG. 1: the ETL 50 is composed of a first ETL 51 and a second ETL 52, and the first ETL 51 is closer to the quantum dot luminescent layer 40 than the first ETL 52; that is, the second ETL 52 is adjacent to the cathode 60. In this case, when the zinc oxide colloidal solution with less surface hydroxyl is deposited on the quantum dot luminescent layer, it is beneficial to obtain a flat zinc oxide film. In some embodiments, the second ETL is arranged on a surface of one side of the first ETL adjacent to the quantum dot luminescent layer.

In some embodiments, the ETL includes a first ETL and a second ETL, the second ETL is arranged on a surface of one side of the first ETL adjacent to the cathode or the quantum dot luminescent layer, and the second ETL is a metal-doped zinc oxide film. In this case, the external quantum efficiency (EQE) of QLED is optimized directly by doping zinc oxide energy level matching optimization or electron mobility optimization, such that QLED is in a better carrier injection balance; through the hydroxyl content on the surface of the first ETL, the QLED-based device can easily reach the carrier injection balance state when it continues to operate to enter a stable state, and then obtain a desirable device service life.

Exemplarily, as shown in FIG. 1: the ETL 50 includes a first ETL 51 and a second ETL 52; the second ETL 52 is a metal-doped zinc oxide film, and the second ETL 52 is arranged on a surface of the first ETL 51 at one side adjacent to the cathode 60; that is, the first ETL 51 is adjacent to the quantum dot luminescent layer 40. In this case, a bilayer ZnO ETL is obtained. Due to the existence of the metal-doped zinc oxide layer, the QLED-based device is in a relatively balanced state of carriers in the early stage of operation, and has a high EQE. However, when the QLED-based device continues to operate to enter a stable state, the zinc oxide film with low surface hydroxyl content makes the quantum dot luminescent layer negatively charged still occur and reach a dynamic equilibrium. In turn, the final electron injection efficiency is at a lower level, which constitutes a carrier injection balance with the hole injection efficiency. Therefore, the service life of the obtained QLED-based devices can also be significantly improved. In addition, the doping metal ions are partially dispersed on the ZnO surface, and to some extent play a role in passivating the surface defects of the ZnO layer. Therefore, the doped ZnO layer has an obvious effect of inhibiting the quenching of excitons by the surface defects of the ZnO layer. Coupled with a low-hydroxyl zinc oxide film, a final bilayer zinc oxide film structure has a more excellent device life (under the dual effects of suppressing surface defects on exciton quenching and low-hydroxyl zinc oxide achieving carrier injection balance during continuous work).

In the above embodiment, when the ETL is a bilayer zinc oxide film, each layer of zinc oxide film has a thickness of 10 nm to 100 nm. In this case, the zinc oxide film has an appropriate thickness and is not easily broken down by electrons, which is beneficial to maintain the injection performance, film quality, and surface smoothness of the ETL. Considering that the zinc oxide film or the metal-doped zinc oxide film (second ETL) with a surface hydroxyl content of greater than or equal to 0.6 has relatively low electron mobility, the film thickness should not be too high. Exemplarily, the zinc oxide film or the metal-doped zinc oxide film with a surface hydroxyl content of greater than or equal to 0.6 has a thickness of 10 nm to 30 nm. The zinc oxide film with surface hydroxyl content of less than or equal to 0.4 has higher electron mobility, so the film thickness can be appropriately higher. Exemplarily, the zinc oxide film or the metal-doped zinc oxide film (first ETL) with a surface hydroxyl content of less than or equal to 0.4 has a thickness of 20 nm to 60 nm.

In some of the above embodiments, the ETL includes n film lamination units, each of the film lamination units includes the first ETL and the second ETL, and n is greater than or equal to 2. The stacking method of the ETL may result in better energy level matching and increase the service life of the device to a greater extent. In some embodiments, n is an integer of greater than or equal to 2 and less than or equal to 9.

In a possible implementation manner, the ETL further includes a third ETL. That is, the ETL includes a zinc oxide film with a surface hydroxyl content of less than or equal to 0.4, that is, the first ETL, the second ETL, and the third ETL. The second ETL is a zinc oxide film or a metal-doped zinc oxide film with a surface hydroxyl content of greater than or equal to 0.6.

In one embodiment, the third ETL is a zinc oxide film with a surface hydroxyl content of less than or equal to 0.4.

In some embodiments, as shown in FIG. 2: the ETL 50 includes a zinc oxide film with a surface hydroxyl content of less than or equal to 0.4 (the first ETL 51), a zinc oxide film with a surface hydroxyl content of greater than or equal to 0.6 (the second ETL 52), and a zinc oxide film with a surface hydroxyl content of less than or equal to 0.4 (the third ETL 53). The third ETL 53 is arranged on a surface of the second ETL 52 at one side facing away from the first ETL 51. In this case, the electron mobility is further enhanced by two layers of ZnO films with low hydroxyl content. Therefore, the QLED-based device can easily reach the carrier injection equilibrium state when it continues to operate to enter a stable state, and thus obtain a desirable device service life. The zinc oxide film with high hydroxyl content can significantly reduce the injection of electrons in the quantum dot luminescent layer, and realize the balance of carrier injection in the initial stage of operation of QLED-based devices. Ultimately, QLED-based devices with higher EQE are obtained. The obtained QLED-based device maintains a high EQE at the initial stage of operation, while having a significant improvement in a final service life of the device. In addition, when the zinc oxide or doped zinc oxide colloidal solution with less surface hydroxyl is deposited on the quantum dot luminescent layer, it is beneficial to obtain a smoother zinc oxide film. Thus, the obtained QLED-based devices have both desirable EQE and device service life.

In some embodiments, as shown in FIG. 2: the ETL 50 includes a zinc oxide film (the first ETL 51) with a surface hydroxyl content of less than or equal to 0.4, a metal-doped zinc oxide film (the second ETL 52), and a zinc oxide film (the third ETL 53) with a surface hydroxyl content of less than or equal to 0.4. The third ETL 53 is arranged on a surface of the second ETL 52 at one side facing away from the first ETL 51. In this case: on the one hand, the two layers of ETLs with low hydroxyl content makes it easy for QLED-based devices to reach a carrier injection equilibrium state when they continue to operate to enter a stable state, thereby obtaining a good device service life. On the other hand, the zinc oxide of the second ETL contains doping metal ions, which can realize effective carrier injection regulation. In this way, a higher EQE can be obtained at the initial stage of device operation than that of a QLED-based device in which an undoped zinc oxide film is used as an ETL, such that the finally obtained QLED has both high EQE and device service life.

In one embodiment, the third ETL is a zinc oxide film with a surface hydroxyl content of greater than or equal to 0.6.

In some embodiments, the ETL includes a zinc oxide film with a surface hydroxyl content of less than or equal to 0.4 (the first ETL), a zinc oxide film with a surface hydroxyl content of greater than or equal to 0.6 (the second ETL), and a zinc oxide film with a surface hydroxyl content of greater than or equal to 0.6 (the third ETL). The third ETL is arranged on a surface of one side of the first ETL facing away from the second ETL. In this case, compared with an ETL including a first ETL with a surface hydroxyl content of 0.4 or less and a second ETL having a surface hydroxyl amount of 0.6 or more, this embodiment adds a layer of zinc oxide film with a surface hydroxyl content of greater than or equal to 0.6. In a QLED thus obtained, the two layers of zinc oxide films with high hydroxyl content formed by the second ETL and the third ETL endow the QLED with an excellent carrier balance state, thereby obtaining a higher EQE. Meanwhile, the first ETL can endow the device with better device service life, such that a finally obtained QLED has both higher EQE and device service life.

In some embodiments, the ETL includes a zinc oxide film with a surface hydroxyl content of less than or equal to 0.4 (the first ETL), a metal-doped zinc oxide film (the second ETL), and a zinc oxide film with a surface hydroxyl content of greater than or equal to 0.6 (the third ETL). The third ETL is arranged on a surface of one side of the first ETL facing away from the second ETL. In this case, the electron mobility is further enhanced by ZnO films with low hydroxyl content. Therefore, the QLED-based device can easily reach the carrier injection equilibrium state when it continues to operate to enter a stable state, and thus obtain a desirable device service life. The zinc oxide film with high hydroxyl content can reduce the injection of electrons in the quantum dot luminescent layer, and realize the balance of carrier injection in the initial stage of operation of QLED-based devices. Ultimately, QLED-based devices with higher EQE are obtained. Meanwhile, through the energy level matching optimization or electron mobility optimization of doped zinc oxide, the QLED-based device is already in a better carrier injection balance, and a higher external quantum efficiency (EQE) than that of QLED-based devices with undoped ZnO films as ETL can be obtained at the initial stage of device operation. Moreover, due to the low hydroxyl content on the surface of the doped zinc oxide film, the QLED-based device can easily reach the carrier injection equilibrium state when it continues to operate to enter a stable state. As a result, the QLED can obtain better device service life and maintain a high EQE in the early stage of operation.

In some embodiments, the ETL includes a zinc oxide film with a surface hydroxyl content of less than or equal to 0.4 (the first ETL), a metal-doped zinc oxide film (the second ETL), and a zinc oxide film with a surface hydroxyl content of greater than or equal to 0.6 (the third ETL). The third ETL is arranged on a surface of the second ETL at one side facing away from the first ETL. In this case, compared with the ETL containing only the first ETL and the second ETL, the additional third ETL, that is, the high-hydroxyl content ZnO film, can further increase the EQE of the initial state of the QLED-based device. The obtained QLEDs can achieve a high EQE in the early stage of operation, and have a desirable final device service life.

In some embodiments, the third ETL is a metal-doped zinc oxide film.

In some embodiments, the ETL includes a zinc oxide film with a surface hydroxyl content of less than or equal to 0.4 (the first ETL), a zinc oxide film with a surface hydroxyl content of greater than or equal to 0.6 (the second ETL), and a metal-doped zinc oxide film (the third ETL). The third ETL is arranged on a surface of one side of the first ETL facing away from the second ETL. In this case, the electron mobility is further enhanced by ZnO films with low hydroxyl content. Therefore, the QLED-based device can easily reach the carrier injection equilibrium state when it continues to operate to enter a stable state, and thus obtain a desirable device service life. The zinc oxide film with high hydroxyl content can reduce the injection of electrons in the quantum dot luminescent layer, and realize the balance of carrier injection in the initial stage of operation of QLED-based devices. Ultimately, QLED-based devices with higher EQE are obtained. Meanwhile, through the energy level matching optimization or electron mobility optimization of doped zinc oxide, the QLED-based device is already in a better carrier injection balance, and a higher external quantum efficiency (EQE) than that of QLED-based devices with undoped ZnO films as ETL can be obtained at the initial stage of device operation. Moreover, due to the low hydroxyl content on the surface of the doped zinc oxide film, the QLED-based device can easily reach the carrier injection equilibrium state when it continues to operate to enter a stable state. As a result, the QLED can obtain better device service life and maintain a high EQE in the early stage of operation. In some embodiments, a third ETL is arranged adjacent to the quantum dot luminescent layer. The doped zinc oxide colloidal solution is deposited on the quantum dot luminescent layer, and is beneficial to obtain a smoother zinc oxide film.

In some embodiments, the ETL includes a zinc oxide film with a surface hydroxyl content of less than or equal to 0.4 (the first ETL), a metal-doped zinc oxide film (the second ETL), and a metal-doped zinc oxide film (the third ETL). The third ETL is arranged on a surface of one side of the first ETL facing away from the second ETL. In this case, the electron mobility is further enhanced by the ZnO film with low hydroxyl content. This makes it easy for QLED-based devices to reach a carrier injection equilibrium state when they continue to operate to enter a stable state, thereby obtaining a desirable device life; metal-doped zinc oxide film. Thus, the obtained QLED-based devices have both desirable EQE and device service life.

It should be understood that, in the embodiment where the ETL includes a third ETL, the zinc oxide in the zinc oxide film with surface hydroxyl content less than or equal to 0.4 can be undoped zinc oxide or metal doped zinc oxide. Similarly, the zinc oxide in the zinc oxide film with surface hydroxyl content greater than or equal to 0.6 can be undoped zinc oxide or metal doped zinc oxide.

In embodiments where the ETL includes a third ETL, among some embodiments, the ETL has a thickness of 10 nm to 100 nm. In some embodiments, the zinc oxide film with the surface hydroxyl content of less than or equal to 0.4 has a thickness of 20 nm to 60 nm. In some embodiments, the zinc oxide film with a surface hydroxyl content of greater than or equal to 0.6 has a thickness of 10 nm to 30 nm. In some embodiments, the metal-doped zinc oxide film has a thickness of 10 nm to 30 nm. Since the second ETL is a zinc oxide film or a metal-doped zinc oxide film with a surface hydroxyl content of greater than or equal to 0.6, the second ETL has a thickness of 10 nm to 30 nm. The thickness of each layer is within this range such that the zinc oxide film has an appropriate thickness and is not easily broken down by electrons in this case. This is beneficial to maintain the injection performance, film formation quality, and surface smoothness of the ETL. In particular, the zinc oxide film or the metal-doped zinc oxide film with a surface hydroxyl content of greater than or equal to 0.6 has a relatively low electron mobility, so the thickness is relatively low; while the zinc oxide film with the surface hydroxyl content of less than or equal to 0.4 has a relatively high electron mobility and therefore relatively high thickness.

In the embodiment where the ETL includes a second ETL and the second ETL is a metal-doped zinc oxide film, and where the ETL includes a second ETL and a third ETL and the second ETL and/or the third ETL is a metal-doped zinc oxide film, the type of the doping metal, the effect of the doping metal, and the doping content of the doping metal in the metal-doped zinc oxide film are as described above (the case where the ETL is the first ETL). In order to save space, details are not repeated here.

In some embodiments, the doping metal in the metal-doped zinc oxide film is selected from at least one of Mg²⁺ and Mn²⁺. In some embodiments, the doping metal in the metal-doped zinc oxide film is selected from at least one of Al³⁺, Y³⁺, La³⁺, Li⁺, Gd³⁺, Zr⁴⁺, and Ce⁴⁺. The doping amount of each doping metal ion refers to the above descriptions, and will not be repeated here.

In the QLED provided by the embodiments of the present disclosure, the zinc oxide film with the surface hydroxyl content of less than or equal to 0.4 is used as a first ETL. In this way, the transmission of electrons to the quantum dot luminescent layer becomes smooth, and the electricity injected into the quantum dot luminescent layer increases. This makes the injection rate of electrons into the quantum dot luminescent layer higher than the injection rate of holes into the quantum dot luminescent layer, thus easily causing the quantum dots in the quantum dot luminescent layer to be negatively charged. This negatively charged state can be maintained due to a quantum dot core-shell structure and a binding effect of the electrically inert surface ligands. Meanwhile, a Coulomb repulsion effect makes the further injection of electrons into the quantum dot luminescent layer more and more difficult. When a QLED-based device continues to light up to a stable state, the negatively charged state of the quantum dots also tends to be stable. That is, the electrons newly captured and bound by the quantum dots and the electrons consumed by the radiative transition reach a dynamic balance, and the injection rate of electrons into the quantum dot luminescent layer is lower than that in the initial stage. At this time, a lower electron injection rate and a hole injection rate are unified to achieve a carrier injection balance, such that the service life of the device is improved. In other words, at the initial stage of QLED-based device operation, a high electron injection rate may make the QLED-based device in a carrier injection unbalanced state, which can affect the device performance. However, when the QLED-based device continues to light up to a steady state, the reduced electron injection rate can easily form a carrier injection balance with the hole injection rate. In this way, the continuous maintenance of the efficiency of the device is realized, thereby improving the service life of the QLED-based device.

On the other hand, an embodiment of the present disclosure provides a QLED, including an anode and a cathode that are oppositely arranged, a quantum dot luminescent layer arranged between the anode and the cathode, and an ETL arranged between the quantum dot luminescent layer and the cathode; where
the ETL includes zinc oxide, and at least a part of a surface of the zinc oxide includes an amino ligand and/or a carboxyl ligand with 3 to 7 carbon atoms.

The ETL includes zinc oxide, and at least a part of a surface of the zinc oxide includes an amino ligand and/or a carboxyl ligand with 3 to 7 carbon atoms. The introduction of the amino ligands and/or the carboxyl ligands can reduce the hydroxyl content on a surface of zinc oxide nanoparticles. Meanwhile, due to a short chain length of the coordinated amine/carboxyl ligands, a distance between the zinc oxide nanoparticles after film formation may not be significantly increased, thereby increasing the electron mobility of the zinc oxide ETL after film formation. In this way, the number of electrons injected by the ETL into the quantum dot luminescent layer increases. As a result, the injection rate of electrons into the quantum dot luminescent layer is higher than the injection rate of holes into the quantum dot luminescent layer, thus causing the quantum dots in the quantum dot luminescent layer to be negatively charged. This negatively charged state can be maintained due to a quantum dot core-shell structure and a binding effect of the electrically inert surface ligands. Meanwhile, a Coulomb repulsion effect makes the further injection of electrons into the quantum dot luminescent layer more and more difficult. When a QLED-based device continues to light up to a stable state, the negatively charged state of the quantum dots also tends to be stable. That is, the electrons newly captured and bound by the quantum dots and the electrons consumed by the radiative transition reach a dynamic balance, and the injection rate of electrons into the quantum dot luminescent layer is much lower than that in the initial stage. At this time, a lower electron injection rate and a hole injection rate just reach a carrier injection balance, such that the service life of the device is improved. In other words, at the initial stage of QLED-based device operation, a high electron injection rate may make the QLED-based device in a carrier injection unbalanced state, which can affect the device performance. However, when the QLED-based device continues to light up to a steady state, the reduced electron injection rate can form a carrier injection balance with the hole injection rate. In this way, the continuous maintenance of the efficiency of the device is realized, thereby effectively improving the service life of the QLED-based device.

In the embodiments of the present disclosure, a chain length of the amino ligands and/or the carboxyl ligands, that is, the number of carbon atoms, needs to be strictly controlled. When the chain length is too low, the acidity and basicity of the amino ligands and/or the carboxyl ligands may increase. When these ligands are added to the zinc oxide colloidal solution, they will react with zinc oxide nanoparticles in an acid-base manner, thus affecting the quality of the final zinc oxide film. When the chain length is too high, the distance between ZnO nanoparticles in the film will be increased under the effect of steric hindrance. This may reduce the electron mobility of ZnO ETL and is contrary to the purpose of original design. Exemplarily, the amino ligands and/or the carboxyl ligands with 3 to 7 carbon atoms is selected from at least one of propionic acid, propylamine, butyric acid, butylamine, hexanoic acid, and hexylamine. In some embodiments, the amino ligands and/or the carboxyl ligands has 4 to 6 carbon atoms, so as to increase the electron mobility of the ETL while having better film quality.

In some embodiments, the ETL includes the first ETL having the zinc oxide, and a surface of the zinc oxide forming the first ETL includes the amino ligands and/or the carboxyl ligands with 3 to 7 carbon atoms. The introduction of the amino ligands and/or the carboxyl ligands can reduce the hydroxyl content on a surface of zinc oxide nanoparticles. Meanwhile, due to a short chain length of the coordinated amine/carboxyl ligands, a distance between the zinc oxide nanoparticles after film formation may not be increased, thereby increasing the electron mobility of the zinc oxide ETL after film formation.

In some embodiments, the amino ligands and/or the carboxyl ligands with 3 to 7 carbon atoms and the zinc oxide are at a molar ratio of 1:4 to 4:1 in the zinc oxide film with the surface containing the amino ligands and/or the carboxyl ligands with 3 to 7 carbon atoms. In this case, the amino ligands and/or the carboxyl ligands on the surface of the zinc oxide nanoparticles has an appropriate content, which can reduce the hydroxyl content on the surface of the zinc oxide nanoparticles. In this way, the electron mobility of the ZnO-containing ETL is increased, thereby improving the device service life of the QLED. In some embodiments, the amino ligands and/or the carboxyl ligands has 3 to 4 carbon atoms; the amino ligands and/or the carboxyl ligands and the zinc oxide nanoparticles are at a molar ratio of 1:1 to 4:1. In some embodiments, the amino ligands and/or the carboxyl ligands has 5 to 7 carbon atoms; the amino ligands and/or the carboxyl ligands and the zinc oxide nanoparticles are at a molar ratio of 1:4 to 2:1. When the chain length is longer (5-7), the electron mobility of the sample after ligand exchange decreases, which is similar to the effect of increasing the hydroxyl content, so the amount of ligands with higher chain length should not be high. When the chain length is short (3-4), the electron mobility of the sample after ligand exchange will be enhanced, which is similar to the effect of reducing the hydroxyl content, so the amount of ligands with higher chain length can be higher.

In a possible implementation manner, the ETL includes only one film, and the film is the first ETL. That is, a material forming the ETL is zinc oxide, and the zinc oxide has the surface containing the amino ligands and/or the carboxyl ligands with 3 to 7 carbon atoms. In this case, the electronic-oriented quantum dot luminescent layer in the ETL has a small transmission resistance, which is conducive to negative charge of the quantum dots in the quantum dot luminescent layer. Under the constraints of the quantum dot structure (quantum dot core-shell structure and electrically inert surface ligands), the quantum dot maintains a negative point state and Coulomb repulsion effect. This makes the negatively charged state of the quantum dots also tend to be stable when the QLED-based device continues to light up to a stable state. At this time, the electrons newly captured and bound by the quantum dots and the electrons consumed by the radiative transition reach a dynamic balance, and the injection rate of electrons into the quantum dot luminescent layer is much lower than that in the initial stage. As a result, a lower electron injection rate and a hole injection rate just reach a carrier injection balance, such that the service life of the device is improved.

In some embodiments, the zinc oxide in the first ETL is undoped zinc oxide. That is, the ETL is made of zinc oxide with the surface containing the amino ligands and/or the carboxyl ligands with 3 to 7 carbon atoms, and the zinc oxide does not contain doping metal. It should be noted that the undoped ZnO film referred to in the embodiments of the present disclosure is a ZnO film relative to the metal-doped ZnO film. This means that the zinc oxide forming the zinc oxide film is not doped with other metal ions. That is, the undoped zinc oxide film is a pure zinc oxide film.

In some embodiments, the zinc oxide in the first ETL is metal-doped zinc oxide, that is, the zinc oxide in the ETL is metal-doped zinc oxide. It should be understood that the doping metal referred to in this application refers to other metal ions other than zinc ions doped into zinc oxide in the form of ions. When the doped zinc oxide obtained by doping metal elements in zinc oxide is used as the ETL material of QLED, it is beneficial for QLED-based devices to obtain higher device efficiency. However, the device service life is not ideal, even worse than that of QLEDs with undoped pure zinc oxide ETL. This is because the hydroxyl content on the surface of ZnO-doped ETLs changes when energy levels/oxygen vacancies (electron mobility) change. Therefore, in this embodiment, the effective carrier injection control is achieved by combining the metal-doped zinc oxide surface with the amino ligands and/or the carboxyl ligands with 3 to 7 carbon atoms. Specifically, compared with the adjustment of the hydroxyl content on the surface of the undoped zinc oxide film, when adjusting the hydroxyl content on the surface of the doped zinc oxide film. On the one hand, through the energy level matching optimization or electron mobility optimization of doped zinc oxide, the QLED-based device is already in a better carrier injection balance, and a higher external quantum efficiency (EQE) than that of QLED-based devices with undoped ZnO films as ETL can be obtained at the initial stage of device operation. On the other hand, since the surface of the doped zinc oxide film contains the amino ligands and/or the carboxyl ligands with 3 to 7 carbon atoms, the QLED-based device can also reach the carrier injection equilibrium state when it continues to operate to enter a stable state, and thus obtain a good device service life. Finally, QLEDs can obtain QLED-based devices with improved service life while maintaining a high EQE.

The selection of the doping metal in the metal-doped zinc oxide in this embodiment is as described above, and will not be repeated here. Exemplary, in some embodiments, the doping metal in the metal-doped zinc oxide is selected from at least one of Mg²⁺ and Mn²⁺. In some embodiments, the doping metal in the metal-doped zinc oxide is selected from at least one of Al³⁺, Y³⁺, La³⁺, Li⁺, Gd³⁺, Zr⁴⁺, and Ce⁴⁺.

In this embodiment, the doping amount of each doping metal ion refers to the above descriptions, and will not be repeated here.

In some embodiments, when the ETL is the first ETL, the first ETL (ETL) has a thickness of 10 nm to 100 nm.

In a possible implementation manner, the ETL further includes a second ETL, and the second ETL is a zinc oxide film with a surface hydroxyl content of greater than or equal to 0.6. That is to say, the ETL also includes a zinc oxide film with the surface containing the amino ligands and/or the carboxyl ligands with 3 to 7 carbon atoms and a zinc oxide film with a surface hydroxyl content of greater than or equal to 0.6, which are stacked along a direction perpendicular to the quantum dot luminescent layer or the cathode. In this case, when bilayer zinc oxide electron transport is used, the zinc oxide film with high hydroxyl content on the surface can reduce the injection of electrons into the quantum dot luminescent layer. This makes the electron injection efficiency of the QLED-based device lower at the initial stage of operation, and realizes the injection balance of carriers in the QLED-based device. At this time, the device is in the state of the same balance of carriers, and has a high external quantum efficiency. However, when the QLED device continues to operate to enter a stable state, due to the presence of zinc oxide film with the surface containing the amino ligands and/or the carboxyl ligands, the negatively charged state of the quantum dot luminescent layer may still occur, and it is easy to reach a dynamic equilibrium. Furthermore, the final electron injection efficiency is kept at a relatively low level, so as to form a carrier injection balance with the hole injection efficiency. Therefore, the service life of the obtained QLED-based devices can also be improved.

The first ETL and the second ETL are stacked, and the relative positions of the two can be flexibly set. In some embodiments, the second ETL is arranged on a surface of one side of the first ETL adjacent to the cathode. In this case, when the zinc oxide or metal-doped zinc oxide colloidal solution with less surface hydroxyl is deposited on the quantum dot luminescent layer, it is beneficial to obtain a more flat zinc oxide film. In some embodiments, the second ETL can also be arranged on a surface of one side of the first ETL adjacent to the quantum dot luminescent layer.

In some embodiments, both the first ETL and the second ETL are undoped zinc oxide film. That is, the first ETL and the second ETL are made of zinc oxide, and the zinc oxide does not contain doping metals, but the zinc oxide of the first ETL contains the amino ligands and/or the carboxyl ligands with 3 to 7 carbon atoms on the surface. In some embodiments, the ETL is composed of a first ETL whose surface contains the amino ligands and/or the carboxyl ligands with 3 to 7 carbon atoms and a second ETL with a surface hydroxyl content of greater than or equal to 0.6.

In some embodiments, the zinc oxide in at least one of the first ETL and the second ETL is metal-doped zinc oxide.

In some embodiments, the zinc oxide in the zinc oxide film (first ETL) containing the amino ligands and/or the carboxyl ligands with 3 to 7 carbon atoms on the surface is metal-doped zinc oxide; the zinc oxide film (the second ETL) with a surface hydroxyl content of greater than or equal to 0.6 is an undoped zinc oxide film. In this case, as mentioned above: on the one hand, the introduction of the amino ligands and/or the carboxyl ligands with 3 to 7 carbon atoms makes QLED-based devices to reach a carrier injection equilibrium state when they continue to operate to enter a stable state, thereby obtaining a good device service life. On the other hand, a high hydroxyl content can reduce the injected electrons in the quantum dot luminescent layer, and realize the balance of carrier injection in QLED-based devices, so as to finally obtain QLED-based devices with higher external quantum efficiency. In addition, metal ions are doped in the zinc oxide of the amino ligands and/or the carboxyl ligands with 3 to 7 carbon atoms to achieve effective carrier injection regulation. In the early stage of device operation, a higher EQE can be obtained than that of a QLED-based device in which an undoped zinc oxide film is used as an ETL, while the second ETL has a surface hydroxyl content of greater than or equal to 0.6. The synergy of the above two can improve the EQE of QLED-based devices more effectively. In this embodiment, the carrier injection balance of the QLED-based devices can be achieved by adjusting the hydroxyl content on the surface of the zinc oxide film. This does not require changing a structure of the device (inserting an EBL), nor does it require modification of the zinc oxide film by means such as doping. The whole process has simple operation, low cost, and good repeatability.

Exemplarily, the ETL is composed of a zinc oxide film (the first ETL) containing the amino ligands and/or the carboxyl ligands with 3 to 7 carbon atoms on the surface and an undoped zinc oxide film with a surface hydroxyl content of greater than or equal to 0.6 (the second ETL). The zinc oxide in the first ETL is metal-doped zinc oxide.

In some embodiments, the zinc oxide film (first ETL) containing the amino ligands and/or the carboxyl ligands with 3 to 7 carbon atoms on the surface is an undoped zinc oxide film; the zinc oxide in the zinc oxide film (the second ETL) with surface hydroxyl content of greater than or equal to 0.6 is metal-doped zinc oxide. In this case: on the one hand, the introduction of the amino ligands and/or the carboxyl ligands with 3 to 7 carbon atoms reduces the hydroxyl content on the surface of zinc oxide, such that QLED-based devices reach a carrier injection equilibrium state when they continue to operate to enter a stable state, thereby obtaining a good device service life. On the other hand, a high hydroxyl content can reduce the injected electrons in the quantum dot luminescent layer, and realize the balance of carrier injection in QLED-based devices, so as to finally obtain QLED-based devices with higher external quantum efficiency. In addition, metal ions are doped in zinc oxide with a surface hydroxyl content of greater than or equal to 0.6 to achieve effective carrier injection regulation. In the early stage of device operation, a higher EQE can be obtained than that of a QLED-based device in which an undoped zinc oxide film is used as an ETL, while the second ETL has a surface hydroxyl content of greater than or equal to 0.6. The synergy of the above two can improve the EQE of QLED-based devices more effectively.

Exemplarily, the ETL is composed of an undoped zinc oxide film (the first ETL) with the amino ligands and/or the carboxyl ligands with 3 to 7 carbon atoms and a zinc oxide film with a surface hydroxyl content of greater than or equal to 0.6 (the second ETL). The zinc oxide in the second ETL is metal-doped zinc oxide.

In some embodiments, the zinc oxide in the zinc oxide film (first ETL) containing the amino ligands and/or the carboxyl ligands with 3 to 7 carbon atoms on the surface is metal-doped zinc oxide; the zinc oxide in the zinc oxide film (the second ETL) with surface hydroxyl content of greater than or equal to 0.6 is metal-doped zinc oxide. In this case: on the one hand, the introduction of the amino ligands and/or the carboxyl ligands with 3 to 7 carbon atoms reduces the hydroxyl content on the surface of zinc oxide, such that QLED-based devices reach a carrier injection equilibrium state when they continue to operate to enter a stable state, thereby obtaining a good device service life. On the other hand, a high hydroxyl content can reduce the injected electrons in the quantum dot luminescent layer, and realize the balance of carrier injection in QLED-based devices, so as to finally obtain QLED-based devices with higher external quantum efficiency. In addition, metal ions are all doped in zinc oxide with the surface containing the amino ligands and/or the carboxyl ligands with 3 to 7 carbon atoms and zinc oxide with surface hydroxyl content of less than or equal to 0.4 to achieve effective carrier injection regulation. In the early stage of device operation, a higher EQE can be obtained than that of a QLED-based device in which an undoped zinc oxide film is used as an ETL, while the second ETL has a surface hydroxyl content of greater than or equal to 0.6. The synergy of the above three can significantly improve the EQE of QLED-based devices.

Exemplarily, the ETL is composed of a zinc oxide film (the first ETL) containing the amino ligands and/or the carboxyl ligands with 3 to 7 carbon atoms on the a zinc oxide film with a surface hydroxyl content of greater than or equal to 0.6 (the second ETL). The zinc oxide in the first ETL and the second ETL are both metal-doped zinc oxide.

In an implementation of the embodiment, as shown in FIG. 1: the ETL 50 is composed of a first ETL 51 and a second ETL 52, and the first ETL 51 is closer to the quantum dot luminescent layer 40 than the first ETL 52; that is, the second ETL 52 is adjacent to the cathode 60. When the zinc oxide colloidal solution containing the amino ligands and/or the carboxyl ligands with 3 to 7 carbon atoms on the surface is deposited on the quantum dot luminescent layer, it is beneficial to obtain a smoother zinc oxide film.

In some embodiments, the ETL includes a first ETL and a second ETL, the second ETL is arranged on a surface of one side of the first ETL adjacent to the cathode or the quantum dot luminescent layer, and the second ETL is a metal-doped zinc oxide film. In this case, the external quantum efficiency (EQE) of QLED is optimized directly by doping zinc oxide energy level matching optimization or electron mobility optimization; electron mobility is reduced through the first ETL, the QLED-based device can also reach the carrier injection balance state when it continues to operate to enter a stable state, and then obtain a desirable device service life.

Exemplarily, as shown in FIG. 1: the ETL 50 includes a first ETL 51 and a second ETL 52; the second ETL 52 is a metal-doped zinc oxide film, and the second ETL 52 is arranged on a surface of the first ETL 51 at one side adjacent to the cathode 60; that is, the first ETL 51 is adjacent to the quantum dot luminescent layer 40. In this case, the external quantum efficiency (EQE) of QLED is optimized directly by doping zinc oxide energy level matching optimization or electron mobility optimization; electron mobility is reduced through the first ETL, the QLED-based device can also reach the carrier injection balance state when it continues to operate to enter a stable state, and then obtain a desirable device service life. In addition, the metal-doped zinc oxide colloidal solution is deposited on the quantum dot luminescent layer, and is beneficial to obtain a smoother zinc oxide film.

In the above embodiment, when the ETL is a bilayer zinc oxide film, each layer of zinc oxide film has a thickness of 10 nm to 100 nm. In this case, the zinc oxide film has an appropriate thickness and is not easily broken down by electrons, which is beneficial to maintain the injection performance, film quality, and surface smoothness of the ETL. Considering that the zinc oxide film or the metal-doped zinc oxide film (second ETL) with a surface hydroxyl content of greater than or equal to 0.6 has relatively low electron mobility, the film thickness should not be too high. Exemplarily, the zinc oxide film or the metal-doped zinc oxide film with a surface hydroxyl content of greater than or equal to 0.6 has a thickness of 10 nm to 30 nm. The zinc oxide or metal-doped zinc oxide film (first ETL) containing the amino ligands and/or the carboxyl ligands with 3 to 7 carbon atoms on the surface has relatively high electron mobility, so the film thickness can be appropriately higher. Exemplarily, the zinc oxide film (the first ETL) containing the amino ligands and/or the carboxyl ligands with 3 to 7 carbon atoms on the surface has a thickness of 10 nm to 80 nm. The metal-doped zinc oxide film has a thickness of 20 nm to 60 nm.

In some of the above embodiments, the ETL includes n film lamination units, each of the film lamination units includes the first ETL and the second ETL, and n is greater than or equal to 2. The stacking method of the ETL may result in better energy level matching and increase the service life of the device to a greater extent. In some embodiments, n is an integer of greater than or equal to 2 and less than or equal to 9.

In a possible implementation manner, the ETL further includes a third ETL. That is, the ETL includes the first ETL, the second ETL, and the third ETL having a surface hydroxyl content of less than or equal to 0.4. The second ETL is a zinc oxide film or a metal-doped zinc oxide film with a surface hydroxyl content of greater than or equal to 0.6.

In some embodiments, the third ETL is a zinc oxide film with a surface hydroxyl content of less than or equal to 0.4.

In some embodiments, as shown in FIG. 2: the ETL 50 includes a zinc oxide film with the amino ligands and/or the carboxyl ligands with 3 to 7 carbon atoms on the surface (the first ETL 51), a zinc oxide film with a surface hydroxyl content of greater than or equal to 0.6 (the second ETL 52), and a zinc oxide film with a surface hydroxyl content of less than or equal to 0.4 (the third ETL 53). The third ETL 53 is arranged on a surface of the second ETL 52 at one side facing away from the first ETL 51. In this case, there are a zinc oxide film with low hydroxyl content and a zinc oxide film whose surface contains the amino ligands and/or the carboxyl ligands with 3 to 7 carbon atoms. Therefore, the QLED-based device can also reach the carrier injection equilibrium state when it continues to operate to enter a stable state, and thus obtain a desirable device service life. The zinc oxide film with high hydroxyl content can reduce the injection of electrons in the quantum dot luminescent layer, and realize the balance of carrier injection during the operation of QLED-based devices. Ultimately, QLED-based devices with higher EQE are obtained. In addition, when the zinc oxide or doped zinc oxide colloidal solution with less surface hydroxyl is deposited on the quantum dot luminescent layer, it is beneficial to obtain a smoother zinc oxide film. Thus, the obtained QLED-based devices have both desirable EQE and device service life.

In some embodiments, as shown in FIG. 2: the ETL 50 includes a first ETL 51 whose surface contains an amino ligand and/or a carboxyl ligand with 3 to 7 carbon atoms, a metal-doped zinc oxide film (the second ETL 52), and a third ETL 53 with a surface hydroxyl content of less than or equal to 0.4. The third ETL 53 is arranged on a surface of the second ETL 52 at one side facing away from the first ETL 51. In this case, there are a zinc oxide film with low hydroxyl content and a zinc oxide film whose surface contains the amino ligands and/or the carboxyl ligands with 3 to 7 carbon atoms. Therefore, the QLED-based device can also reach the carrier injection equilibrium state when it continues to operate to enter a stable state, and thus obtain a desirable device service life. The zinc oxide film with high hydroxyl content can reduce the injection of electrons in the quantum dot luminescent layer, and realize the balance of carrier injection during the operation of QLED-based devices. Ultimately, QLED-based devices with higher EQE are obtained. In addition, when the zinc oxide or doped zinc oxide colloidal solution with less surface hydroxyl is deposited on the quantum dot luminescent layer, it is beneficial to obtain a smoother zinc oxide film. Through the energy level matching optimization or electron mobility optimization of doped zinc oxide, the QLED-based device is already in a better carrier injection balance, and a higher external quantum efficiency (EQE) than that of QLED-based devices with undoped ZnO films as ETL can be obtained at the initial stage of device operation. Moreover, due to the low hydroxyl content on the surface of the doped zinc oxide film, the QLED-based device can also reach the carrier injection equilibrium state when it continues to operate to enter a stable state. As a result, the QLED can obtain better device service life and maintain a high EQE in the early stage of operation.

In some embodiments, the third ETL is a zinc oxide film whose surface contains the amino ligands and/or the carboxyl ligands with 3 to 7 carbon atoms.

In some embodiments, as shown in FIG. 2: the ETL 50 includes a first ETL 51 whose surface contains an amino ligand and/or a carboxyl ligand with 3 to 7 carbon atoms, a second ETL 52 with a surface hydroxyl content of greater than or equal to 0.6, and a third ETL 53 whose surface contains the amino ligands and/or the carboxyl ligands with 3 to 7 carbon atoms. The third ETL 53 is arranged on a surface of the second ETL 52 at one side facing away from the first ETL 51. In this case, there are two zinc oxide films whose surfaces contain the amino ligands and/or the carboxyl ligands with 3 to 7 carbon atoms. Therefore, the QLED-based device can also reach the carrier injection equilibrium state when it continues to operate to enter a stable state, and thus obtain a desirable device service life. The zinc oxide film with high hydroxyl content can reduce the injection of electrons in the quantum dot luminescent layer, and realize the balance of carrier injection during the operation of QLED-based devices. Ultimately, QLED-based devices with higher EQE are obtained. In addition, when the zinc oxide or doped zinc oxide colloidal solution with less surface hydroxyl is deposited on the quantum dot luminescent layer, it is beneficial to obtain a smoother zinc oxide film. Thus, the obtained QLED-based devices have both desirable EQE and device service life.

In some embodiments, as shown in FIG. 2: the ETL 50 includes a first ETL 51 whose surface contains an amino ligand and/or a carboxyl ligand with 3 to 7 carbon atoms, a metal-doped zinc oxide film (the second ETL 52), and a third ETL 53 whose surface contains the amino ligands and/or the carboxyl ligands with 3 to 7 carbon atoms. The third ETL 53 is arranged on a surface of the second ETL 52 at one side facing away from the first ETL 51. In this case, there are two zinc oxide films whose surfaces contain the amino ligands and/or the carboxyl ligands with 3 to 7 carbon atoms. This enables the QLED-based device to achieve a carrier injection equilibrium state when it continues to work to a steady state, thereby obtaining a desirable device service life. Through the energy level matching optimization or electron mobility optimization of doped zinc oxide, the QLED-based device is already in a better carrier injection balance, and a higher external quantum efficiency (EQE) than that of QLED-based devices with undoped ZnO films as ETL can be obtained at the initial stage of device operation. Moreover, due to the low hydroxyl content on the surface of the doped zinc oxide film, the QLED-based device can also reach the carrier injection equilibrium state when it continues to operate to enter a stable state. As a result, the QLED can obtain better device service life and maintain a high EQE in the early stage of operation.

In some embodiments, the third ETL is a zinc oxide film with a surface hydroxyl content of greater than or equal to 0.6.

In some embodiments, the ETL includes a first ETL whose surface contains an amino ligand and/or a carboxyl ligand with 3 to 7 carbon atoms, a second ETL with surface hydroxyl content of greater than or equal to 0.6, and a third ETL with surface hydroxyl content of greater than or equal to 0.6. The third ETL is arranged on a surface of one side of the first ETL away from the second ETL. In this case, there are two zinc oxide films whose surfaces contain the amino ligands and/or the carboxyl ligands with 3 to 7 carbon atoms. Therefore, the QLED-based device can also reach the carrier injection equilibrium state when it continues to operate to enter a stable state, and thus obtain a desirable device service life. The two zinc oxide films with high hydroxyl content can reduce the injection of electrons in the quantum dot luminescent layer, and realize the balance of carrier injection during the operation of QLED-based devices. Ultimately, QLED-based devices with higher EQE are obtained. In addition, when the zinc oxide or doped zinc oxide colloidal solution with less surface hydroxyl is deposited on the quantum dot luminescent layer, it is beneficial to obtain a smoother zinc oxide film. Thus, the obtained QLED-based devices have both desirable EQE and device service life.

In some embodiments, the ETL includes a first ETL whose surface contains amino ligands and/or carboxyl ligand with 3 to 7 carbon atoms, a metal-doped zinc oxide film (the second ETL), and a third ETL with surface hydroxyl content of greater than or equal to 0.6. The third ETL is arranged on a surface of one side of the first ETL facing away from the second ETL. In this case, there are two zinc oxide films whose surfaces contain the amino ligands and/or the carboxyl ligands with 3 to 7 carbon atoms. Therefore, the QLED-based device can also reach the carrier injection equilibrium state when it continues to operate to enter a stable state, and thus obtain a desirable device service life. The two zinc oxide films with high hydroxyl content can reduce the injection of electrons in the quantum dot luminescent layer, and realize the balance of carrier injection during the operation of QLED-based devices. Ultimately, QLED-based devices with higher EQE are obtained. Through the energy level matching optimization or electron mobility optimization of doped zinc oxide, the QLED-based device is already in a better carrier injection balance, and a higher external quantum efficiency (EQE) than that of the QLED-based devices with undoped ZnO films as ETL can be obtained at the initial stage of device operation. Moreover, due to the low hydroxyl content on the surface of the doped zinc oxide film, the QLED-based device can also reach the carrier injection equilibrium state when it continues to operate to enter a stable state. As a result, the QLED can obtain better device service life and maintain a high EQE in the early stage of operation.

In some embodiments, the third ETL is a metal-doped zinc oxide film.

In some embodiments, the ETL includes a first ETL whose surface contains an amino ligand and/or a carboxyl ligand with 3 to 7 carbon atoms, a metal-doped zinc oxide film (the second ETL), and a metal-doped zinc oxide film (third ETL). The third ETL is arranged on a surface of one side of the first ETL facing away from the second ETL. In this case, there are two zinc oxide films whose surfaces contain the amino ligands and/or the carboxyl ligands with 3 to 7 carbon atoms. This enables the QLED-based device to achieve a carrier injection equilibrium state when it continues to work to a steady state, thereby obtaining a desirable device service life. Through the energy level matching optimization or electron mobility optimization of doped zinc oxide, the QLED-based device is already in a better carrier injection balance, and a higher external quantum efficiency (EQE) than that of QLED-based devices with undoped ZnO films as ETL can be obtained at the initial stage of device operation. Moreover, due to the low hydroxyl content on the surface of the doped zinc oxide film, the QLED-based device can also reach the carrier injection equilibrium state when it continues to operate to enter a stable state. As a result, the QLED can obtain better device service life and maintain a high EQE in the early stage of operation.

It should be understood that, in the embodiment where the ETL includes a third ETL, the zinc oxide film with the surface hydroxyl content of less than or equal to 0.4 may be an undoped zinc oxide film or a metal-doped zinc oxide film; similarly, the zinc oxide film with a surface hydroxyl content of greater than or equal to 0.6 may be an undoped zinc oxide film or a metal-doped zinc oxide film.

In embodiments where the ETL includes a third ETL, among some embodiments, the ETL has a thickness of 10 nm to 100 nm. In some embodiments, the zinc oxide film containing the amino ligands and/or the carboxyl ligands with 3 to 7 carbon atoms on the surface has a thickness of 10 nm to 80 nm. In some embodiments, the zinc oxide film with the surface hydroxyl content of less than or equal to 0.4 has a thickness of 20 nm to 60 nm. In some embodiments, the zinc oxide film with a surface hydroxyl content of greater than or equal to 0.6 has a thickness of 10 nm to 30 nm. In some embodiments, the metal-doped zinc oxide film has a thickness of 10 nm to 30 nm. Since the second ETL is a zinc oxide film or a metal-doped zinc oxide film with a surface hydroxyl content of greater than or equal to 0.6, the second ETL has a thickness of 10 nm to 30 nm. The thickness of each layer is within this range such that the zinc oxide film has an appropriate thickness and is not easily broken down by electrons in this case. This is beneficial to maintain the injection performance, film formation quality, and surface smoothness of the ETL. In particular, the zinc oxide film or the metal-doped zinc oxide film with a surface hydroxyl content of greater than or equal to 0.6 has a relatively low electron mobility, so the thickness is relatively low; while the zinc oxide film whose surface contains the amino ligands and/or the carboxyl ligands with 3 to 7 carbon atoms, or the zinc oxide film with the surface hydroxyl content of less than or equal to 0.4 has a relatively high electron mobility and therefore relatively high thickness.

In the embodiment where the ETL includes a second ETL and the second ETL is a metal-doped zinc oxide film, and where the ETL includes a second ETL and a third ETL and the second ETL and/or the third ETL is a metal-doped zinc oxide film, the type of the doping metal, the effect of the doping metal, and the doping content of the doping metal in the metal-doped zinc oxide film are as described above (the case where the ETL is the first ETL). In order to save space, details are not repeated here.

In some embodiments, the doping metal in the metal-doped zinc oxide film is selected from at least one of Mg²⁺ and Mn²⁺. In some embodiments, the doping metal in the metal-doped zinc oxide film is selected from at least one of Al³⁺ Y^{3′}, La³⁺, Li⁺, Gd³⁺, Zr⁴⁺, and Ce⁴⁺. The doping amount of each doping metal ion refers to the above descriptions, and is not repeatedly described herein.

In a possible implementation, the above two QLEDs provided in the embodiments of the present disclosure (a first type is ETL including the first ETL, and the first ETL being a zinc oxide film with a surface hydroxyl content of less than or equal to 0.4; a second type is ETL including zinc oxide, and at least a part of a surface of the zinc oxide having the amino ligands and/or the carboxyl ligands with 3 to 7 carbon atoms) are shown in FIG. 3. The QLED includes an anode 10 and a cathode 60 that are oppositely arranged, a quantum dot luminescent layer 40 arranged between the cathode 60 and the anode 10, and an ETL 50 arranged between the cathode 60 and the quantum dot luminescent layer 40.

In some embodiments, the QLED further includes a hole functional layer arranged between the anode 10 and the quantum dot luminescent layer 40. The hole functional layer includes at least one of an HTL, an HIL, and an EBL. In some embodiments, the QLED further includes an electron injection layer (EIL) arranged between the cathode 60 and the ETL 50.

In the above embodiments, the QLED may further include a substrate, and the anode 10 or the cathode 60 is arranged on the substrate.

The QLED provided in the embodiments of the present disclosure is classified into an upright QLED and an inverted QLED.

In some embodiments, the upright QLED includes an anode 10 and a cathode 60 that are oppositely arranged, a quantum dot luminescent layer 40 arranged between the anode 10 and the cathode 60, and an ETL 50 arranged between the cathode 60 and the quantum dot luminescent layer 40, and the anode 10 is arranged on a substrate. In some embodiments, an HTL 30 is provided between the anode 10 and the quantum dot luminescent layer 40; further, an HIL 20 is provided between the anode 10 and the HTL; and/or, an EIL is provided between cathode 60 and the ETL 50. In some embodiments of the upright QLED, as shown in FIG. 4: the QLED includes a substrate 100, an anode 10 arranged on a surface of the substrate 100, an HIL 20 arranged on a surface of the anode 10, an HTL arranged on a surface of the HIL 20, a quantum dot luminescent layer 40 arranged on a surface of the HTL, an ETL 50 arranged on a surface of the quantum dot luminescent layer 40, and a cathode 60 arranged on a surface of the ETL 50.

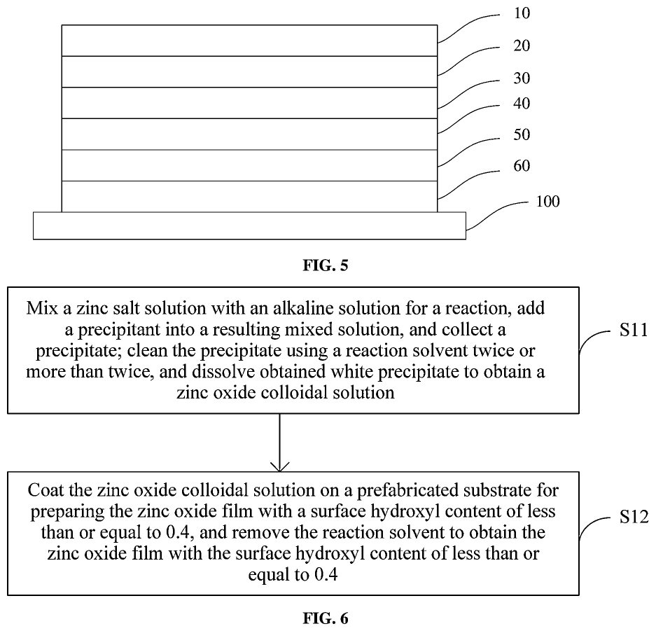

In some embodiments, the inverted QLED includes a laminated structure of an anode 10 and a cathode 60 that are oppositely arranged, a quantum dot luminescent layer 40 arranged between the anode 10 and the cathode 60, and an ETL 50 arranged between the cathode 60 and the quantum dot luminescent layer 40, and the cathode 60 is arranged on a substrate. In some embodiments, an HTL 30 is provided between the anode 10 and the quantum dot luminescent layer 40; further, an HIL 20 is provided between the anode 10 and the HTL; and/or, an EIL is provided between cathode 60 and the ETL 50. In some embodiments of the inverted QLED, as shown in FIG. 5: the QLED includes a substrate 100, a cathode 60 arranged on a surface of the substrate 100, an ETL 50 arranged on a surface of the cathode 60, a quantum dot luminescent layer 40 arranged on a surface of the ETL 50, an HTL arranged on a surface of the quantum dot luminescent layer 40, an HIL 20 arranged on a surface of the HTL, and an anode 10 arranged on a surface of the HIL 20.

In the above embodiments, the substrate 100 may be a rigid substrate or a flexible substrate. Specifically, glass, silicon wafer, polycarbonate, polymethyl methacrylate, poalkaline solutionthylene terephthalate, poalkaline solutionthylene naphthalate, polyamide, and poalkaline solutionthersulfone can be selected. It is either a composition formed of at least two of the above materials, or a laminated structure formed of at least two of the above materials.

In some embodiments, a material of the HIL 20 can be selected from at least one of poly(3,4-ethylenedioxythiophene):poly(styrene sulfonate) (PEDOT:PSS), HTL-1, and HTL-2. Of course, other hole injection materials with high injection performance can also be used.

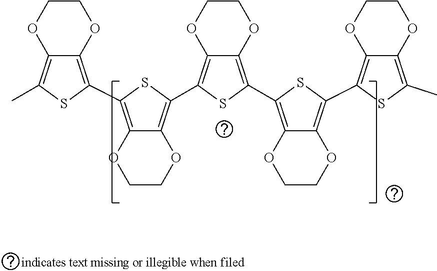

The PEDOT:PSS has the following structure:

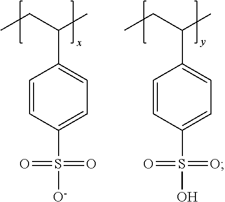

the HTL-1 has the following structure:

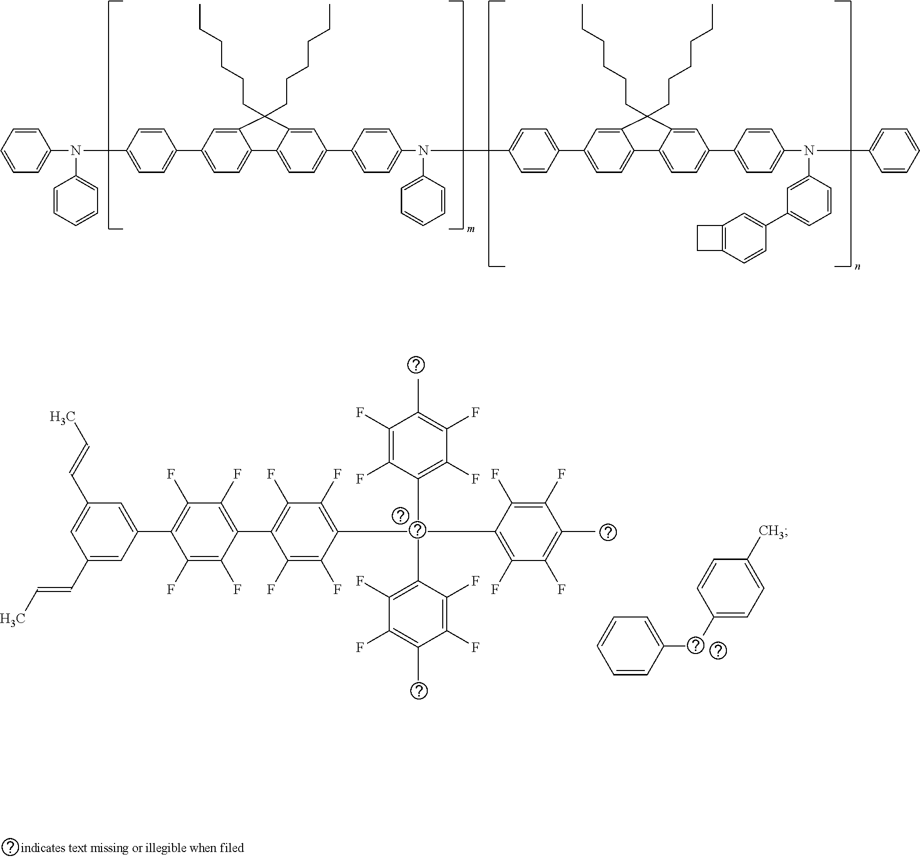

and
the HTL-2 has the following structure:

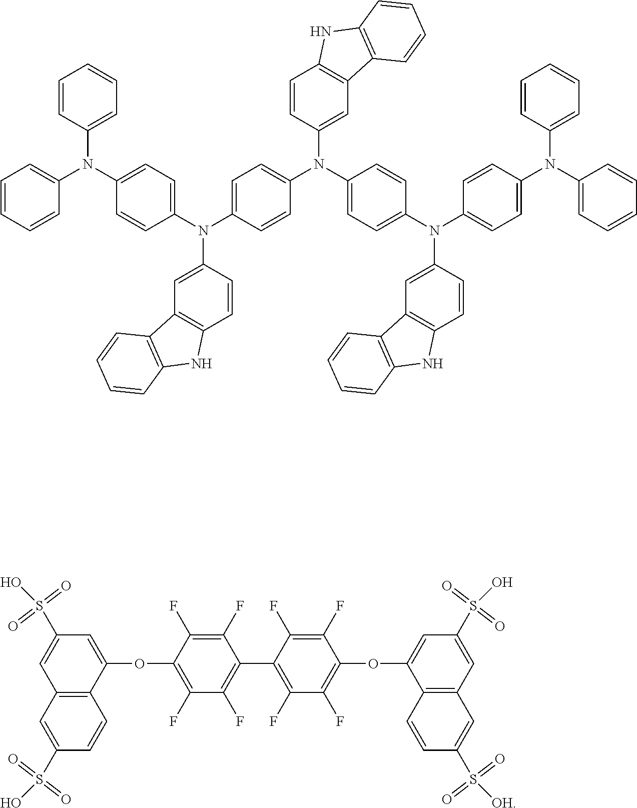 [SMILES: c1ccc(N(c2ccccc2)c2ccc(N(c3ccc(N(c4ccc(N(c5ccc(N(c6ccccc6)c6ccccc6)cc5)c5ccc6[nH]c7ccccc7c6c5)cc4)c4ccc5[nH]c6ccccc6c5c4)cc3)c3ccc4[nH]c5ccccc5c4c3)cc2)cc1 ; O=S(=O)(O)c1ccc2c(Oc3c(F)c(F)c(-c4c(F)c(F)c(Oc5cc(S(=O)(=O)O)cc6cc(S(=O)(=O)O)ccc56)c(F)c4F)c(F)c3F)cc(S(=O)(=O)O)cc2c1]

In some embodiments, a material of the HTL 30 can be a conventional hole transport material. Exemplarily, the material of the HTL 30 is selected from at least one of 4, 4′-N, N′-dicarbazolyl-biphenyl (CBP), poly[(9, 9′-dioctylfluorene-2, 7-diyl)-co-(4, 4′-(N-(4-sec-butylphenyl)diphenylamine))] (TFB), poly(4-butylphenyl-diphenylamine) (poly-TPD), 4, 4′, 4′-tris(N-carbazolyl)-triphenylamine (TCTA), and poly(N-vinylcarbazole) (PVK), and a derivative thereof. Certainly, the material of the HTL 30 may also be other hole transport materials with high injection performance.

The quantum dots in the quantum dot luminescent layer 40 are one of red, green and blue quantum dots, and may also be yellow quantum dots. The quantum dots can be cadmium-containing or cadmium-free. In some embodiments, a quantum dot in the quantum dot luminescent layer 40 is selected from the group consisting of a single-core quantum dot and a core-shell quantum dot; and a core compound and a shell compound of the quantum dot can be independently selected from at least one of CdS, CdSe, CdTe, ZnO, ZnS, ZnSe, ZnTe, GaAs, GaP, GaSb, HgS, HgSe, HgTe, InAs, InP, InSb, AlAs, AlP, CuInS, and CuInSe, and a core-shell quantum dot or an alloy quantum dot formed by the above substances. The quantum dot luminescent layer thus formed has wide excitation spectrum, continuous distribution, and high stability of emission spectrum.

In the embodiments of the present disclosure, the material and thickness of the ETL 50 are as above, and will not be repeated here. The ETL has a thickness of 10 nm to 100 nm. When the ETL has a thickness less than 10 nm, the film layer is easily broken down by electrons, and it is difficult to ensure the carrier injection performance; when the ETL has a thickness greater than 100 nm, it may hinder the injection of electrons and affect the charge injection balance of the device.

Common bottom electrode materials can be used for a bottom electrode (the anode 10 combined on the substrate 100 or the cathode 60 combined on the substrate). In some embodiments, a material of the bottom electrode includes at least one of zinc oxide, indium oxide, tin oxide, indium tin oxide (ITO), indium zinc oxide (IZO), and fluorine-doped tin oxide.

In some embodiments, a top electrode (the anode 10 or cathode 60 remote from the substrate 100) is a transparent oxide, a thin metal, or a combination of both. In some embodiments, the transparent oxide can be ITO, IZO, AZO. In some embodiments, the thin metal can be Ag, Al, Au, Mg, Ca, Yb, and Ba or alloys thereof. In some embodiments, the top electrode can also be O/M/O, where M is Ag, Al, Au, Mg, Ca, Yb, and Ba or their alloys; and O is an oxide, including but not limited to ITO, IZO, and AZO.

In the QLED provided in the embodiments of the present disclosure, the ETL includes zinc oxide, and at least a part of a surface of the zinc oxide includes an amino ligand and/or a carboxyl ligand with 3 to 7 carbon atoms. The introduction of the amino ligands and/or the carboxyl ligands can reduce the hydroxyl content on a surface of zinc oxide nanoparticles. Meanwhile, due to a short chain length of the coordinated amine/carboxyl ligands, a distance between the zinc oxide nanoparticles after film formation may not be increased, thereby increasing the electron mobility of the zinc oxide ETL after film formation. In this way, the number of electrons injected by the ETL into the quantum dot luminescent layer increases. As a result, the injection rate of electrons into the quantum dot luminescent layer is higher than the injection rate of holes into the quantum dot luminescent layer, thus causing the quantum dots in the quantum dot luminescent layer to be negatively charged. This negatively charged state can be maintained due to a quantum dot core-shell structure and a binding effect of the electrically inert surface ligands. Meanwhile, a Coulomb repulsion effect makes the further injection of electrons into the quantum dot luminescent layer more and more difficult. When a QLED-based device continues to light up to a stable state, the negatively charged state of the quantum dots also tends to be stable. That is, the electrons newly captured and bound by the quantum dots and the electrons consumed by the radiative transition reach a dynamic balance, and the injection rate of electrons into the quantum dot luminescent layer is much lower than that in the initial stage. At this time, a lower electron injection rate and a hole injection rate just reach a carrier injection balance, such that the service life of the device is improved. In other words, at the initial stage of QLED-based device operation, a high electron injection rate may make the QLED-based device in a carrier injection unbalanced state, which can affect the device performance. However, when the QLED-based device continues to light up to a steady state, the reduced electron injection rate can form a carrier injection balance with the hole injection rate. In this way, the continuous maintenance of the efficiency of the device is realized, thereby effectively improving the service life of the QLED-based device.

It should be noted that, in the embodiments of the present disclosure, the determination of the hydroxyl content on the surface of the zinc oxide film is conducted on the zinc oxide film by XPS. Specifically, in the XPS detection results, the O1s energy spectrum can be divided into three sub-peaks, which are an OM peak representing the molar concentration of oxygen atoms in the zinc oxide crystal (the peak position is between 529 ev to 531 ev), an OV peak representing the molar concentration of oxygen vacancies in zinc oxide crystals (peak position at 531 ev to 532 ev), and an OH peak representing the molar concentration of hydroxyl ligands on the ZnO crystal surface (peak position at 532 ev to 534 ev). The area ratio between each sub-peak represents the molar concentration ratio of different kinds of oxygen atoms in the ZnO film. Therefore, the hydroxyl content on the surface of zinc oxide film is defined as: OH peak area/OM peak area. That is, the hydroxyl content on the surface of the zinc oxide film is a ratio of the molar concentration of hydroxyl ligands on the surface of the zinc oxide film to the molar concentration of oxygen atoms in the zinc oxide crystal.

The QLEDs provided in the embodiments of this application can be prepared by various methods. The following provides examples of three methods for preparing the QLED of the present disclosure.

In the first embodiment, an embodiment of the present disclosure provides a preparation method of the QLED, where the QLED includes an anode and a cathode that are oppositely arranged, a quantum dot luminescent layer arranged between the anode and the cathode, and an ETL arranged between the quantum dot luminescent layer and the cathode. The ETL includes a first ETL, and the first ETL is a zinc oxide film with a surface hydroxyl content of less than or equal to 0.4; and
as shown in FIG. 6, a preparation method of the zinc oxide film with the surface hydroxyl content of less than or equal to 0.4 includes the following steps:

S11, mixing a zinc salt solution with a alkaline solution for a reaction, adding a precipitant into a mixed solution after the reaction, and collecting a precipitate; cleaning the precipitate using a reaction solvent twice or more than twice, and dissolving an obtained white precipitate to obtain a zinc oxide colloidal solution; and

S12, coating the zinc oxide colloidal solution on a prefabricated substrate for preparing the zinc oxide film with the surface hydroxyl content of less than or equal to 0.4, and removing a solvent to obtain the zinc oxide film with the surface hydroxyl content of less than or equal to 0.4.

In the preparation method of the QLED provided in the embodiment of the present disclosure, a zinc oxide colloidal solution is prepared by a solution method as a film-forming solution of a zinc oxide film with a surface hydroxyl content of less than or equal to 0.4. During the preparation process of the zinc oxide colloidal solution by the solution method, an obtained precipitate is washed twice or more than twice with a reaction solvent, so as to obtain zinc oxide with a surface hydroxyl content of less than or equal to 0.4. The zinc oxide film with the surface hydroxyl content of less than or equal to 0.4 is used as a first ETL. In this way, the transmission of electrons to the quantum dot luminescent layer becomes smooth, and the electricity injected into the quantum dot luminescent layer increases. This makes the injection rate of electrons into the quantum dot luminescent layer higher than the injection rate of holes into the quantum dot luminescent layer, thus causing the quantum dots in the quantum dot luminescent layer to be negatively charged. This negatively charged state can be maintained due to a quantum dot core-shell structure and a binding effect of the electrically inert surface ligands. Meanwhile, a Coulomb repulsion effect makes the further injection of electrons into the quantum dot luminescent layer more and more difficult. When a QLED-based device continues to light up to a stable state, the negatively charged state of the quantum dots also tends to be stable. That is, the electrons newly captured and bound by the quantum dots and the electrons consumed by the radiative transition reach a dynamic balance, and the injection rate of electrons into the quantum dot luminescent layer is much lower than that in the initial stage. At this time, a lower electron injection rate and a hole injection rate are easily to achieve a carrier injection balance, such that the service life of the device is improved.

In the embodiments of the present disclosure, the composition of the QLED, especially the situation of the ETL, is as described in the first aspect above. In order to save space, details are not repeated here.

In the step S11, the zinc oxide colloidal solution is prepared by a solution method, and the solution method may be one of an alcoholysis method, a hydrolysis method, and the like. A basic process of preparing zinc oxide by the solution method is: mixing the zinc salt solution with the alkaline solution for a reaction, to form a hydroxide intermediate such as zinc hydroxide; and subjecting the hydroxide intermediate to polycondensation to gradually generate zinc oxide nanoparticles.

In the embodiments of the present disclosure, the zinc salt solution is a salt solution formed by dissolving zinc salt in a solvent. The zinc salt is selected to react with the alkaline solution to generate zinc hydroxide, and includes but is not limited to one of zinc acetate, zinc nitrate, zinc sulfate, and zinc chloride. The solvent is selected to have desirable solubility to both the zinc salt and the generated zinc oxide nanoparticles, and includes but is not limited to more polar solvents such as water, organic alcohols, organic ethers, and sulfones. In some embodiments, the solvent is selected from at least one of water, organic alcohols, organic ethers, and sulfones. These solvents show desirable solubility to zinc salt, are relatively stable in alkaline environment as a reaction medium, and are not prone to introduce side reactions; moreover, such solvents have solubility for the polar end product zinc oxide nanoparticles. In addition, the solvent can ionize the reaction alkali, and can simultaneously serve as a dissolving solvent for the zinc salt and a dilution or dissolving solvent for the reaction alkali, so as to promote the reaction between the alkali and the zinc salt. Exemplarily, the solvent may be selected from at least one of water, methanol, ethanol, propanol, butanol, ethylene glycol, 2-methoxyethanol, and DMSO.

In the embodiments of the present disclosure, the alkaline solution is a solution formed by an alkali capable of reacting with a zinc salt to form a zinc hydroxide. Specifically, the alkaline solution provides hydroxide ions that react with zinc ions in the reaction system. It should be understood that when the zinc salt contains doping metal ions, the alkaline solution reacts with the zinc ions and the hydroxide ions of the doping metal ions at the same time. In the embodiments of the present disclosure, a solvent is used to dissolve or dilute the alkali to obtain the alkaline solution. On the one hand, a solid alkali such as sodium hydroxide can be dissolved in a solvent to form a liquid alkaline solution, and then added to the reaction system, which is beneficial to the uniformity of the alkaline solution in the reaction system. On the other hand, by dissolving or diluting, the concentration of the alkali in the alkaline solution can be adjusted so that its concentration is (0.1-2) mol/L, so as to avoid the concentration of the added alkali being too high. If the alkali concentration is too high, the reaction rate will be too high, thus eventually leading to the uneven size of the obtained zinc oxide nanoparticles; and when the zinc oxide particles are too large, agglomeration will also occur.

The alkali in the alkaline solution can be selected from inorganic alkalies or organic alkalies, strong alkalies or weak alkalies. In a possible implementation, the alkali in the alkaline solution is an alkali with K_{b}>10-1; exemplarily, the alkali with K_{b}>10⁻¹ is at least one of potassium hydroxide, sodium hydroxide, and lithium hydroxide. In a possible implementation, the alkali in the alkaline solution is an alkali with K_{b}<10⁻¹; exemplarily, the alkali with K_{b}<10⁻¹ is at least one of TMAH, ammonia water, ethanolamine, and ethylenediamine. The solvent used for dissolving or diluting the alkali to form the alkaline solution can dissolve the alkali or be miscible with the alkali, and a polarity of the solvent is the same as that of the zinc oxide nanoparticles. In some embodiments, the solvent used to dissolve or dilute the alkali to form the alkaline solution may be the same as or different from the solvent in the zinc salt solution. In some embodiments, the solvent used to dissolve or dilute the alkali to form the alkaline solution is selected to be the same solvent as the zinc salt solution, which is more conducive to obtaining a stable reaction system. The same solvent includes but is not limited to more polar solvents, such as water, organic alcohols, organic ethers, and sulfones. In some embodiments, the solvent is selected from at least one of water, organic alcohols, organic ethers, and sulfones. Exemplarily, the solvent may be selected from at least one of water, methanol, ethanol, propanol, butanol, ethylene glycol, 2-methoxyethanol, and DMSO.

In some embodiments, the zinc salt solution and the alkaline solution are mixed and reacted at 0° C. to 70° C. for 30 min to 4 h to obtain zinc oxide nanoparticles. In some embodiments, the mixing of the zinc salt solution and the alkaline solution includes: dissolving a zinc salt at room temperature (5° C. to 40° C.) to obtain the zinc salt solution, dissolving or diluting an alkali at room temperature to obtain the alkaline solution; and adjusting the zinc salt solution to 0° C. to 70° C., and adding the alkaline solution. In this case, the added alkali reacts with the zinc salt in the zinc salt solution to form zinc oxide nanoparticles, with desirable particle dispersion. When the reaction temperature is lower than 0° C., the formation of ZnO nanoparticles may be significantly slowed down, and the reaction needs special equipment to realize. This increases the difficulty of the reaction, and even ZnO nanoparticles cannot be produced under some conditions, but only hydroxide intermediates can be obtained. When the reaction temperature is higher than 70° C., the reactivity is too high, and the generated zinc oxide nanoparticles are easy to agglomerate. This is not prone to obtain a colloidal solution with high dispersibility, thus affecting the later film formation of the zinc oxide colloidal solution. In some embodiments, the reaction between the zinc salt solution and the alkaline solution is conducted at room temperature to 50° C. In this case, not only the formation of ZnO nanoparticles is beneficial, but also the obtained ZnO ions have better particle dispersion. This is beneficial to the film formation of the zinc oxide colloidal solution. In some embodiments, the zinc salt solution and the alkaline solution are mixed and treated at a temperature of 0° C. to 30° C. to easily generate a qualified zinc oxide colloidal solution. In some embodiments, the zinc oxide colloidal solution can also be generated at a temperature of 30° C. to 70° C. However, the quality of the obtained zinc oxide colloidal solution is generally not as high as the zinc oxide colloidal solution generated under the condition of 0° C. to 30° C., and the reaction time is generally reduced. In some embodiments, during mixing the zinc salt solution and the alkaline solution: according to a molar ratio of the hydroxide ions to the zinc ions being 1.5:1 to 2.5:1, the zinc salt solution is mixed with the alkaline solution, to ensure the formation of ZnO nanoparticles and reduce the formation of reaction by-products. When the molar ratio of hydroxide ions to zinc ions is less than 1.5:1, the zinc salt is excessive, resulting in a large amount of zinc salts unable to generate zinc oxide nanoparticles. When the molar ratio of hydroxide ions to zinc ions is greater than 2.5:1, the alkaline solution is excessive, and the excess hydroxide ions form a stable complex with the zinc hydroxide intermediate, which is difficult to polycondensate to form zinc oxide nanoparticles. In some embodiments, during mixing the zinc salt solution and the alkaline solution: the addition amount of the zinc salt solution and the alkaline solution meets the requirement that the hydroxide ions provided by the alkaline solution and the zinc ions provided by the zinc salt are at a molar ratio of 1.7:1 to 1.9:1.

In some embodiments, the zinc salt solution is mixed with the alkaline solution and reacted at 0° C. to 70° C. for 30 min to 4 h, so as to ensure the formation of zinc oxide nanoparticles and control a particle size of the nanoparticles. When the reaction time is less than 30 min, cluster seeds of ZnO may be obtained if the reaction time is too low. At this time, the crystalline state of the sample is incomplete, and the crystal structure is poor, thus making the conductivity of the ETL poor if it is used as an ETL material. However, when the reaction time exceeds 4 h, the long particle growth time makes the generated nanoparticles too large and the particle size is not uniform. In this way, the surface roughness of the zinc oxide colloidal solution can be relatively high after film formation, thus affecting the electron transport performance. In some embodiments, the zinc salt solution and the alkaline solution are mixed and reacted at the reaction temperature for 1 hour to 2 hours.

In some embodiments, the zinc salt solution and the alkaline solution are mixed and reacted for 30 min to 4 h at 0° C. to 70° C. under stirring to promote the uniformity of the reaction and the particle uniformity of the obtained zinc oxide nanoparticles. Thus, zinc oxide nanoparticles with uniform size are obtained.

In the embodiments of the present disclosure, after the reaction is completed, a precipitant is added to a mixed solution after the reaction to collect the precipitate. The precipitant is a solvent whose polarity is opposite to that of the final zinc oxide nanoparticles, thereby reducing the solubility of the zinc oxide nanoparticles and precipitating them. In some embodiments, the precipitant is a less polar solvent. This type of precipitant is opposite to the polarity of zinc oxide nanoparticles, and is beneficial to the precipitation of zinc oxide nanoparticles. Exemplarily, the precipitant includes but not limited to ethyl acetate, acetone, n-hexane, n-heptane, and other long-chain alkanes with low polarity.

In some embodiments, 2 to 6 times a volume of the precipitant is added to the mixed solution after the reaction (that is, a volume ratio of the precipitant to the mixed solution is 2:1 to 6:1), and a white precipitate is produced in the mixed solution. In this case, it is ensured that under the premise of fully precipitating the zinc oxide nanoparticles, the solubility of the zinc oxide particles is not damaged due to too much precipitant. In some embodiments, the precipitant and the mixed solution are at a volume ratio of 3:1 to 5:1.

In the embodiments of the present disclosure, a precipitated mixed system is centrifuged to collect the precipitate. The collected precipitate is washed with a reaction solvent to remove reactants that do not participate in the reaction. Cleaning the obtained zinc oxide nanoparticles with a reaction solvent can remove excess zinc salt, alkali and other raw materials for preparing the zinc oxide nanoparticles, so as to improve a purity of the zinc oxide nanoparticles. It should be noted that the reaction solvent is as described above. In some embodiments, the reaction solvent is selected from at least one of water, organic alcohols, organic ethers, and sulfones. Exemplarily, the reaction solvent may be selected from at least one of water, methanol, ethanol, propanol, butanol, ethylene glycol, 2-methoxyethanol, and DMSO.

In the embodiments of the present disclosure, zinc oxide nanoparticles are formed by reacting a zinc salt with an alkali. In the polar zinc oxide solution, due to the characteristics of the zinc oxide colloid itself, a large number of ionized hydroxyl groups are adsorbed on the surface. These hydroxyl groups are negatively charged, and a large number of them are adsorbed on the surface of the zinc oxide nanoparticles, such that the surface of the zinc oxide nanoparticles is also negatively charged. Under the action of the electrostatic Coulomb repulsion between the zinc oxide nanoparticles, the zinc oxide nanoparticles can be dispersed in the polar solution, and show high solution stability and dispersibility. When the zinc oxide colloidal solution is deposited into a zinc oxide film, a large number of hydroxyl groups may still cover the surface of the zinc oxide particles after curing to form a film. When this zinc oxide film is used as the ETL in a QLED structure, since a large number of negatively charged hydroxyl groups are adsorbed on the surface of zinc oxide, it will inhibit and hinder the electron transmission in the zinc oxide layer. Therefore, the hydroxyl content on the surface of ZnO film can directly affect the injection of electrons in QLED-based devices. When the hydroxyl content on the surface is high, the transport of electrons in the QLED-based device may be significantly inhibited, and the electrons injected into the quantum dot luminescent layer may be significantly reduced. When the hydroxyl content on the surface is low, the transport of electrons in the QLED-based device may be significantly smoother, and the number of electrons injected into the quantum dot luminescent layer may increase significantly. Therefore, in the embodiments of the present disclosure, the content of surface hydroxyl groups of the obtained zinc oxide nanoparticles is adjusted by controlling the number of cleanings.

Specifically, when the cleaning frequency of zinc oxide nanoparticles is more, the content of residual hydroxyl groups on the surface is correspondingly lower; when the cleaning frequency of zinc oxide nanoparticles is less, the content of residual hydroxyl groups on the surface is correspondingly higher. In the embodiments of the present disclosure, the precipitate is washed twice or more than twice with a reaction solvent, such that the hydroxyl content on the surface thereof is less than or equal to 0.4.

In a possible implementation manner, if the alkali in the alkaline solution is an alkali with K_{b}>10⁻¹, the cleaning frequency is at least 3 times. In this case, since the alkali with K_{b}>10⁻¹ has a higher ionization coefficient, the hydroxyl content on the surface of the final synthesized zinc oxide colloid is higher. Therefore, the need for cleaning frequency at least 3 times is easy to achieve less hydroxyl content on the surface.

In a possible implementation manner, if the alkali in the alkaline solution is an alkali with K_{b}<10⁻¹, the cleaning frequency is at least 2 times. In this case, since the alkali with K_{b}<10⁻¹ has a lower ionization coefficient, the hydroxyl content on the surface of the final synthesized zinc oxide colloid is lower. Therefore, the need for cleaning frequency at least 2 times can generally achieve less hydroxyl content on the surface.

The selection of different K_{b} alkalies can refer to the above records. Exemplarily, alkalies with K_{b}>10⁻¹ include but are not limited to strong inorganic alkalies such as potassium hydroxide, sodium hydroxide, and lithium hydroxide; while alkalies with K_{b}<10⁻¹ include but are not limited to organic weak alkalies such as TMAH, ammonia water, ethanolamine, and ethylenediamine.

In some embodiments, the alkali in the alkaline solution is at least one of potassium hydroxide, sodium hydroxide, and lithium hydroxide. The cleaning frequency of the collected precipitate with the reaction solvent is 3 to 5 times, and zinc oxide nanoparticles with a surface hydroxyl content of less than or equal to 0.4 can be obtained. In some embodiments, the alkali in the alkaline solution is at least one of TMAH, ammonia water, ethanolamine, and ethylenediamine. The cleaning frequency of the collected precipitate with the reaction solvent is 2 to 4 times, and zinc oxide nanoparticles with a surface hydroxyl content of less than or equal to 0.4 can be obtained.

A white precipitate is obtained after cleaning, and the white precipitate is dissolved to obtain a zinc oxide colloidal solution.

In a possible implementation, the zinc oxide film with the surface hydroxyl content of less than or equal to 0.4 is a metal-doped zinc oxide film; correspondingly, the zinc oxide with a surface hydroxyl content of less than or equal to 0.4 is metal-doped zinc oxide. At this time, the zinc salt solution also contains doping metal ions. In this embodiment, the selection of doping metal ions is the same as the selection of doping metal in the above metal-doped zinc oxide film.

In some embodiments, the doping metal ions are selected from at least one of Mg²⁺ and Mn²⁺. In some embodiments, the doping metal ions are selected from at least one of Al³⁺, Y³⁺, La³⁺, Li⁺, Gd³⁺, Zr⁴⁺, and Ce⁴⁺. The doping amount of each doping metal ion refers to the above descriptions, and is not repeatedly described herein.

In some embodiments, the zinc salt solution contains zinc ions and doping metal ions. In the step of mixing the zinc salt solution and the alkaline solution, the addition amount of the zinc salt solution and the alkaline solution satisfies: a product of the molar weight of the metal ions and a valence number and a molar weight of the hydroxide ions are at a ratio of 0.75:1 to 1.25:1. In this case, the zinc salt solution was mixed with alkaline solution to ensure the formation of metal-doped ZnO nanoparticles and reduce the formation of reaction by-products. When a molar ratio of hydroxide ions to metal ions is less than 0.75:1, the metal ion content is excessive, and the metal salt is difficult to generate metal-doped zinc oxide nanoparticles; when a molar ratio of hydroxide ions to zinc ions is greater than 1.25:1, the alkaline solution is excessive, and the excess hydroxide ions form a stable complex with the zinc hydroxide intermediate, which is difficult to polycondensate to form zinc oxide nanoparticles. In some embodiments, in the step of mixing the zinc salt solution and the alkaline solution, the addition amount of the zinc salt solution and the alkaline solution satisfies a product of the molar weight of the metal ions and a valence number and a molar weight of the hydroxide ions are at a ratio of 0.85:1 to 0.95:1.

In the step S12, according to the type of the prepared QLED-based device, the zinc oxide colloidal solution is coated on a prefabricated substrate for preparing the zinc oxide film with the surface hydroxyl content of less than or equal to 0.4, and a solvent is removed to obtain the zinc oxide film with the surface hydroxyl content of less than or equal to 0.4.

In some embodiments, the zinc oxide colloidal solution may be formed on the substrate of the prefabricated device by one of methods including but not limited to spin coating, blade coating, printing, spray coating, roll coating, and electrodeposition. After the zinc oxide colloidal solution is formed on the substrate of the prefabricated device, the solvent is removed by annealing to obtain a zinc oxide film with a surface hydroxyl content of less than or equal to 0.4.

In a possible implementation manner, the QLED is an upright QLED, and the substrate of the prefabricated device includes an anode substrate and a quantum dot luminescent layer combined on the anode substrate. In some embodiments, the substrate of the prefabricated device further includes a hole functional layer arranged between the anode substrate and the quantum dot luminescent layer. The hole functional layer includes at least one of an HTL, an HIL, and an EBL.

In a possible implementation manner, the QLED is an inverted QLED, and the substrate of the prefabricated device is a cathode substrate. In some embodiments, the substrate of the prefabricated device further includes an EIL combined to a cathode surface of the cathode substrate.

In some embodiments, the zinc oxide film with the surface hydroxyl content of less than or equal to 0.4 can be used as ETL alone.

In some embodiments, the ETL includes two zinc oxide films or n film lamination units composed of two zinc oxide films. The two zinc oxide films are named as a first ETL and a second ETL, respectively, and n is greater than or equal to 2. In some embodiments, n is an integer of greater than or equal to 2 and less than or equal to 9. At least the first ETL is a zinc oxide film prepared by the above method with a surface hydroxyl content of less than or equal to 0.4; for the situation of the second ETL, reference may be made to the situation in the second ETL of the QLED-based device above.

In some embodiments, the second ETL is a zinc oxide film with a surface hydroxyl content of greater than or equal to 0.6, or the second ETL is a metal-doped zinc oxide film. The first ETL can be set on one side adjacent to the quantum dot luminescent layer, or on one side adjacent to the cathode. Preferably, the first ETL is arranged on one side adjacent to the quantum dot luminescent layer or the metal-doped zinc oxide film is arranged on one side adjacent to the quantum dot luminescent layer, such that a smoother zinc oxide film can be obtained.

In some embodiments, the ETL includes three zinc oxide films. The three zinc oxide films are named as a first ETL, a second ETL, and a third ETL, respectively. At least the first ETL is a zinc oxide film prepared by the above method with a surface hydroxyl content of less than or equal to 0.4; for the situation of the second ETL and the third ETL, reference may be made to the situation in the ETL including the third ETL in the QLED-based device above.

In the embodiments, the zinc oxide film with a surface hydroxyl content of greater than or equal to 0.6 may be formed by a zinc oxide colloidal solution with a surface hydroxyl content of greater than or equal to 0.6.

In the embodiments, the metal-doped zinc oxide films can be prepared by the following method:
mixing a zinc salt solution containing doping metal ions with a alkaline solution at 0° C. to 70° C. for 30 min to 4 h; adding a precipitant to a mixed solution obtained after the reaction and collecting a precipitate; cleaning the precipitate using a reaction solvent, and dissolving a resulting white precipitate to obtain a metal-doped zinc oxide colloidal solution; and coating the metal-doped zinc oxide colloidal solution on a substrate to be prepared to obtain the metal-doped zinc oxide film. In the embodiment, the type of zinc salt and solvent in the zinc salt solution and the content of the zinc salt solution, the type and doping content of doping ions, the type and addition amount of alkaline solution, the reaction temperature and reaction time, and the selection and addition amount of precipitant are conducted by reference to step S11 of the embodiment of the present disclosure. In this method, a solution of zinc salts containing doping metal ions can be obtained by dissolving zinc salts and selected metal salts in a solvent at room temperature in a certain proportion. During mixing the zinc salt solution containing doping metal ions with the alkaline solution, the amount of alkali added meets: a product of the molar weight of the metal ions and a valence number and a molar weight of the hydroxide ions are at a ratio of 0.75:1 to 1.25:1.

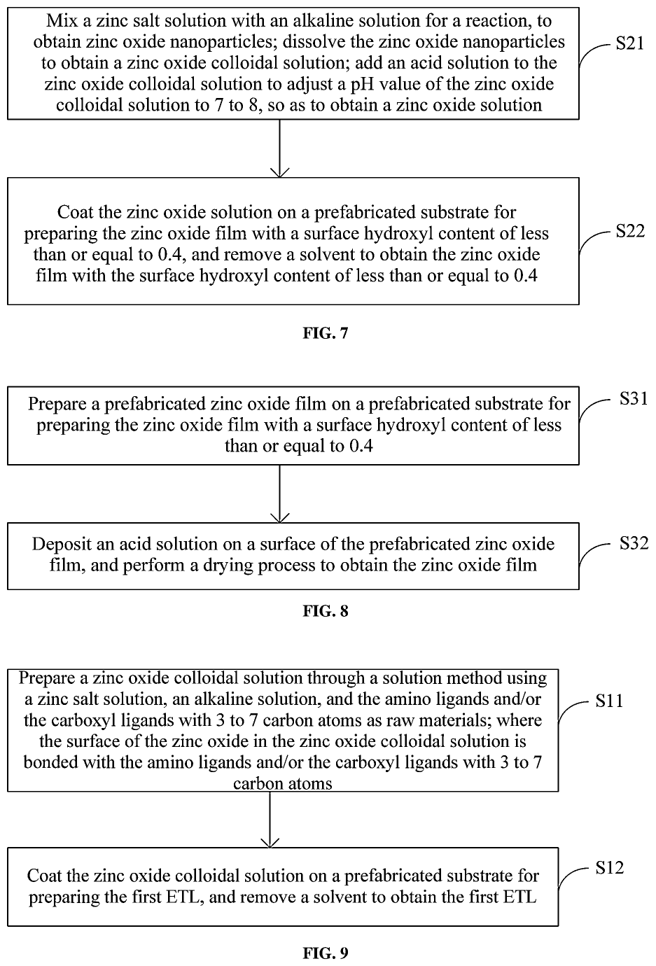

In the second embodiment, an embodiment of the present disclosure provides a preparation method of the QLED, where the QLED includes an anode and a cathode that are oppositely arranged, a quantum dot luminescent layer arranged between the anode and the cathode, and an ETL arranged between the quantum dot luminescent layer and the cathode. The ETL includes a first ETL, and the first ETL is a zinc oxide film with a surface hydroxyl content of less than or equal to 0.4; and
as shown in FIG. 7, a preparation method of the zinc oxide film with the surface hydroxyl content of less than or equal to 0.4 includes the following steps:

S21, mixing a zinc salt solution with a alkaline solution for a reaction, to obtain zinc oxide nanoparticles; dissolving the zinc oxide nanoparticles to obtain a zinc oxide colloidal solution; adding an acid solution to the zinc oxide colloidal solution to adjust a pH value of the zinc oxide colloidal solution to 7 to 8, to obtain a zinc oxide solution; and

S22, coating the zinc oxide colloidal solution on a prefabricated substrate for preparing the zinc oxide film with the surface hydroxyl content of less than or equal to 0.4, and removing a solvent to obtain the zinc oxide film with the surface hydroxyl content of less than or equal to 0.4.

In the preparation method of the QLED provided in the embodiment of the present disclosure, a zinc oxide colloidal solution is prepared by a solution method, and then an acid solution is added to the zinc oxide colloidal solution to adjust a pH value of the zinc oxide colloidal solution to 7 to 8 to obtain a zinc oxide solution, so as to obtain the zinc oxide with a surface hydroxyl content of less than or equal to 0.4. The zinc oxide film with the surface hydroxyl content of less than or equal to 0.4 is used as a first ETL. In this way, the transmission of electrons to the quantum dot luminescent layer becomes obviously smooth, and the electricity injected into the quantum dot luminescent layer increases. This makes the injection rate of electrons into the quantum dot luminescent layer higher than the injection rate of holes into the quantum dot luminescent layer, thus causing the quantum dots in the quantum dot luminescent layer to be negatively charged. This negatively charged state can be maintained due to a quantum dot core-shell structure and a binding effect of the electrically inert surface ligands. Meanwhile, a Coulomb repulsion effect makes the further injection of electrons into the quantum dot luminescent layer more and more difficult. When a QLED-based device continues to light up to a stable state, the negatively charged state of the quantum dots also tends to be stable. That is, the electrons newly captured and bound by the quantum dots and the electrons consumed by the radiative transition reach a dynamic balance, and the injection rate of electrons into the quantum dot luminescent layer is much lower than that in the initial stage. At this time, a lower electron injection rate and a hole injection rate just reach a carrier injection balance, such that the service life of the device is improved.

In the embodiments of the present disclosure, the composition of the QLED, especially the situation of the ETL, is as described in the first aspect above. In order to save space, details are not repeated here.

In the step S21, the zinc oxide colloidal solution is prepared by a solution method, and the solution method may be one of an alcoholysis method, a hydrolysis method, and the like. A basic process of preparing zinc oxide by the solution method is: mixing the zinc salt solution with the alkaline solution for a reaction, to form a hydroxide intermediate such as zinc hydroxide; and subjecting the hydroxide intermediate to polycondensation to gradually generate zinc oxide nanoparticles.

In the embodiments of the present disclosure, the zinc salt solution, the basis and type of selection of zinc salt and solvent in zinc salt solution, and mode of formation of zinc salt solution, as well as the alkaline solution, the basis and type of selection of alkali and solvent in alkaline solution, and mode of formation of alkaline solution, are both as described in the first aspect above. In order to save space, details are not repeated here. The reaction conditions and time of mixing zinc salt solution with alkaline solution, the content ratio of zinc salt solution to alkaline solution, and the optimal situation are both as described in the first aspect above. In order to save space, details are not repeated here.

In some embodiments, a precipitant is added to a mixed solution obtained at the end of the reaction and a precipitate is collected. The choice of precipitant is referred to the first aspect above.

In the embodiments of the present disclosure, a precipitation-treated mixed system is centrifuged, a precipitate is collected, and the method and conditions of centrifugation are referred to in the first aspect above.

The zinc oxide colloidal solution is obtained by dissolving the washed precipitate.

In embodiments of the present disclosure, the acid solution is added to the zinc oxide colloidal solution to adjust a pH value of the zinc oxide colloidal solution to 7 to 8. The hydroxyl ligands on a surface of zinc oxide form a dynamic equilibrium with the ionized hydroxyl groups in the zinc oxide colloidal solution, and the addition of the acid solution can break this equilibrium. Specifically, after the acid solution is added, the content of ionized hydroxyl groups in the zinc oxide colloidal solution is reduced, and the content of hydroxyl ligands on the surface of zinc oxide is also correspondingly reduced. However, the amount of acid solution added to the system should not be too much (pH value should not be too low), otherwise the hydroxyl ligand volume on the surface of zinc oxide will be too low, resulting in the loss of ligand protection on the surface of zinc oxide, so as to cause serious aggregation or even precipitation of zinc oxide particles. Therefore, the pH value of zinc oxide colloidal solution is adjusted to 7 to 8 by adding acid solution. In some embodiments, the pH value of the zinc oxide colloidal solution is adjusted to 7.2 to 7.8 by adding the acid solution. In this way, on the basis of making the surface hydroxyl content of the obtained zinc oxide less than or equal to 0.4, the surface of zinc oxide nanoparticles can also contain certain hydroxyl ligands, thus achieving desirable dispersion. In some embodiments, the pH value of the zinc oxide colloidal solution is adjusted to 7.3 to 7.6 by adding the acid solution.

In some embodiments, an acid in the acid solution is at least one of inorganic strong acids such as hydrochloric acid, sulfuric acid, nitric acid, and hydrofluoric acid, or at least one of organic carboxylic acids such as formic acid, acetic acid, propionic acid, oxalic acid, and acrylic acid. The acid solution is a solution formed by dissolution of inorganic acid or a solution formed by dissolution or dilution of organic acid. By dissolving or diluting the acid, an acid concentration is adjusted to control a reaction rate, such that the surface hydroxyl content of zinc oxide nanoparticles can be fully adjusted. A solvent for dissolving or diluting the acid to form the acid solution, is capable of dissolving the acid or miscible with the acid; in addition, the solvent has a same polarity as that of the zinc oxide nanoparticles. In some embodiments, the solvent used to dissolve or dilute the acid to form the acid solution may be the same as or different from the solvent in the zinc salt solution. In some embodiments, the solvent used to dissolve or dilute the acid to form the acid solution includes but is not limited to more polar solvents, such as water, organic alcohols, organic ethers, and sulfones. In some embodiments, the solvent is selected from at least one of water, organic alcohols, organic ethers, and sulfones. Exemplarily, the solvent may be selected from at least one of water, methanol, ethanol, propanol, butanol, ethylene glycol, 2-methoxyethanol, and DMSO.

In a possible implementation, the zinc oxide film with the surface hydroxyl content of less than or equal to 0.4 is a metal-doped zinc oxide film; correspondingly, the zinc oxide with a surface hydroxyl content of less than or equal to 0.4 is metal-doped zinc oxide. At this time, the zinc salt solution also contains doping metal ions. In this embodiment, the selection of doping metal ions is the same as the selection of doping metal in the above metal-doped zinc oxide film in the first aspect.

In some embodiments, the zinc salt solution contains zinc ions and doping metal ions. In the step of mixing the zinc salt solution and the alkaline solution, the addition amount of the zinc salt solution and the alkaline solution satisfies: a product of the molar weight of the metal ions and a valence number and a molar weight of the hydroxide ions are at a ratio of 0.75:1 to 1.25:1. In this case, the zinc salt solution was mixed with alkaline solution to ensure the formation of metal-doped ZnO nanoparticles and reduce the formation of reaction by-products. When a molar ratio of hydroxide ions to metal ions is less than 0.75:1, the metal ion content is excessive, and the metal salt is difficult to generate metal-doped zinc oxide nanoparticles; when a molar ratio of hydroxide ions to zinc ions is greater than 1.25:1, the alkaline solution is significantly excessive, and the excess hydroxide ions form a stable complex with the zinc hydroxide intermediate, which is difficult to polycondensate to form zinc oxide nanoparticles. In some embodiments, in the step of mixing the zinc salt solution and the alkaline solution, the addition amount of the zinc salt solution and the alkaline solution satisfies a product of the molar weight of the metal ions and a valence number and a molar weight of the hydroxide ions are at a ratio of 0.85:1 to 0.95:1.

In the step S22, according to the type of the prepared QLED-based device, the zinc oxide colloidal solution is coated on a prefabricated substrate for preparing the zinc oxide film with the surface hydroxyl content of less than or equal to 0.4, and a solvent is removed to obtain the zinc oxide film with the surface hydroxyl content of less than or equal to 0.4.

The implementation of step S22 is as described in the first aspect.

In the third embodiment, an embodiment of the present disclosure provides a preparation method of the QLED, where the QLED includes an anode and a cathode that are oppositely arranged, a quantum dot luminescent layer arranged between the anode and the cathode, and an ETL arranged between the quantum dot luminescent layer and the cathode. The ETL includes a first ETL, and the first ETL is a zinc oxide film with a surface hydroxyl content of less than or equal to 0.4; and
as shown in FIG. 8, a preparation method of the zinc oxide film with the surface hydroxyl content of less than or equal to 0.4 includes the following steps:
S31, preparing a prefabricated zinc oxide film on a prefabricated substrate for preparing the zinc oxide film with the surface hydroxyl content of less than or equal to 0.4; and
S32, depositing an acid solution on a surface of the prefabricated zinc oxide film, and drying to obtain the zinc oxide film.

In the preparation method of the QLED provided in the embodiment of the present disclosure, a prefabricated zinc oxide film is treated with acid to obtain zinc oxide with a surface hydroxyl content of less than or equal to 0.4. In this case, the zinc oxide film with the surface hydroxyl content of less than or equal to 0.4 is used as a first ETL. In this way, the transmission of electrons to the quantum dot luminescent layer becomes smooth, and the electricity injected into the quantum dot luminescent layer increases. This makes the injection rate of electrons into the quantum dot luminescent layer higher than the injection rate of holes into the quantum dot luminescent layer, thus causing the quantum dots in the quantum dot luminescent layer to be negatively charged. This negatively charged state can be maintained due to a quantum dot core-shell structure and a binding effect of the electrically inert surface ligands. Meanwhile, a Coulomb repulsion effect makes the further injection of electrons into the quantum dot luminescent layer more and more difficult. When a QLED-based device continues to light up to a stable state, the negatively charged state of the quantum dots also tends to be stable. That is, the electrons newly captured and bound by the quantum dots and the electrons consumed by the radiative transition reach a dynamic balance, and the injection rate of electrons into the quantum dot luminescent layer is much lower than that in the initial stage. At this time, a lower electron injection rate and a hole injection rate just reach a carrier injection balance, such that the service life of the device is improved.

In the embodiments of the present disclosure, the composition of the QLED, especially the situation of the ETL, is as described in the first aspect above. In order to save space, details are not repeated here.

In step S31, the prefabricated zinc oxide film can be prepared by various methods; as an example, the prefabricated zinc oxide film is prepared by solution method or sol-gel method.

In some embodiments, the prefabricated zinc oxide film is prepared by solution method, including: mixing a zinc salt solution mixed with a alkaline solution to obtain zinc oxide nanoparticles; dissolving the zinc oxide nanoparticles to obtain a zinc oxide colloidal solution; coating the zinc oxide colloidal solution on a prefabricated substrate for preparing the zinc oxide film with the surface hydroxyl content of less than or equal to 0.4, and removing a solvent to obtain the prefabricated zinc oxide film.

In the present disclosure, the zinc oxide nanoparticles are prepared by mixing the zinc salt solution with alkaline solution; the step for dissolving zinc oxide nanoparticles to obtain a zinc oxide colloidal solution refers to step S11 in the first aspect. In order to save space, details are not repeated here.

In one possible implementation, zinc oxide in the zinc oxide film with the surface hydroxyl content of less than or equal to 0.4 is metal-doped zinc oxide. Correspondingly, the zinc oxide in the zinc oxide film with surface hydroxyl content of less than or equal to 0.4 is metal-doped zinc oxide. At this time, the zinc salt solution also contains doping metal ions. In this embodiment, the selection and doping amount of doping metal ions are the same as the selection and doping amount of doping metal in the above metal-doped zinc oxide film.

In the embodiments, according to the type of the prepared QLED-based device, the zinc oxide colloidal solution is coated on a prefabricated substrate for preparing the zinc oxide film with the surface hydroxyl content of less than or equal to 0.4, and a solvent is removed to obtain the zinc oxide film with the surface hydroxyl content of less than or equal to 0.4.

In some embodiments, the zinc oxide colloidal solution is formed on the substrate of the prefabricated device by referring to step S12 “coating the zinc oxide colloidal solution on a prefabricated substrate for preparing the zinc oxide film with the surface hydroxyl content of less than or equal to 0.4, and removing a solvent to obtain the zinc oxide film with the surface hydroxyl content of less than or equal to 0.4″.

In step S32, the surface hydroxyl content of the prefabricated zinc oxide film is changed by depositing the acid solution on the prefabricated zinc oxide film. Specifically, when the acid solution is deposited, the surface of the prefabricated zinc oxide film can form a liquid film. Therefore, the hydroxyl groups on the surface of the prefabricated zinc oxide film react with ionized hydrogen ions in the liquid film, thus reducing the surface hydroxyl content of the prefabricated zinc oxide film.

In some embodiments, an acid in the acid solution includes but is not limited to at least one of inorganic strong acids such as hydrochloric acid, sulfuric acid, nitric acid, and hydrofluoric acid, or at least one of organic carboxylic acids such as formic acid, acetic acid, propionic acid, oxalic acid, and acrylic acid. In the embodiments of the present disclosure, the acid solution is a solution formed by an inorganic acid, or a solution formed by dilution or dissolution of an organic acid, or may be directly an organic carboxylic acid. By dissolving or diluting the acid, an acid concentration is adjusted to control a reaction rate, such that the surface hydroxyl content of zinc oxide nanoparticles can be fully adjusted. A solvent for dissolving or diluting the acid to form the acid solution, is capable of dissolving the acid or miscible with the acid; in addition, the solvent has a same polarity as that of the zinc oxide nanoparticles. In some embodiments, the solvent used to dissolve or dilute the acid to form the acid solution may be the same as or different from the solvent in the zinc salt solution. In some embodiments, the solvent used to dissolve or dilute the acid to form the acid solution includes but is not limited to more polar solvents, such as water, organic alcohols, organic ethers, and sulfones. In some embodiments, the solvent is selected from at least one of water, organic alcohols, organic ethers, and sulfones. Exemplarily, the solvent may be selected from at least one of water, methanol, ethanol, propanol, butanol, ethylene glycol, 2-methoxyethanol, and DMSO.

In embodiments of the present disclosure, it is necessary to control the concentration and addition of acid solution. This is because the excess concentration and addition of acid may make the surface hydroxyl content of zinc oxide too low. This makes the surface of zinc oxide lose ligand protection, resulting in serious agglomeration of zinc oxide particles, thus affecting the quality of zinc oxide film. However, the insufficient concentration and addition of acid is not prone to reduce the surface hydroxyl content of zinc oxide. In some embodiments, the acid solution has a concentration of (0.05-0.5) mmol/L to obtain a suitable concentration to regulate the surface hydroxyl content of the prefabricated zinc oxide film. In some embodiments, the amount of acid solution deposited is sufficient for the weight of the underlying prefabricated zinc oxide film: each 5 mg of the prefabricated zinc oxide film is treated with 50 μL to 1,000 μL of the acid solution. The excess concentration of acid solution and addition of acid both may make the surface hydroxyl content of zinc oxide nanoparticles too low. This makes the surface of zinc oxide lose ligand protection, resulting in serious agglomeration of zinc oxide particles, thus affecting the quality of zinc oxide film. However, the insufficient concentration of acid solution and addition of acid are not prone to reduce the surface hydroxyl content of zinc oxide. It should be understood that the concentration of the acid solution can be flexibly adjusted according to the different types of acid chosen.

Inorganic acids are generally strong acids with strong hydrogen ion ionization ability, so only a small amount of inorganic acids with low concentration can adjust the surface hydroxyl content of zinc oxide. Organic acids are generally weak acids with weak hydrogen ion ionization ability, so a relatively high concentration of organic acids is needed to effectively adjust the surface hydroxyl content of zinc oxide.

In some embodiments, the acid in the acid solution is an inorganic acid, and the acid solution has a concentration of (0.05-0.1) mmol/L. As an example, the inorganic acid is at least one of hydrochloric acid, sulfuric acid, nitric acid, and hydrofluoric acid. In this case, the amount of acid solution deposited is sufficient for the weight of the underlying prefabricated zinc oxide film: each 5 mg of the prefabricated zinc oxide film is treated with 50 μL to 200 μL of the acid solution.

In some embodiments, the acid in the acid solution is an organic carboxylic acid, in which case the corresponding acid solution is formed with a concentration of (0.2-0.4) mmol/L. As an example, the organic carboxylic acid is at least one of formic acid, acetic acid, propionic acid, oxalic acid, and acrylic acid. In this case, the amount of acid solution deposited is sufficient for the weight of the underlying prefabricated zinc oxide film: each 5 mg of the prefabricated zinc oxide film is treated with 100 μL to 500 μL of the acid solution.

In the embodiments of the present disclosure, a method of depositing the acid solution on the surface of the prefabricated zinc oxide film may be a solution processing method, including but not limited to spin coating, blade coating, printing, spray coating, roll coating, and electrodeposition.

In the present disclosure, after the acid solution is deposited on the surface of the prefabricated zinc oxide film, drying is conducted such that ionized hydrogen ions in the acid solution can fully react with the hydroxyl groups on the surface of the zinc oxide. In some embodiments, the drying process is conducted at 10° C. to 100° C. for 10 min to 2 hours. In this case, the ionized hydrogen ions in the acid solution react fully with the hydroxyl groups on the surface of zinc oxide to reduce the surface hydroxyl content of zinc oxide. If the drying temperature is too high or the drying time is too long, the acid solution is quickly dried, and the prefabricated zinc oxide film quickly becomes a solid film. This makes the ionized hydrogen ions in the acid solution unable to fully react with the hydroxyl groups on the surface of zinc oxide, and it is not prone to fully reduce the surface hydroxyl content of zinc oxide. When the drying temperature is too low or the drying time is too short, the prefabricated zinc oxide film is difficult to be dried fully. This affects the preparation of the next layer, especially an evaporation quality of the electrode. In some embodiments, the drying process is conducted at 10° C. to 50° C. for 30 min to 2 hours. By changing the surface hydroxyl content of zinc oxide, a resulting film may retain a very small amount of acid forming an auxiliary layer on the surface.

In a possible implementation manner, the QLED is an upright QLED, and the substrate of the prefabricated device includes an anode substrate and a quantum dot luminescent layer combined on the anode substrate. In some embodiments, the substrate of the prefabricated device further includes a hole functional layer arranged between the anode substrate and the quantum dot luminescent layer. The hole functional layer includes at least one of an HTL, an HIL, and an EBL.

In a possible implementation manner, the QLED is an inverted QLED, and the substrate of the prefabricated device is a cathode substrate. In some embodiments, the substrate of the prefabricated device further includes an EIL combined to a cathode surface of the cathode substrate.

In some embodiments, the zinc oxide film with the surface hydroxyl content of less than or equal to 0.4 can be used as ETL alone.

In some embodiments, the ETL includes two zinc oxide films or n film lamination units composed of two zinc oxide films. The two zinc oxide films are named as a first ETL and a second ETL, respectively, and n is greater than or equal to 2. In some embodiments, n is an integer of greater than or equal to 2 and less than or equal to 9. At least the first ETL is a zinc oxide film prepared by the above method with a surface hydroxyl content of less than or equal to 0.4; for the situation of the second ETL, reference may be made to the situation in the second ETL of the QLED-based device above.

In some embodiments, the second ETL is a zinc oxide film with a surface hydroxyl content of greater than or equal to 0.6, or the second ETL is a metal-doped zinc oxide film. The first ETL can be set on one side adjacent to the quantum dot luminescent layer, or on one side adjacent to the cathode. Preferably, the first ETL is arranged on one side adjacent to the quantum dot luminescent layer or the metal-doped zinc oxide film is arranged on one side adjacent to the quantum dot luminescent layer, such that a smoother zinc oxide film can be obtained.

In some embodiments, the ETL includes three zinc oxide films. The three zinc oxide films are named as a first ETL, a second ETL, and a third ETL, respectively. At least the first ETL is a zinc oxide film prepared by the above method with a surface hydroxyl content of less than or equal to 0.4; for the situation of the second ETL and the third ETL, reference may be made to the situation in the ETL including the third ETL in the QLED-based device above.

In the embodiments, the metal-doped zinc oxide film may be prepared by referring to the method of metal-doped zinc oxide film provided in the first aspect. In some embodiments, a preparation method of the metal-doped zinc oxide film includes:
mixing a zinc salt solution containing doping metal ions with a alkaline solution at 0° C. to 70° C. for 30 min to 4 h; adding a precipitant to a mixed solution obtained after the reaction and collecting a precipitate; cleaning the precipitate using a reaction solvent, and dissolving a resulting white precipitate to obtain a metal-doped zinc oxide colloidal solution; and coating the metal-doped zinc oxide colloidal solution on a substrate to be prepared to obtain the metal-doped zinc oxide film.

In the embodiment, the type of zinc salt and solvent in the zinc salt solution and the content of the zinc salt solution, the type and doping content of doping ions, the type and addition amount of alkaline solution, the reaction temperature and reaction time, the selection and addition amount of precipitant, and the type and content of doping metal ions are conducted by reference to step S11 of the embodiment of the present disclosure. In some embodiments, during mixing the zinc salt solution containing doping metal ions with the alkaline solution, the amount of alkali added meets: a product of the molar weight of the metal ions and a valence number and a molar weight of the hydroxide ions are at a ratio of 0.75:1 to 1.25:1.

In some embodiments, the doping metal in the metal-doped zinc oxide film is at least one of Mg²⁺ and Mn²⁺. In some embodiments, the doping metal in the metal-doped zinc oxide film is at least one of Al³⁺, Y³⁺, La³⁺, Li⁺, Gd³⁺, Zr⁴⁺, and Ce⁴⁺. The doping amount of each doping metal ion refers to the above descriptions, and is not repeatedly described herein.

It should be understood that in the above three embodiments of this application, when the device is an upright QLED, after the ETL is prepared, the cathode is also evaporated on the ETL to obtain the QLED. In some embodiments, the EIL is also prepared on the ETL prior to evaporation of the cathode. When the device is an inverted QLED, after the ETL is prepared, a quantum dot luminescent layer is also prepared on the ETL, and the QLED is obtained by evaporating an anode on the quantum dot luminescent layer. In some embodiments, a hole functional layer is also prepared on the quantum dot luminescent layer prior to evaporation of the anode.

In the embodiments of the present disclosure, the formation of the hole functional layer (including at least one of HIL, HTL, and EBL) and the quantum dot luminescent layer is preferably conducted by solution processing, including but not limited to spin coating, blade coating, printing, spray coating, roll coating, and electrodeposition.

In the fourth embodiment, an embodiment of the present disclosure provides a preparation method of the QLED, where the QLED includes an anode and a cathode that are oppositely arranged, a quantum dot luminescent layer arranged between the anode and the cathode, and an ETL arranged between the quantum dot luminescent layer and the cathode. The ETL includes a first ETL, and a surface of the zinc oxide forming the first ETL includes an amino ligand and/or a carboxyl ligand with 3 to 7 carbon atoms; and
as shown in FIG. 9, a preparation method of the first ETL included the following steps:
S11, preparing a zinc oxide colloidal solution by a solution method using a zinc salt solution, a alkaline solution, and the amino ligands and/or the carboxyl ligands with 3 to 7 carbon atoms as raw materials; where the surface of the zinc oxide in the zinc oxide colloidal solution is bonded with the amino ligands and/or the carboxyl ligands with 3 to 7 carbon atoms; and
S12, coating the zinc oxide colloidal solution on a prefabricated substrate for preparing the first ETL, and removing a solvent to obtain the first ETL.

In the preparation method of the QLED provided in the embodiments of the present disclosure, an amino ligand and/or a carboxyl ligand with 3 to 7 carbon atoms is added during the synthesis of a zinc oxide colloidal solution to induce ligand exchange between the amino ligands and/or the carboxyl ligands and the hydroxyl ligand on the surface of the zinc oxide colloidal solution. In this way, the amino ligands and/or the carboxyl ligands with 3 to 7 carbon atoms is coordinated on the surface of the zinc oxide colloid. The coordinated the amino ligands and/or the carboxyl ligands have a lower chain length and does not significantly increase a distance between zinc oxide nanoparticles in solution and after film formation. Meanwhile, the surface hydroxyl content of zinc oxide nanoparticles is reduced, and the electron mobility of zinc oxide ETL after film formation is increased. As a result, the service life of QLED-based devices is effectively improved.

In the embodiments of the present disclosure, the composition of the QLED, especially the situation of the ETL, the selection of the amino ligands and/or the carboxyl ligands with 3 to 7 carbon atoms, and the thickness of zinc oxide film containing the amino ligands and/or the carboxyl ligands with 3 to 7 carbon atoms, are as described in the first aspect above. In order to save space, details are not repeated here.

In step S11, a basic process of preparing zinc oxide by the solution method is: mixing the zinc salt solution with the alkaline solution for a reaction, to form a hydroxide intermediate such as zinc hydroxide; and subjecting the hydroxide intermediate to polycondensation to gradually generate zinc oxide nanoparticles. On this basis, in the embodiments of the present disclosure, an amino ligand and/or a carboxyl ligand with 3 to 7 carbon atoms is added during the synthesis of a zinc oxide colloidal solution to induce ligand exchange between the amino ligands and/or the carboxyl ligands and the hydroxyl ligand on the surface of the zinc oxide colloidal solution. In this way, the amino ligands and/or the carboxyl ligands with 3 to 7 carbon atoms is coordinated on the surface of the zinc oxide colloid. The coordinated the amino ligands and/or the carboxyl ligands have a lower chain length and does not significantly increase a distance between zinc oxide nanoparticles in solution and after film formation. Meanwhile, the surface hydroxyl content of zinc oxide nanoparticles is reduced, and the electron mobility of zinc oxide film after film formation is increased, thus actually playing a same role as that of zinc oxide film with a surface hydroxyl content of less than or equal to 0.4.

In the step of preparing a zinc oxide colloidal solution by a solution method using a zinc salt solution, a alkaline solution, and the amino ligands and/or the carboxyl ligands with 3 to 7 carbon atoms as raw materials: there are multiple time nodes of adding the amino ligands and/or the carboxyl ligands with 3 to 7 carbon atoms, and there should be several ways of preparing zinc oxide colloidal solution by the solution method.

In a first aspect, the amino ligands and/or the carboxyl ligands with 3 to 7 carbon atoms is added at the beginning of the synthesis of the zinc oxide colloidal solution. That is, the amino ligands and/or the carboxyl ligands with 3 to 7 carbon atoms and the alkaline solution are simultaneously added to the zinc salt solution.

At this time, the steps for preparing the zinc oxide colloidal solution by solution method include:
mixing the zinc salt solution, the alkaline solution, and the amino ligands and/or the carboxyl ligands with 3 to 7 carbon atoms for a reaction, to obtain zinc oxide nanoparticles with the surface bonded with the amino ligands and/or the carboxyl ligands with 3 to 7 carbon atoms; and
dissolving the zinc oxide nanoparticles to obtain the zinc oxide colloidal solution.

In the above steps, the zinc salt solution is a salt solution formed by dissolving a zinc salt in a solvent. The zinc salt is selected to react with the alkaline solution to generate zinc hydroxide, and includes but is not limited to one of zinc acetate, zinc nitrate, zinc sulfate, and zinc chloride. The solvent is selected to have desirable solubility to the zinc salt, and includes but is not limited to more polar solvents such as water, organic alcohols, organic ethers, and sulfones. In some embodiments, the solvent is selected from at least one of water, organic alcohols, organic ethers, and sulfones. These solvents show desirable solubility to zinc salt, are relatively stable in alkaline environment as a reaction medium, and are not prone to introduce side reactions. Exemplarily, the solvent may be selected from at least one of water, methanol, ethanol, propanol, butanol, ethylene glycol, 2-methoxyethanol, and DMSO.

In the embodiments of the present disclosure, the alkaline solution is a solution formed by an alkali capable of reacting with a zinc salt to form a zinc hydroxide. The alkaline solution is obtained by solvent dissolution or dilution. The alkali in the alkaline solution can be selected from inorganic alkalies or organic alkalies. In one possible embodiment, the alkali in the alkaline solution is an inorganic alkali; As an example, the inorganic alkali is at least one of potassium hydroxide, sodium hydroxide, and lithium hydroxide. In one possible embodiment, the alkali in the alkaline solution is an organic alkali; As an example, the weak alkali is at least one of TMAH, ammonia water, ethanolamine, and ethylenediamine. In some embodiments, the solvent used to dissolve or dilute the alkali to form the alkaline solution may be the same as or different from the solvent in the zinc salt solution. In some embodiments, the solvent used to dissolve or dilute the alkali to form the alkaline solution is selected to be the same solvent as the zinc salt solution, which is more conducive to obtaining a stable reaction system. The same solvent includes but is not limited to more polar solvents, such as water, organic alcohols, organic ethers, and sulfones. In some embodiments, the solvent is selected from at least one of water, organic alcohols, organic ethers, and sulfones. Exemplarily, the solvent may be selected from at least one of water, methanol, ethanol, propanol, butanol, ethylene glycol, 2-methoxyethanol, and DMSO.

In some embodiments, the amino ligands and/or the carboxyl ligands with 3 to 7 carbon atoms includes but is not limited to propionic acid, propylamine, butyric acid, butylamine, hexanoic acid, and hexylamine. In some embodiments, the amino ligands and/or the carboxyl ligands with 3 to 7 carbon atoms is configured to form a ligand solution and react with the zinc salt solution and the alkaline solution. The solvent in the ligand solution is selected with larger polarity, mainly considering the solubility of the reaction raw materials and products. Exemplarily, the solvent in the ligand solution is selected from at least one of methanol, ethanol, propanol, butanol, ethylene glycol, 2-methoxyethanol, and DMSO. In some embodiments, the amino ligands and/or the carboxyl ligands with 3 to 7 carbon atoms is a ligand solution, and the ligand solution has a concentration of (0.2-0.4) mmol/L. When the ligand concentration is too low, the addition of the amino ligands and/or the carboxyl ligands with 3 to 7 carbon atoms is too low, and it is difficult to achieve an effective ligand exchange effect. When the ligand concentration is too high, the addition of the amino ligands and/or the carboxyl ligands with 3 to 7 carbon atoms is too high, and a large number of ligands remaining in the solution may remain in the first ETL, thus affecting film forming quality and properties of ETL.

In some embodiments, the amount of alkaline solution added is satisfied that the hydroxide ions provided by the alkaline solution and the zinc ions provided by the zinc salt are at a molar ratio of 1.5:1 to 2.5:1 to ensure the formation of zinc oxide nanoparticles and reduce the formation of reaction byproducts. When a molar ratio of hydroxide ions to zinc ions is less than 1.5:1, the zinc salt content is excessive, and a large number of zinc salt is difficult to generate zinc oxide nanoparticles; when a molar ratio of hydroxide ions to zinc ions is greater than 2.5:1, the alkaline solution is excessive, and the excess hydroxide ions form a stable complex with the zinc hydroxide intermediate, which is difficult to polycondensate to form zinc oxide nanoparticles. In some embodiments, during mixing the zinc salt solution and the alkaline solution: the addition amount of the zinc salt solution and the alkaline solution meets the requirement that the hydroxide ions provided by the alkaline solution and the zinc ions provided by the zinc salt are at a molar ratio of 1.7:1 to 1.9:1.

In some embodiments, the addition of the amino ligands and/or the carboxyl ligands with 3 to 7 carbon atoms meets the requirement that the amino ligands and/or the carboxyl ligands with 3 to 7 carbon atoms has a molar ratio of 1:1 to 10:1 with zinc salt in the zinc salt solution. In this case, the addition of the amino ligands and/or the carboxyl ligands with 3 to 7 carbon atoms is bonded with the surfaces of the obtained zinc oxide nanoparticles, such that the surfaces of the zinc oxide nanoparticles have less hydroxyl ligands, which is conducive to improving the service life of the device. However, when the additive amount of the amino ligands and/or the carboxyl ligands with 3 to 7 carbon atoms is excessive, there may be too many ligands connected to the surface of zinc oxide, reducing the electron mobility of zinc oxide, which is not conducive to the achievement of long-life devices. When the ligand volume is too low, the ligands connected to the surface of zinc oxide are insufficient, and are not prone to reduce the surface hydroxyl content, which is also not prone to achieve a long-life device. In some embodiments, the amino ligands and/or the carboxyl ligands has 3 to 4 carbon atoms, and the amino ligands and/or the carboxyl ligands with 3 to 7 carbon atoms and the zinc salt in the zinc salt solution are at a molar ratio of 4:1 to 10:1. In some embodiments, the amino ligands and/or the carboxyl ligands has 5 to 7 carbon atoms, and the amino ligands and/or the carboxyl ligands with 3 to 7 carbon atoms and the zinc salt in the zinc salt solution are at a molar ratio of 1:1 to 5:1. When a chain length is longer (5-7), the electron mobility of the sample after ligand exchange decreases, which is similar to the effect of increasing the hydroxyl content, so the amount of ligands with higher chain length should not be high. When the chain length is short (3-4), the electron mobility of the sample after ligand exchange will be enhanced, which is similar to the effect of reducing the hydroxyl content, so the amount of ligands with higher chain length can be higher.

In some embodiments, the zinc salt solution, the alkaline solution, and the amino ligands and/or the carboxyl ligands with 3 to 7 carbon atoms are mixed for a reaction at 0° C. to 70° C. for 30 min to 4 h, to obtain zinc oxide nanoparticles with the surface bonded with the amino ligands and/or the carboxyl ligands with 3 to 7 carbon atoms. In some embodiments, the mixing of the zinc salt solution and the alkaline solution includes: dissolving a zinc salt at room temperature (5° C. to 40° C.) to obtain the zinc salt solution, dissolving or diluting an alkali at room temperature to obtain the alkaline solution, and dissolving the amino ligands and/or the carboxyl ligands with 3 to 7 carbon atoms at room temperature to obtain the ligand solution; and adjusting the zinc salt solution to 0° C. to 70° C., and adding the alkaline solution and the ligand solution. In this case, the added alkali reacts with the zinc salt in the zinc salt solution to form zinc oxide nanoparticles; the added ligands are exchanged with hydroxyl ligands on the surface of zinc oxide nanoparticles to obtain zinc oxide nanoparticles with the amino ligands and/or the carboxyl ligands with 3 to 7 carbon atoms on the surface, with desirable particle dispersion. When the reaction temperature is lower than 0° C., the formation of zinc oxide nanoparticles is significantly slowed down, and even zinc oxide nanoparticles are not prone to be formed, and only hydroxide intermediates can be obtained. However, when the reaction temperature is higher than 70° C., the zinc oxide nanoparticles show serious agglomeration and poor dispersibility, which affects the late film formation of zinc oxide colloidal solution. In some embodiments, the reaction between the zinc salt solution and the alkaline solution is conducted at room temperature to 50° C. In this case, not only the formation of ZnO nanoparticles is beneficial, but also the obtained ZnO ions have better particle dispersion. This is beneficial to the film formation of the zinc oxide colloidal solution.

In some embodiments, during mixing the zinc salt solution and the alkaline solution: according to a molar ratio of the hydroxide ions to the zinc ions being 1.5:1 to 2.5:1, the zinc salt solution is mixed with the alkaline solution, to ensure the formation of ZnO nanoparticles and reduce the formation of reaction by-products. When a molar ratio of hydroxide ions to zinc ions is less than 1.5:1, the zinc salt content is excessive, and a large number of zinc salt is difficult to generate zinc oxide nanoparticles; when a molar ratio of hydroxide ions to zinc ions is greater than 2.5:1, the alkaline solution is excessive, and the excess hydroxide ions form a stable complex with the zinc hydroxide intermediate, which is difficult to polycondensate to form zinc oxide nanoparticles. In some embodiments, during mixing the zinc salt solution and the alkaline solution: the addition amount of the zinc salt solution and the alkaline solution meets the requirement that the hydroxide ions provided by the alkaline solution and the zinc ions provided by the zinc salt are at a molar ratio of 1.7:1 to 1.9:1.

In some embodiments, the zinc salt solution is mixed with the alkaline solution and reacted for 30 min to 4 h, so as to ensure the formation of zinc oxide nanoparticles and control a particle size of the nanoparticles. When the reaction time is less than 30 min, the reaction time is too short, the formation of the zinc oxide nanoparticles is insufficient, and the crystallinity of the obtained nanoparticles is poor. However, when the reaction time is more than 4 h, the long particle growth time makes the nanoparticles generated too large and the particle size is not uniform, thus affecting the late film formation of zinc oxide colloidal solution. In some embodiments, after adding the amino ligands and/or the carboxyl ligands with 3 to 7 carbon atoms, the reaction is conducted for 10 min to 2 hours. In some embodiments, the zinc salt solution and the alkaline solution are mixed and reacted at the reaction temperature for 1 hour to 2 hours.

In some embodiments, the zinc salt solution, the alkaline solution, and the amino ligands and/or the carboxyl ligands with 3 to 7 carbon atoms are mixed for a reaction at 0° C. to 70° C. under stirring to promote the uniformity of the reaction and the particle uniformity of the obtained zinc oxide nanoparticles.

In some embodiments, a precipitant is added to a mixed solution obtained at the end of the reaction and a precipitate is collected. The precipitant is a solvent whose polarity is opposite to that of the final zinc oxide nanoparticles, thereby reducing the solubility of the zinc oxide nanoparticles and precipitating them. In some embodiments, the precipitant is a less polar solvent. This type of precipitant is opposite to the polarity of zinc oxide nanoparticles, and is beneficial to the precipitation of zinc oxide nanoparticles. Exemplarily, the precipitant includes but not limited to ethyl acetate, acetone, n-hexane, n-heptane, and other long-chain alkanes with low polarity.

In some embodiments, 2 to 6 times a volume of the precipitant is added to the mixed solution after the reaction (that is, a volume ratio of the precipitant to the mixed solution is 2:1 to 6:1), and a white precipitate is produced in the mixed solution. In this case, it is ensured that under the premise of fully precipitating the zinc oxide nanoparticles, the solubility of the zinc oxide particles is not damaged due to too much precipitant. In some embodiments, the precipitant and the mixed solution are at a volume ratio of 3:1 to 5:1.

In the embodiments of the present disclosure, a precipitated mixed system is centrifuged to collect the precipitate. In some embodiments, the collected precipitate is washed with a reaction solvent to remove reactants that do not participate in the reaction. Cleaning the obtained zinc oxide nanoparticles with a reaction solvent can remove excess zinc salt, alkali and other raw materials for preparing the zinc oxide nanoparticles, so as to improve a purity of the zinc oxide nanoparticles. It should be noted that the reaction solvent is as described above. In some embodiments, the reaction solvent is selected from at least one of water, organic alcohols, organic ethers, and sulfones. This kind of reaction solvent has a large polarity, and can effectively remove the residual zinc salt, alkali and other raw material impurities and intermediate impurities in the zinc oxide nanoparticles. Exemplarily, the reaction solvent may be selected from at least one of water, methanol, ethanol, propanol, butanol, ethylene glycol, 2-methoxyethanol, and DMSO.

The zinc oxide colloidal solution is obtained by dissolving the washed precipitate.

In a second aspect, the amino ligands and/or the carboxyl ligands with 3 to 7 carbon atoms is added during the synthesis of the zinc oxide colloidal solution. That is, the amino ligands and/or the carboxyl ligands with 3 to 7 carbon atoms is added to a zinc oxide precursor solution that has been added with the alkaline solution.

At this time, the steps for preparing the zinc oxide colloidal solution by solution method include:
mixing the zinc salt solution and the alkaline solution, and then adding the amino ligands and/or the carboxyl ligands with 3 to 7 carbon atoms for a reaction for greater than or equal to 10 min, to obtain zinc oxide nanoparticles having the surfaces bonded with the amino ligands and/or the carboxyl ligands with 3 to 7 carbon atoms; and
dissolving the zinc oxide nanoparticles to obtain the zinc oxide colloidal solution.

In the above steps, the zinc salt solution is a salt solution formed when the zinc salt is dissolved in a solvent, and the alkaline solution is a solution formed by an alkali that can react with the zinc salt to produce zinc hydroxide. The selection of zinc salt and solvent in the zinc salt solution, the alkali in the alkaline solution and its formation mode, the selection of the solvent, and the addition ratio of zinc salt and alkaline solution in the reaction system are described in the first aspect.

In some embodiments, the amino ligands and/or the carboxyl ligands with 3 to 7 carbon atoms includes but is not limited to propionic acid, propylamine, butyric acid, butylamine, hexanoic acid, and hexylamine. In some embodiments, the amino ligands and/or the carboxyl ligands with 3 to 7 carbon atoms is configured to form a ligand solution and react with the zinc salt solution and the alkaline solution. The solvent in the ligand solution is selected with larger polarity, mainly considering the solubility of the reaction raw materials and products. Exemplarily, the solvent in the ligand solution is selected from at least one of methanol, ethanol, propanol, butanol, ethylene glycol, 2-methoxyethanol, and DMSO. In some embodiments, the amino ligands and/or the carboxyl ligands with 3 to 7 carbon atoms is a ligand solution, and the ligand solution has a concentration of (0.2-0.4) mmol/L. When the ligand concentration is too low, the addition of the amino ligands and/or the carboxyl ligands with 3 to 7 carbon atoms is too low, and it is difficult to achieve an effective ligand exchange effect. When the ligand concentration is too high, the addition of the amino ligands and/or the carboxyl ligands with 3 to 7 carbon atoms is too high, and a large number of ligands remaining in the solution may remain in the first ETL, thus affecting film forming quality and properties of ETL.

In the embodiments of the present disclosure, the reaction temperature and time for mixing the zinc salt solution with the alkaline solution are as described in the first implementation method.

In the embodiments of the present disclosure, an the amino ligands and/or the carboxyl ligands with 3 to 7 carbon atoms is added during the reaction to prepare zinc oxide nanoparticles with a surface bonded with the amino ligands and/or the carboxyl ligands with 3 to 7 carbon atoms.

In some embodiments, the addition of the amino ligands and/or the carboxyl ligands with 3 to 7 carbon atoms meets the requirement that the amino ligands and/or the carboxyl ligands with 3 to 7 carbon atoms has a molar ratio of 1:1 to 10:1 with zinc salt in the zinc salt solution. In this case, the addition of an the amino ligands and/or the carboxyl ligands with 3 to 7 carbon atoms is bonded with the surface of the resulting zinc oxide nanoparticle, such that the surface of the zinc oxide nanoparticles has less hydroxyl ligand, thus helping to improve the service life of the device. However, when there is excess the amino ligands and/or the carboxyl ligands with 3 to 7 carbon atoms, there may be too many ligands connected to the surface of zinc oxide, reducing the electron mobility of zinc oxide, which is not conducive to the achievement of long-life devices. When the ligand volume is too low, the ligands connected to the surface of zinc oxide are insufficient, and are not prone to reduce the surface hydroxyl content, which is also not prone to achieve a long-life device. In some embodiments, the amino ligands and/or the carboxyl ligands has 3 to 4 carbon atoms, and the amino ligands and/or the carboxyl ligands with 3 to 7 carbon atoms and the zinc salt in the zinc salt solution are at a molar ratio of 4:1 to 10:1. In some embodiments, the amino ligands and/or the carboxyl ligands has 5 to 7 carbon atoms, and the amino ligands and/or the carboxyl ligands with 3 to 7 carbon atoms and the zinc salt in the zinc salt solution are at a molar ratio of 1:1 to 5:1. When a chain length is longer (5-7), the electron mobility of the sample after ligand exchange decreases, which is similar to the effect of increasing the hydroxyl content, so the amount of ligands with higher chain length should not be high. When the chain length is short, the electron mobility of the sample after ligand exchange will be enhanced, which is similar to the effect of reducing the hydroxyl content, so the amount of ligands with higher chain length can be higher.

It should be noted that the reaction time of continuing the reaction after adding the amino ligands and/or the carboxyl ligands with 3 to 7 carbon atoms is greater than or equal to 10 min, such that the ligand and the hydroxyl groups on the surface of the generated zinc oxide nanoparticles (3-4) are fully exchanged. In some embodiments, after adding the amino ligands and/or the carboxyl ligands with 3 to 7 carbon atoms during the reaction, stirring is conducted for 10 min to 2 hours, such that the exchange reaction can be fully completed. In some implementations of, stirring is conducted for 30 min to 1 h.

In some embodiments, a precipitant is added to a mixed solution obtained at the end of the reaction and a precipitate is collected. The choice of precipitant is referred to the first aspect.

In the embodiments of the present disclosure, a precipitated mixed system is centrifuged to collect the precipitate. In some embodiments, the collected precipitate is washed with a reaction solvent to remove reactants that do not participate in the reaction. Cleaning the obtained zinc oxide nanoparticles with a reaction solvent can remove excess zinc salt, alkali and other raw materials for preparing the zinc oxide nanoparticles, so as to improve a purity of the zinc oxide nanoparticles. It should be noted that the reaction solvent is as described above. In some embodiments, the reaction solvent is selected from at least one of water, organic alcohols, organic ethers, and sulfones. This kind of reaction solvent has a large polarity, and can effectively remove the residual zinc salt, alkali and other raw material impurities and intermediate impurities in the zinc oxide nanoparticles. Exemplarily, the reaction solvent may be selected from at least one of water, methanol, ethanol, propanol, butanol, ethylene glycol, 2-methoxyethanol, and DMSO.

The zinc oxide colloidal solution is obtained by dissolving the washed precipitate.

In a third aspect, an the amino ligands and/or the carboxyl ligands with 3 to 7 carbon atoms is added after the preparation of a zinc oxide colloidal solution.

At this time, the steps for preparing the zinc oxide colloidal solution by solution method include:
mixing the zinc salt solution and the alkaline solution for a reaction to obtain zinc oxide nanoparticles, and then adding the amino ligands and/or the carboxyl ligands with 3 to 7 carbon atoms to continue the reaction, to obtain zinc oxide nanoparticles having surfaces bonded with the amino ligands and/or the carboxyl ligands with 3 to 7 carbon atoms; and
dissolving the zinc oxide nanoparticles to obtain the zinc oxide colloidal solution.

In the above steps, the zinc salt solution is a salt solution formed when the zinc salt is dissolved in a solvent, and the alkaline solution is a solution formed by an alkali that can react with the zinc salt to produce zinc hydroxide. The selection of zinc salt and solvent in the zinc salt solution, the alkali in the alkaline solution and its formation mode, the selection of the solvent, and the addition ratio of zinc salt and alkaline solution in the reaction system are described in the first aspect.

In some embodiments, the amino ligands and/or the carboxyl ligands with 3 to 7 carbon atoms, the choice of solvent in the ligand solution, and the concentration of the ligand solution are described in the first aspect.

In the embodiments of the present disclosure, the reaction temperature and time for mixing the zinc salt solution with the alkaline solution are as described in the first implementation method.

In the embodiments of the present disclosure, an the amino ligands and/or the carboxyl ligands with 3 to 7 carbon atoms is added after the preparation of zinc oxide nanoparticles to obtain zinc oxide nanoparticles with a surface bonded with the amino ligands and/or the carboxyl ligands with 3 to 7 carbon atoms.

In some embodiments, the addition of the amino ligands and/or the carboxyl ligands with 3 to 7 carbon atoms meets the requirement that the amino ligands and/or the carboxyl ligands with 3 to 7 carbon atoms has a molar ratio of 1:1 to 10:1 with zinc salt in the zinc salt solution. In this case, the addition of an the amino ligands and/or the carboxyl ligands with 3 to 7 carbon atoms is bonded with the surface of the obtained zinc oxide nanoparticles, such that the surfaces of the zinc oxide nanoparticles have less hydroxyl ligands, which is conducive to improve the service life of the device. However, when there is excess the amino ligands and/or the carboxyl ligands with 3 to 7 carbon atoms, there may be too many ligands connected to the surface of zinc oxide, reducing the electron mobility of zinc oxide, which is not conducive to the achievement of long-life devices. When the ligand volume is too low, the ligands connected to the surface of zinc oxide are insufficient, and are not prone to reduce the surface hydroxyl content, which is also not prone to achieve a long-life device. In some embodiments, the amino ligands and/or the carboxyl ligands has 3 to 4 carbon atoms, and the amino ligands and/or the carboxyl ligands with 3 to 7 carbon atoms and the zinc salt in the zinc salt solution are at a molar ratio of 4:1 to 10:1. In some embodiments, the amino ligands and/or the carboxyl ligands has 5 to 7 carbon atoms, and the amino ligands and/or the carboxyl ligands with 3 to 7 carbon atoms and the zinc salt in the zinc salt solution are at a molar ratio of 1:1 to 5:1. When a chain length is longer (5-7), the electron mobility of the sample after ligand exchange decreases, which is similar to the effect of increasing the hydroxyl content, so the amount of ligands with higher chain length should not be high. When the chain length is short, the electron mobility of the sample after ligand exchange will be enhanced, which is similar to the effect of reducing the hydroxyl content, so the amount of ligands with higher chain length can be higher.

It should be noted that the reaction time of continuing the reaction after adding the amino ligands and/or the carboxyl ligands with 3 to 7 carbon atoms is greater than or equal to 10 min, such that the ligand and the hydroxyl groups on the surface of the generated zinc oxide nanoparticles are fully exchanged. In some embodiments, after adding the amino ligands and/or the carboxyl ligands with 3 to 7 carbon atoms during the reaction, stirring is conducted for 10 min to 2 hours, such that the exchange reaction can be fully completed. In some implementations of, stirring is conducted for 30 min to 1 h.

In some embodiments, a precipitant is added to a mixed solution obtained at the end of the reaction and a precipitate is collected. The choice and addition of precipitant are referred to the first aspect.

In the embodiments of the present disclosure, a precipitated mixed system is centrifuged to collect the precipitate. In some embodiments, the collected precipitate is washed with a reaction solvent to remove reactants that do not participate in the reaction. Cleaning the obtained zinc oxide nanoparticles with a reaction solvent can remove excess zinc salt, alkali and other raw materials for preparing the zinc oxide nanoparticles, so as to improve a purity of the zinc oxide nanoparticles. It should be noted that the reaction solvent is as described above. In some embodiments, the reaction solvent is selected from at least one of water, organic alcohols, organic ethers, and sulfones. This kind of reaction solvent has a large polarity, and can effectively remove the residual zinc salt, alkali and other raw material impurities and intermediate impurities in the zinc oxide nanoparticles. Exemplarily, the reaction solvent may be selected from at least one of water, methanol, ethanol, propanol, butanol, ethylene glycol, 2-methoxyethanol, and DMSO.

The zinc oxide colloidal solution is obtained by dissolving the washed precipitate.

In a fourth aspect, an the amino ligands and/or the carboxyl ligands with 3 to 7 carbon atoms is added after the preparation and cleaning of a zinc oxide colloidal solution.

At this time, the steps for preparing the zinc oxide colloidal solution by solution method include:
mixing the zinc salt solution and the alkaline solution for a reaction, collecting a reaction product, and cleaning the reaction product to obtain zinc oxide nanoparticles; and
dissolving the zinc oxide nanoparticles, adding the amino ligands and/or the carboxyl ligands with 3 to 7 carbon atoms for a reaction, such that the amino ligands and/or the carboxyl ligands with 3 to 7 carbon atoms is bonded with the surface of the zinc oxide to obtain the zinc oxide colloidal solution.

In the above steps, the zinc salt solution is a salt solution formed when the zinc salt is dissolved in a solvent, and the alkaline solution is a solution formed by an alkali that can react with the zinc salt to produce zinc hydroxide. The selection of zinc salt and solvent in the zinc salt solution, the alkali in the alkaline solution and its formation mode, the selection of the solvent, and the addition ratio of zinc salt and alkaline solution in the reaction system are described in the first aspect.

In the embodiments of the present disclosure, the reaction temperature and time for the zinc salt solution are as described in the first implementation method.

In some embodiments, a precipitant is added to a mixed solution obtained at the end of the reaction and a precipitate is collected. The choice and addition of precipitant are referred to the first aspect.

In the embodiments of the present disclosure, a precipitated mixed system is centrifuged to collect a product. In some embodiments, the collected product is washed with a reaction solvent to remove reactants that do not participate in the reaction. Cleaning the obtained zinc oxide nanoparticles with a reaction solvent can remove excess zinc salt, alkali and other raw materials for preparing the zinc oxide nanoparticles, so as to improve a purity of the zinc oxide nanoparticles. It should be noted that the reaction solvent is as described above. In some embodiments, the reaction solvent is selected from at least one of water, organic alcohols, organic ethers, and sulfones. This kind of reaction solvent has a large polarity, and can effectively remove the residual zinc salt, alkali and other raw material impurities and intermediate impurities in the zinc oxide nanoparticles. Exemplarily, the reaction solvent may be selected from at least one of water, methanol, ethanol, propanol, butanol, ethylene glycol, 2-methoxyethanol, and DMSO.

In embodiments of the present disclosure, the zinc oxide nanoparticles are dissolved, the amino ligands and/or the carboxyl ligands with 3 to 7 carbon atoms is added for a reaction, such that the amino ligands and/or the carboxyl ligands with 3 to 7 carbon atoms are bonded with the surface of the zinc oxide to obtain the zinc oxide colloidal solution.

In some embodiments, the amino ligands and/or the carboxyl ligands with 3 to 7 carbon atoms includes but is not limited to propionic acid, propylamine, butyric acid, butylamine, hexanoic acid, and hexylamine. In some embodiments, the amino ligands and/or the carboxyl ligands with 3 to 7 carbon atoms is configured to form a ligand solution and react with the zinc salt solution and the alkaline solution. The solvent in the ligand solution is selected with larger polarity, mainly considering the solubility of the reaction raw materials and products. Exemplarily, the solvent in the ligand solution is selected from at least one of methanol, ethanol, propanol, butanol, ethylene glycol, 2-methoxyethanol, and DMSO. In some embodiments, the amino ligands and/or the carboxyl ligands with 3 to 7 carbon atoms is a ligand solution, and the ligand solution has a concentration of (0.05-0.1) mmol/L.

In some embodiments, the addition of the amino ligands and/or the carboxyl ligands with 3 to 7 carbon atoms meets the requirement that the amino ligands and/or the carboxyl ligands with 3 to 7 carbon atoms has a molar ratio of 1:4 to 4:1 with zinc salt in the zinc salt solution. In this case, the addition of an the amino ligands and/or the carboxyl ligands with 3 to 7 carbon atoms are bonded with the surfaces of the obtained zinc oxide nanoparticles, such that the surfaces of the zinc oxide nanoparticles have less hydroxyl ligands, which is conducive to improving the service life of the device. However, when there is excess the amino ligands and/or the carboxyl ligands with 3 to 7 carbon atoms, there may be too many ligands connected to the surface of zinc oxide, reducing the electron mobility of zinc oxide, which is not conducive to the achievement of long-life devices. When the ligand volume is too low, the ligands connected to the surface of zinc oxide are insufficient, and are not prone to reduce the surface hydroxyl content, which is also not prone to achieve a long-life device. In some embodiments, the amino ligands and/or the carboxyl ligands has 3 to 4 carbon atoms, and the amino ligands and/or the carboxyl ligands with 3 to 7 carbon atoms and the zinc salt in the zinc salt solution are at a molar ratio of 4:1 to 10:1. In some embodiments, the amino ligands and/or the carboxyl ligands has 5 to 7 carbon atoms, and the amino ligands and/or the carboxyl ligands with 3 to 7 carbon atoms and the zinc salt in the zinc salt solution are at a molar ratio of 1:1 to 5:1. When a chain length is longer (5-7), the electron mobility of the sample after ligand exchange decreases, which is similar to the effect of increasing the hydroxyl content, so the amount of ligands with higher chain length should not be high. When the chain length is short, the electron mobility of the sample after ligand exchange will be enhanced, which is similar to the effect of reducing the hydroxyl content, so the amount of ligands with higher chain length can be higher.

It should be noted that the reaction time of continuing the reaction after adding the amino ligands and/or the carboxyl ligands with 3 to 7 carbon atoms is greater than or equal to 10 min, such that the ligand and the hydroxyl groups on the surface of the generated zinc oxide nanoparticles are fully exchanged. In some embodiments, after adding the amino ligands and/or the carboxyl ligands with 3 to 7 carbon atoms during the reaction, stirring is conducted for 10 min to 2 hours, such that the exchange reaction can be fully completed. In some implementations of, stirring is conducted for 30 min to 1 h.

In one possible embodiment, the first ETL is a metal-doped zinc oxide film. Correspondingly, the zinc oxide in the first ETL is metal-doped zinc oxide. At this time, the zinc salt solution also contains doping metal ions. In this embodiment, the choice of doping metal ions and their doping amount are described above.

In some embodiments, the doping metal ions are selected from at least one of Mg²⁺ and Mn²⁺. In some embodiments, the doping metal ions are selected from at least one of Al³⁺, Y³⁺, La³⁺, Li⁺, Gd³⁺, Zr⁴⁺, and Ce⁴⁺.

In some embodiments, the zinc salt solution contains zinc ions and doping metal ions. In the step of mixing the zinc salt solution and the alkaline solution, the addition amount of the zinc salt solution and the alkaline solution satisfies: a product of the molar weight of the metal ions and a valence number and a molar weight of the hydroxide ions are at a ratio of 0.75:1 to 1.25:1. In this case, the zinc salt solution was mixed with alkaline solution to ensure the formation of metal-doped ZnO nanoparticles and reduce the formation of reaction by-products. When a molar ratio of hydroxide ions to metal ions is less than 0.75:1, the metal ion content is excessive, and the metal salt is difficult to generate metal-doped zinc oxide nanoparticles; when a molar ratio of hydroxide ions to zinc ions is greater than 1.25:1, the alkaline solution is significantly excessive, and the excess hydroxide ions form a stable complex with the zinc hydroxide intermediate, which is difficult to polycondensate to form zinc oxide nanoparticles. In some embodiments, in the step of mixing the zinc salt solution and the alkaline solution, the addition amount of the zinc salt solution and the alkaline solution satisfies a product of the molar weight of the metal ions and a valence number and a molar weight of the hydroxide ions are at a ratio of 0.85:1 to 0.95:1.

In the step S12, according to the type of the prepared QLED-based device, the zinc oxide colloidal solution is coated on a substrate of a prefabricated device, and a solvent is removed to obtain the zinc oxide film with an the amino ligands and/or the carboxyl ligands with 3 to 7 carbon atoms on the surface.

In some embodiments, the zinc oxide colloidal solution may be formed on the substrate of the prefabricated device by one of methods including but not limited to spin coating, blade coating, printing, spray coating, roll coating, and electrodeposition. After the zinc oxide colloidal solution is formed on the substrate of the prefabricated device, the solvent is removed by annealing to obtain a zinc oxide film having an the amino ligands and/or the carboxyl ligands with 3 to 7 carbon atoms bonded on the surface of the zinc oxide.

In a possible implementation manner, the QLED is an upright QLED, and the substrate of the prefabricated device includes an anode substrate and a quantum dot luminescent layer combined on the anode substrate. In some embodiments, the substrate of the prefabricated device further includes a hole functional layer arranged between the anode substrate and the quantum dot luminescent layer. The hole functional layer includes at least one of an HTL, an HIL, and an EBL.

In a possible implementation manner, the QLED is an inverted QLED, and the substrate of the prefabricated device is a cathode substrate. In some embodiments, the substrate of the prefabricated device further includes an EIL combined to a cathode surface of the cathode substrate.

In some embodiments, the first ETL can be used as an ETL alone.

In some embodiments, the ETL includes two zinc oxide films or n film lamination units composed of two zinc oxide films. The two zinc oxide films are named as a first ETL and a second ETL, respectively, and n is greater than or equal to 2. In some embodiments, n is an integer of greater than or equal to 2 and less than or equal to 9. At least the first ETL is a zinc oxide film prepared by the method and having a surface bonded with an amino ligand and/or a carboxyl ligand with 3 to 7 carbon atoms; for the situation of the second ETL, reference may be made to the situation in the second ETL of the QLED-based device above.

In some embodiments, the second ETL is a zinc oxide film with a surface hydroxyl content of greater than or equal to 0.6, or the second ETL is a metal-doped zinc oxide film. The first ETL can be set on one side adjacent to the quantum dot luminescent layer, or on one side adjacent to the cathode. Preferably, the first ETL is arranged on one side adjacent to the quantum dot luminescent layer or the metal-doped zinc oxide film is arranged on one side adjacent to the quantum dot luminescent layer, such that a smoother zinc oxide film can be obtained.

In some embodiments, the ETL includes three zinc oxide films. The three zinc oxide films are named as a first ETL, a second ETL, and a third ETL, respectively. At least the first ETL is a zinc oxide film prepared by the above method and having a surface bonded with an amino ligand and/or a carboxyl ligand with 3 to 7 carbon atoms; for the situation of the second ETL and the third ETL, reference may be made to the situation in the ETL including the third ETL in the QLED-based device above.

In the embodiments, the zinc oxide film with a surface hydroxyl content of greater than or equal to 0.6 may be formed by a zinc oxide colloidal solution with a surface hydroxyl content of greater than or equal to 0.6.

In the embodiments, a zinc oxide film with a surface hydroxyl content of less than or equal to 0.4 may be formed by a zinc oxide colloidal solution with a surface hydroxyl content of less than or equal to 0.4.

In the embodiments, the metal-doped zinc oxide films can be prepared by the following method:
mixing a zinc salt solution containing doping metal ions with a alkaline solution at 0° C. to 70° C. for 30 min to 4 h; adding a precipitant to a mixed solution obtained after the reaction and collecting a precipitate; cleaning the precipitate using a reaction solvent, and dissolving a resulting white precipitate to obtain a metal-doped zinc oxide colloidal solution; and coating the metal-doped zinc oxide colloidal solution on a substrate to be prepared to obtain the metal-doped zinc oxide film. In the embodiment, the type of zinc salt and solvent in the zinc salt solution and the content of the zinc salt solution, the type and doping content of doping ions, the type and addition amount of alkaline solution, the reaction temperature and reaction time, and the selection and addition amount of precipitant are conducted by reference to step S11 of the embodiment of the present disclosure. In this method, a solution of zinc salts containing doping metal ions can be obtained by dissolving zinc salts and selected metal salts in a solvent at room temperature in a certain proportion. During mixing the zinc salt solution containing doping metal ions with the alkaline solution, the amount of alkali added meets: a product of the molar weight of the metal ions and a valence number and a molar weight of the hydroxide ions are at a ratio of 0.75:1 to 1.25:1.

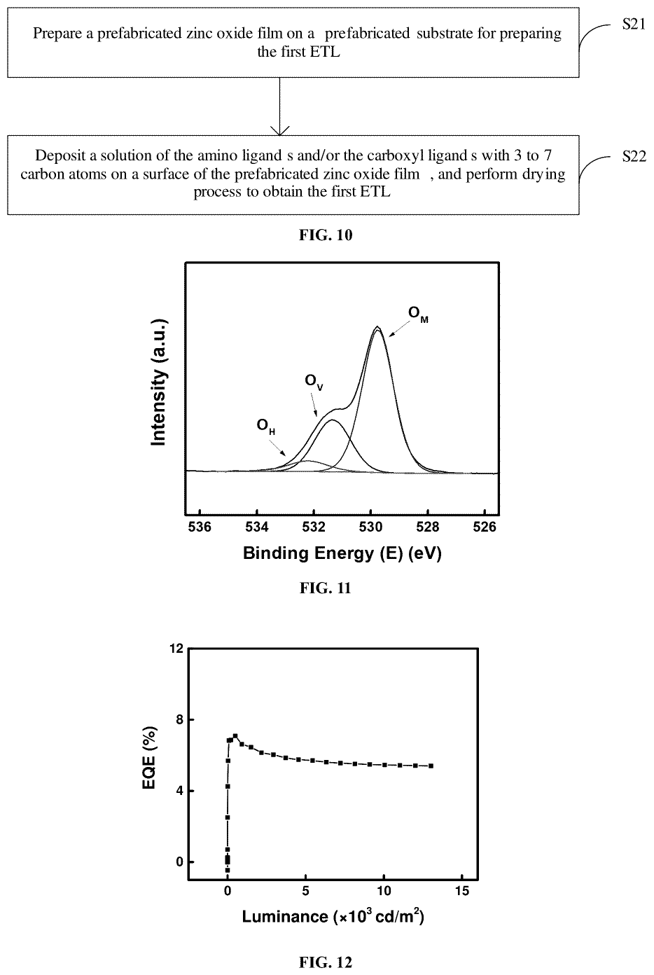

In the fifth embodiment, an embodiment of the present disclosure provides a preparation method of the QLED, where the QLED includes an anode and a cathode that are oppositely arranged, a quantum dot luminescent layer arranged between the anode and the cathode, and an ETL arranged between the quantum dot luminescent layer and the cathode. The ETL includes a first ETL containing zinc oxide, and a surface at one side of the first ETL includes an amino ligand and/or a carboxyl ligand with 3 to 7 carbon atoms; and
as shown in FIG. 10, a preparation method of the first ETL included the following steps:

S21, preparing a prefabricated zinc oxide film on a prefabricated substrate for preparing the first ETL; and

S22, depositing a solution of the amino ligands and/or the carboxyl ligands with 3 to 7 carbon atoms on a surface of the prefabricated zinc oxide film, and drying to obtain the first ETL.

In the preparation method of the QLED provided in the embodiments of the present disclosure, a solution of the amino ligands and/or the carboxyl ligands with 3 to 7 carbon atoms is deposited on the surface of the prefabricated zinc oxide film to induce ligand exchange between the amino ligands and/or the carboxyl ligands and the hydroxyl ligand on the surface of the zinc oxide colloidal solution. In this way, the amino ligands and/or the carboxyl ligands with 3 to 7 carbon atoms is coordinated on the surface of the zinc oxide colloid. The coordinated the amino ligands and/or the carboxyl ligands have a lower chain length and does not significantly increase a distance between zinc oxide nanoparticles in solution and after film formation. Meanwhile, the surface hydroxyl content of zinc oxide nanoparticles is reduced, and the electron mobility of zinc oxide ETL after film formation is increased. As a result, the service life of QLED-based devices is effectively improved.

In the embodiments of the present disclosure, the composition of the QLED, especially the situation of the ETL, is as described in the first aspect above. In order to save space, details are not repeated here.

In step S21, the prefabricated zinc oxide film can be prepared by various methods; as an example, the prefabricated zinc oxide film is prepared by solution method or sol-gel method.

In some embodiments, the prefabricated zinc oxide film is prepared by solution method, including: mixing a zinc salt solution mixed with a alkaline solution to obtain zinc oxide nanoparticles; dissolving the zinc oxide nanoparticles to obtain a zinc oxide colloidal solution; coating the zinc oxide colloidal solution on a prefabricated substrate for preparing the first ETL, and removing a solvent to obtain the prefabricated zinc oxide film.

The zinc oxide colloidal solution is prepared by a solution method, and the solution method may be one of an alcoholysis method, a hydrolysis method, and the like. A basic process of preparing zinc oxide by the solution method is: mixing the zinc salt solution with the alkaline solution for a reaction, to form a hydroxide intermediate such as zinc hydroxide; and subjecting the hydroxide intermediate to polycondensation to gradually generate zinc oxide nanoparticles.

In the embodiments of the present disclosure, the zinc salt solution, the basis and type of selection of zinc salt and solvent in zinc salt solution, and mode of formation of zinc salt solution are as described in the first aspect above.

In the embodiments of the present disclosure, the alkaline solution, the basis and type of selection of alkali and solvent in alkaline solution, and mode of formation of alkaline solution are as described in the first aspect above.

In some embodiments, the zinc salt solution and the alkaline solution are mixed and reacted at 0° C. to 70° C. for 30 min to 4 h to obtain zinc oxide nanoparticles. In some embodiments, the mixing of the zinc salt solution and the alkaline solution includes: dissolving a zinc salt at room temperature (5° C. to 40° C.) to obtain the zinc salt solution, dissolving or diluting an alkali at room temperature to obtain the alkaline solution; and adjusting the zinc salt solution to 0° C. to 70° C., and adding the alkaline solution. In this case, the added alkali reacts with the zinc salt in the zinc salt solution to form zinc oxide nanoparticles, with desirable particle dispersion. When the reaction temperature is lower than 0° C., the formation of ZnO nanoparticles may be significantly slowed down, and the reaction needs special equipment to realize. This increases the difficulty of the reaction, and even ZnO nanoparticles is not easily produced under some conditions, but only hydroxide intermediates can be obtained. When the reaction temperature is higher than 70° C., the reactivity is too high, and the generated zinc oxide nanoparticles have serious agglomeration. This is not prone to obtain a colloidal solution with high dispersibility, thus affecting the later film formation of the zinc oxide colloidal solution. In some embodiments, the reaction between the zinc salt solution and the alkaline solution is conducted at room temperature to 50° C. In this case, not only the formation of ZnO nanoparticles is beneficial, but also the obtained ZnO ions have better particle dispersion. This is beneficial to the film formation of the zinc oxide colloidal solution. In some embodiments, the zinc salt solution and the alkaline solution are mixed and treated at a temperature of 0° C. to 30° C. to easily form a qualified zinc oxide colloidal solution. In some embodiments, the zinc oxide colloidal solution can also be generated at a temperature of 30° C. to 70° C. However, the quality of the obtained zinc oxide colloidal solution is not as high as the zinc oxide colloidal solution generated under the condition of 0° C. to 30° C., and the reaction time is also reduced.

In some embodiments, during mixing the zinc salt solution and the alkaline solution: according to a molar ratio of the hydroxide ions to the zinc ions being 1.5:1 to 2.5:1, the zinc salt solution is mixed with the alkaline solution, to ensure the formation of ZnO nanoparticles and reduce the formation of reaction by-products. When a molar ratio of hydroxide ions to zinc ions is less than 1.5:1, the zinc salt content is excessive, and a large number of zinc salt is difficult to generate zinc oxide nanoparticles; when a molar ratio of hydroxide ions to zinc ions is greater than 2.5:1, the alkaline solution is excessive, and the excess hydroxide ions form a stable complex with the zinc hydroxide intermediate, which is difficult to polycondensate to form zinc oxide nanoparticles. In some embodiments, during mixing the zinc salt solution and the alkaline solution: the addition amount of the zinc salt solution and the alkaline solution meets the requirement that the hydroxide ions provided by the alkaline solution and the zinc ions provided by the zinc salt are at a molar ratio of 1.7:1 to 1.9:1.

In some embodiments of the present disclosure, the zinc salt solution is mixed with the alkaline solution and reacted at 0° C. to 70° C. for 30 min to 4 h, so as to ensure the formation of zinc oxide nanoparticles and control a particle size of the nanoparticles. When the reaction time is less than 30 min, cluster seeds of ZnO may be obtained if the reaction time is too low. At this time, the crystalline state of the sample is incomplete, and the crystal structure is poor, thus making the conductivity of the ETL poor if it is used as an ETL material. However, when the reaction time exceeds 4 h, the long particle growth time makes the generated nanoparticles too large and the particle size is not uniform. In this way, the surface roughness of the zinc oxide colloidal solution can be relatively high after film formation, thus affecting the electron transport performance. In some embodiments, the zinc salt solution and the alkaline solution are mixed and reacted at the reaction temperature for 1 hour to 2 hours.

In some embodiments, the zinc salt solution and the alkaline solution are mixed and reacted for 30 min to 4 h at 0° C. to 70° C. under stirring to promote the uniformity of the reaction and the particle uniformity of the obtained zinc oxide nanoparticles. Thus, zinc oxide nanoparticles with uniform size are obtained.

In some embodiments, the zinc oxide nanoparticles are dissolved to obtain the zinc oxide colloidal solution.

In some embodiments, a method for obtaining the zinc oxide nanoparticles further includes: adding a precipitant to a mixed solution obtained at the end of the reaction and collecting a precipitate. The precipitant is a solvent whose polarity is opposite to that of the final zinc oxide nanoparticles, thereby reducing the solubility of the zinc oxide nanoparticles and precipitating them. In some embodiments, the precipitant is a less polar solvent. This type of precipitant is opposite to the polarity of zinc oxide nanoparticles, and is beneficial to the precipitation of zinc oxide nanoparticles. Exemplarily, the precipitant includes but not limited to ethyl acetate, acetone, n-hexane, n-heptane, and other long-chain alkanes with low polarity.

In some embodiments, 2 to 6 times a volume of the precipitant is added to the mixed solution after the reaction (that is, a volume ratio of the precipitant to the mixed solution is 2:1 to 6:1), and a white precipitate is produced in the mixed solution. In this case, it is ensured that under the premise of fully precipitating the zinc oxide nanoparticles, the solubility of the zinc oxide particles is not damaged due to too much precipitant. In some embodiments, the precipitant and the mixed solution are at a volume ratio of 3:1 to 5:1.

In the embodiments of the present disclosure, a precipitated mixed system is centrifuged to collect the precipitate. The collected precipitate is washed with a reaction solvent to remove reactants that do not participate in the reaction. Cleaning the obtained zinc oxide nanoparticles with a reaction solvent can remove excess zinc salt, alkali and other raw materials for preparing the zinc oxide nanoparticles, so as to improve a purity of the zinc oxide nanoparticles. It should be noted that the reaction solvent is as described above. In some embodiments, the reaction solvent is selected from at least one of water, organic alcohols, organic ethers, and sulfones. Exemplarily, the reaction solvent may be selected from at least one of water, methanol, ethanol, propanol, butanol, ethylene glycol, 2-methoxyethanol, and DMSO.

A white precipitate is obtained after cleaning, and the white precipitate is dissolved to obtain a zinc oxide colloidal solution.

In one possible embodiment, the first ETL is a metal-doped zinc oxide film. Correspondingly, the zinc oxide in the first ETL is metal-doped zinc oxide. At this time, the zinc salt solution also contains doping metal ions. In this embodiment, the selection and doping amount of doping metal ions are the same as the selection and doping amount of doping metal in the above metal-doped zinc oxide film.

In the embodiments, according to the type of the prepared QLED-based device, the zinc oxide colloidal solution is coated on a prefabricated substrate for preparing the first ETL, and a solvent is removed to obtain the prefabricated zinc oxide film.

In some embodiments, the zinc oxide colloidal solution may be formed on the substrate of the prefabricated device by one of methods including but not limited to spin coating, blade coating, printing, spray coating, roll coating, and electrodeposition. After the zinc oxide colloidal solution is formed on the substrate of the prefabricated device, the solvent is removed by annealing to obtain a prefabricated zinc oxide film.

In some embodiments, the prefabricated zinc oxide film is prepared by sol-gel method (high-temperature calcination method). Specifically, a zinc oxide precursor is directly spun on the substrate to be prepared prefabricated zinc oxide film, and then the zinc oxide is obtained by high-temperature heat treatment.

In step S22, a solution of the amino ligands and/or the carboxyl ligands with 3 to 7 carbon atoms is deposited on the surface of the prefabricated zinc oxide film to induce ligand exchange between the amino ligands and/or the carboxyl ligands and the hydroxyl ligand on the surface of the zinc oxide colloidal solution. In this way, the amino ligands and/or the carboxyl ligands with 3 to 7 carbon atoms is coordinated on the surface of the zinc oxide colloid.

In embodiments of the present disclosure, a ligand solution of the amino ligands and/or the carboxyl ligands with 3 to 7 carbon atoms means a ligand solution obtained by dissolving the amino ligands and/or the carboxyl ligands with 3 to 7 carbon atoms in a solvent by coordination. In some embodiments, the amino ligands and/or the carboxyl ligands with 3 to 7 carbon atoms includes but is not limited to propionic acid, propylamine, butyric acid, butylamine, hexanoic acid, and hexylamine. In some embodiments, the solvent used to dissolve the amino ligands and/or the carboxyl ligands with 3 to 7 carbon atoms includes but is not limited to, one of the more polar solvents such as water and alcohols. As an example, the solvents used to dissolve the amino ligands and/or the carboxyl ligands with 3 to 7 carbon atoms is at least one of water, methanol, ethanol, propanol, butanol, ethylene glycol, 2-methoxyethanol, and DMSO.

In embodiments of the present disclosure, the concentration and addition of the solution of the amino ligands and/or the carboxyl ligands with 3 to 7 carbon atoms are required to be controlled. When the ligand concentration is too low, the addition of the amino ligands and/or the carboxyl ligands with 3 to 7 carbon atoms is too low, and it is difficult to achieve an effective ligand exchange effect. When the ligand concentration is too high, the addition of the amino ligands and/or the carboxyl ligands with 3 to 7 carbon atoms is too high, and a large number of ligands remaining in the solution may directly remain in the final first ETL, thus affecting film forming quality and properties of ETL. In some embodiments, the amino ligands and/or the carboxyl ligands with 3 to 7 carbon atoms is a ligand solution, and the ligand solution has a concentration of (0.05-0.5) mmol/L. When the ligand concentration is too low, the addition of the amino ligands and/or the carboxyl ligands with 3 to 7 carbon atoms is too low, and it is difficult to achieve an effective ligand exchange effect. When the ligand concentration is too high, the addition of the amino ligands and/or the carboxyl ligands with 3 to 7 carbon atoms is too high, and a large number of ligands remaining in the solution may directly remain in the final first ETL, thus affecting film forming quality and properties of ETL.

The ligand solution of the amino ligands and/or the carboxyl ligands with 3 to 7 carbon atoms has a concentration of (0.05-0.5) mmol/L. In the step following the deposition of a solution of the amino ligands and/or the carboxyl ligands with 3 to 7 carbon atoms on the surface of the prefabricated zinc oxide film, the addition of the amino ligands and/or the carboxyl ligands with 3 to 7 carbon atoms meets: every 5 mg of the prefabricated zinc oxide film is deposited with 50 μL to 1,000 μL of the ligand solution of the amino ligands and/or the carboxyl ligands with 3 to 7 carbon atoms. When the ligand chain length is longer (5-7), the electron mobility of the sample after ligand exchange decreases, which is similar to the effect of increasing the hydroxyl content, so the amount of ligands with higher chain length should not be high. When the ligand chain length is short (3-4), the electron mobility of the sample after ligand exchange will be enhanced, which is similar to the effect of reducing the hydroxyl content, so the amount of ligands with higher chain length can be higher. In some embodiments, when the amino ligands and/or the carboxyl ligands with 3 to 7 carbon atoms has 3 to 4 carbon atoms, 100 μL to 500 μL of the solution of the amino ligands and/or the carboxyl ligands with 3 to 7 carbon atoms is deposited on per 5 mg of the prefabricated zinc oxide film. When the amino ligands and/or the carboxyl ligands with 3 to 7 carbon atoms has 5 to 7 carbon atoms, 50 μL to 400 μL of the solution of the amino ligands and/or the carboxyl ligands with 3 to 7 carbon atoms is deposited on per 5 mg of the prefabricated zinc oxide film.

In the embodiments of the present disclosure, a method of depositing the ligand solution of amino ligand and/or the carboxyl ligand with 3 to 7 carbon atoms on the surface of the prefabricated zinc oxide film may be a solution processing method, including but not limited to spin coating, blade coating, printing, spray coating, roll coating, and electrodeposition.

The surface of the prefabricated zinc oxide film is dried after depositing the solution of the amino ligands and/or the carboxyl ligands with 3 to 7 carbon atoms; the drying process makes the ligands in the solution of the amino ligands and/or the carboxyl ligands with 3 to 7 carbon atoms to be fully exchanged with the hydroxyl groups on the surface of the zinc oxide. In some embodiments, the drying process is conducted at 10° C. to 100° C. for 10 min to 2 hours. In this case, electric ligands in the amino ligands and/or the carboxyl ligands with 3 to 7 carbon atoms reacts fully with the hydroxyl groups on the surface of zinc oxide to reduce the surface hydroxyl content of zinc oxide. If the drying temperature is too high or the drying time is too long, the amino ligands and/or the carboxyl ligands with 3 to 7 carbon atoms is quickly dried, and the prefabricated zinc oxide film quickly becomes a solid film. This makes ligands in the amino ligands and/or the carboxyl ligands with 3 to 7 carbon atoms unable to fully react with the hydroxyl groups on the surface of zinc oxide, and it is not prone to fully reduce the surface hydroxyl content of zinc oxide. When the drying temperature is too low or the drying time is too short, the prefabricated zinc oxide film is difficult to be dried fully. This affects the preparation of the next layer, especially an evaporation quality of the electrode. In some embodiments, the drying process is conducted at 10° C. to 50° C. for 30 min to 2 hours.

In a possible implementation manner, the QLED is an upright QLED, and the substrate of the prefabricated device includes an anode substrate and a quantum dot luminescent layer combined on the anode substrate. In some embodiments, the substrate of the prefabricated device further includes a hole functional layer arranged between the anode substrate and the quantum dot luminescent layer. The hole functional layer includes at least one of an HTL, an HIL, and an EBL.

In a possible implementation manner, the QLED is an inverted QLED, and the substrate of the prefabricated device is a cathode substrate. In some embodiments, the substrate of the prefabricated device further includes an EIL combined to a cathode surface of the cathode substrate.

In some embodiments, the first ETL can be used as an ETL alone.

In some embodiments, the ETL includes two zinc oxide films or n film lamination units composed of two zinc oxide films. The two zinc oxide films are named as a first ETL and a second ETL, respectively, and n is greater than or equal to 2. In some embodiments, n is an integer of greater than or equal to 2 and less than or equal to 9. At least the first ETL is a zinc oxide film prepared by the method and having a surface bonded with an amino ligand and/or a carboxyl ligand with 3 to 7 carbon atoms; for the situation of the second ETL, reference may be made to the situation in the second ETL of the QLED-based device above.

In some embodiments, the second ETL is a zinc oxide film with a surface hydroxyl content of greater than or equal to 0.6, or the second ETL is a metal-doped zinc oxide film. The first ETL can be set on one side adjacent to the quantum dot luminescent layer, or on one side adjacent to the cathode. Preferably, the first ETL is arranged on one side adjacent to the quantum dot luminescent layer or the metal-doped zinc oxide film is arranged on one side adjacent to the quantum dot luminescent layer, such that a smoother zinc oxide film can be obtained.

In some embodiments, the ETL includes three zinc oxide films. The three zinc oxide films are named as a first ETL, a second ETL, and a third ETL, respectively. At least the first ETL is a zinc oxide film prepared by the above method and having a surface bonded with an amino ligand and/or a carboxyl ligand with 3 to 7 carbon atoms; for the situation of the second ETL and the third ETL, reference may be made to the situation in the ETL including the third ETL in the QLED-based device above.

In the embodiments, the zinc oxide film with a surface hydroxyl content of greater than or equal to 0.6 may be formed by a zinc oxide colloidal solution with a surface hydroxyl content of greater than or equal to 0.6.

In the embodiments, a zinc oxide film with a surface hydroxyl content of less than or equal to 0.4 may be formed by a zinc oxide colloidal solution with a surface hydroxyl content of less than or equal to 0.4.

In the embodiments, the metal-doped zinc oxide film is described above. In order to save space, details are not repeated here.

It should be understood that in the above two embodiments of this application, when the device is an upright QLED, after the ETL is prepared, the cathode is also evaporated on the ETL to obtain the QLED. In some embodiments, the EIL is also prepared on the ETL prior to evaporation of the cathode. When the device is an inverted QLED, after the ETL is prepared, a quantum dot luminescent layer is also prepared on the ETL, and the QLED is obtained by evaporating an anode on the quantum dot luminescent layer. In some embodiments, a hole functional layer is also prepared on the quantum dot luminescent layer prior to evaporation of the anode.

In the embodiments of the present disclosure, the formation of the hole functional layer (including at least one of HIL, HTL, and EBL) and the quantum dot luminescent layer is preferably conducted by solution processing, including but not limited to spin coating, blade coating, printing, spray coating, roll coating, and electrodeposition.

In one possible implementation, a zinc oxide film with a surface hydroxyl content of greater than or equal to 0.6 can be prepared by the following method. A preparation method included the following steps:
Mixing a zinc salt solution with a first alkaline solution to obtain zinc oxide; dissolving the zinc oxide to obtain a zinc oxide colloidal solution; adding the zinc oxide colloidal solution with a second alkaline solution to adjust a pH value of the zinc oxide colloidal solution to be greater than or equal to 8 to obtain a zinc oxide solution; and
coating the zinc oxide solution on a prefabricated substrate for preparing the zinc oxide film with a surface hydroxyl content of greater than or equal to 0.6, and removing a solvent to obtain the zinc oxide film with a surface hydroxyl content of greater than or equal to 0.6.

In some embodiments, during adding the second alkaline solution to the zinc oxide colloidal solution to adjust a pH value of the zinc oxide colloidal solution to be greater than or equal to 8: the second alkaline solution is added to the zinc oxide colloidal solution such that an obtained mixed solution has a pH value of 9 to 12.

In some embodiments, during adding the second alkaline solution to the zinc oxide colloidal solution to adjust a pH value of the zinc oxide colloidal solution to be greater than or equal to 8: the second alkaline solution is added to the zinc oxide colloidal solution such that an obtained mixed solution has a pH value of 9 to 10.

Typically, an alkali in the second alkaline solution is at least one of potassium hydroxide, sodium hydroxide, lithium hydroxide, TMAH, ammonia water, ethanolamine, and ethylenediamine.

As an example, the first alkaline solution is prepared by at least one of potassium hydroxide, sodium hydroxide, lithium hydroxide, TMAH, ammonia water, ethanolamine, and ethylenediamine.

The solvent in the zinc salt solution and the solvent in the first alkaline solution are independently water, organic alcohols, organic ethers, and sulfones.

In some embodiments, a solvent in the second alkaline solution is at least one of water, methanol, ethanol, propanol, butanol, ethylene glycol, 2-methoxyethanol, and DMSO.

In the above embodiments of this application, the prepared QLED is packaged, and a packaging process can adopt common machine packaging or manual packaging. Preferably, the oxygen content and water content in the packaged environment are less than 0.1 ppm to ensure the stability of the device. A curing resin used in the packaging is acrylic resin, acrylate resin, or epoxy resin; the resin is cured by UV irradiation, heating, or a combination of two.

In some embodiments, after packaging the prepared QLED according to the performance requirements of the QLE-based device, the method also includes one or more treatments including ultraviolet irradiation, heating, positive and negative pressure, applied electric field, and applied magnetic field on the obtained QLED. This improves the performance of one or more aspects of the QLED-based device. An atmosphere in which the process is applied can be air or inert gas.

The present application will be described below with reference to specific examples.

Firstly, three detection methods used in embodiments of the present disclosure are introduced:

(1) X-ray photoelectron spectroscopy (XPS) is a method of surface analysis. X-rays of a certain energy are used to radiate a sample, causing the inner electrons or valence electrons of atoms or molecules to be excited out. The electrons excited by photons are called photoelectrons, which can measure energy and number of photoelectrons to obtain a composition of the object to be measured. This technique can effectively distinguish between three chemical states of oxygen present in zinc oxide materials: lattice oxygen attached to metal atoms, oxygen defects formed during crystal growth, and hydroxyl oxygen. When using XPS for surface hydroxyl testing, an equipment model is: Thermo Fei NEXSA; a sample preparation method includes: diluting a prepared zinc oxide solution to 30 mg/mL, spin-coating on a pre-treated glass sheet into film. A calculation method of hydroxyl content is as follows: a ratio of hydroxyl oxygen peak area to lattice oxygen peak area is the ratio of hydroxyl content:

$${R}_{OH} = \frac{{A}_{OH}}{{A}_{MO}} ,$$

as shown in FIG. 11.

(2) External quantum efficiency test method of current-voltage-luminance (JVL) equipment
Device model: Keithley 2400/6485

The external quantum efficiency parameters mainly include six parameters: voltage, current, brightness, external quantum dot efficiency, power efficiency, and luminescence spectrum. A certain voltage output is applied in a cassette to make the device conductive and luminous and an instant current is recorded, and the light source is collected by silicon photodiode. The G (λ) human visual function and S (λ) normalized electroluminescence spectra can be calculated by analyzing the spectral data while obtaining the color coordinates. Therefore, the calculation method of current efficiency ηA is:

$${η}_{A} = \frac{L}{{J}_{D}}$$

L represents the brightness read out by the silicon photodiode; JD represents the device current density, which is a ratio of the device area (a) to the current flowing through the device (I).

The external quantum efficiency ηEQE is calculated as follows:

$${η}_{EQE} = \frac{q π}{hc} \cdot \frac{\int λ S ( λ ) d λ}{\int G ( λ ) S ( λ ) d λ} \cdot {η}_{A}$$

q represents the basic charge, h represents Planck's constant, and c represents the speed of light in vacuum.

A maximum EQE value of the EQE-luminance curve, read from FIG. 12 of the example, is an external quantum efficiency of the device.

(3) QLED service life test system

Model: New Vision NVO-QLED-LT-128

Working Principle:

A 128-way QLED service life test system, through the central processing computer PCI bus communication, controls NI (National Instruments) digital IO card to achieve the path selection and digital signal output. The corresponding digital signal is converted to analog signal by D/A chip to complete current output (I), and data acquisition is realized by a data acquisition card. The acquisition of brightness is to convert the light signal into an electrical signal by a sensor, and the electrical signal is used to simulate the brightness change (L).

Test Method:

QLED service life test method (constant-current method)

(A) three or four different constant-current densities are selected, such as 100 mA cm\hat{ }2, 50 mA cm\hat{ }2, 20 mA cm\hat{ }2, and 10 mA cm\hat{ }2, and initial brightness is tested under the appropriate conditions.

(B) a constant current is maintained and changes are recorded in brightness and device voltage over time.

(C) the time of device decay to T95, T80, T75, T50 are recorded at different constant currents.

(D) acceleration factors are calculated by curve fitting.

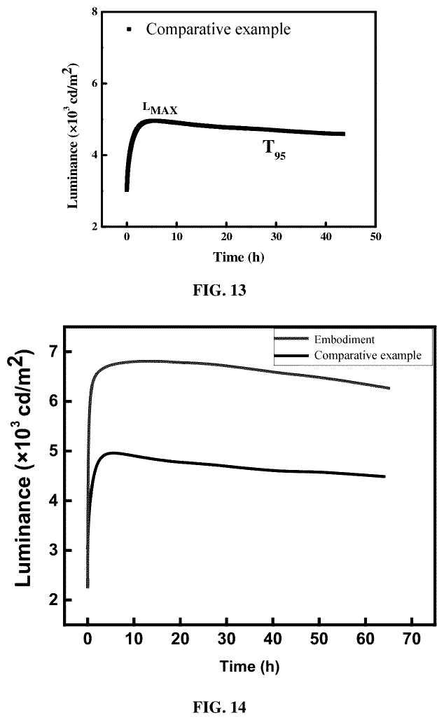

(E) the service life of the device at 1000 nit T95, T80, T75, and T50 is extrapolated by empirical formulas, as shown in FIG. 13.

Calculation method: T_{T95@1000nits}=(L_{MAX}/1000)\hat{ }A*T₉₅

L_{MAX} represents maximum brightness;

A represents acceleration factor; and

T₉₅ represents the time during which the maximum brightness of the device decays to 95%.

### Embodiment 1

A QLED included an anode substrate and a cathode that were oppositely arranged, a quantum dot luminescent layer arranged between the anode and the cathode, an HTL arranged between the anode and the quantum dot luminescent layer, an HIL arranged between the anode and the HTL, and an ETL between the quantum dot luminescent layer and the cathode. The anode was ITO (55 nm), the HIL was PEDOT:PSS (50 nm), the HTL was TFB (30 nm), the quantum dot luminescent layer was red quantum dots CdₓZn₁₋ₓSe/ZnSe (40 nm), the ETL was a ZnO material (50 nm) prepared by the following method, and the cathode was an Ag electrode (100 nm).

A preparation method of the QLED included the following steps:
the HIL, the HTL, and the quantum dot luminescent layer were sequentially prepared on the anode substrate;
the ETL was prepared on the quantum dot luminescent layer; and
a top electrode was evaporated or sputtered on the zinc oxide ETL or zinc oxide-doped ETL to obtain the QLED.

A preparation method of the ETL included the following steps:

Step I:
(A) zinc acetate was dissolved in DMSO at room temperature to obtain a zinc salt solution with a concentration of 0.6 mol/L, and sodium hydroxide was dissolved in methanol at room temperature to obtain a alkaline solution with a concentration of 0.96 mol/L, where hydroxide ions and zinc ions were at a molar ratio of 1.6:1;
(B) the zinc salt solution was adjusted to 40° C., the alkaline solution was added dropwise into the zinc salt solution according to a molar ratio of hydroxide ions to zinc ions at 1.6:1, and then an obtained mixed solution was continuously stirred for a reaction at 40° C. for 80 min;
(C) a precipitant was added at a volume ratio of 4.5:1 to a mixed solution obtained after the reaction, such that a white precipitate was formed in the mixed solution; and
(D) the precipitate was washed 3 times with methanol as a reaction solvent, and an obtained white precipitate was dissolved to obtain a zinc oxide colloidal solution with a surface hydroxyl content of 0.3.

Step II: the zinc oxide colloidal solution was coated on the quantum dot luminescent layer, and the reaction solvent was removed to obtain the zinc oxide film with the surface hydroxyl content of less than or equal to 0.4.

The hydroxyl groups in the zinc oxide of the ETL were detected by XPS, and it was determined that the ETL had a hydroxyl group content of 0.3.

### Comparative Example 1

This comparative example differed from Embodiment 1 in that ordinary zinc oxide nanoparticles were used as the ETL material. The hydroxyl groups in the zinc oxide of the ETL were detected by XPS, and it was determined that the ETL had a hydroxyl group content of 0.7.

FIG. 14 showed a lifetime test result of QLED-based devices provided by Embodiment 1 and Comparative Example 1.

### Embodiment 2

A QLED included an anode substrate and a cathode that were oppositely arranged, a quantum dot luminescent layer arranged between the anode and the cathode, an HTL arranged between the anode and the quantum dot luminescent layer, an HIL arranged between the anode and the HTL, and an ETL between the quantum dot luminescent layer and the cathode. The anode was ITO (55 nm), the HIL was PEDOT:PSS (50 nm), the HTL was TFB (30 nm), the quantum dot luminescent layer was red quantum dots CdₓZn₁₋ₓSe/ZnSe (40 nm), the ETL was a ZnO material prepared by the following method, and the cathode was an Ag electrode (100 nm).

A preparation method of the QLED included the following steps:
the HIL, the HTL, and the quantum dot luminescent layer were sequentially prepared on the anode substrate;
the ETL was prepared on the quantum dot luminescent layer; and
a top electrode was evaporated or sputtered on the zinc oxide ETL or zinc oxide-doped ETL to obtain the QLED.

A preparation method of the ETL included the following steps:

(1): (A) zinc chloride was dissolved in DMSO at room temperature to obtain a zinc salt solution with a concentration of 0.8 mol/L, and ammonia water was dissolved in butanol at room temperature to obtain a alkaline solution with a concentration of 1.2 mol/L, where hydroxide ions and zinc ions were at a molar ratio of 1.5:1; (B) the zinc salt solution was adjusted to 40° C., the alkaline solution was added dropwise into the zinc salt solution according to a molar ratio of hydroxide ions to zinc ions at 1.5:1, and then an obtained mixed solution was continuously stirred for a reaction at 40° C. for 60 min; (C) a precipitant was added at a volume ratio of 5:1 to a mixed solution obtained after the reaction, such that a white precipitate was formed in the mixed solution; and (D) the precipitate was washed 2 times with methanol as a reaction solvent, and an obtained white precipitate was dissolved to obtain a first zinc oxide colloidal solution at a concentration of 0.6 mol/L.

(2): (A) zinc chloride was dissolved in DMSO at room temperature to obtain a zinc salt solution with a concentration of 0.8 mol/L, and potassium hydroxide was dissolved in ethanol at room temperature to obtain a alkaline solution with a concentration of 1.2 mol/L; (B) the zinc salt solution was adjusted to 45° C., the alkaline solution was added dropwise into the zinc salt solution according to a molar ratio of hydroxide ions to zinc ions at 1.5:1, and then an obtained mixed solution was continuously stirred for a reaction at 45° C. for 60 min; (C) a precipitant was added at a volume ratio of 5:1 to a mixed solution obtained after the reaction, such that a white precipitate was formed in the mixed solution; and (D) the precipitate was washed 2 times with ethanol as a reaction solvent, and an obtained white precipitate was dissolved to obtain a second zinc oxide colloidal solution at a concentration of 0.6 mol/L.

(3) the first zinc oxide colloidal solution was coated on the quantum dot luminescent layer, a solvent was removed to obtain a first zinc oxide film with a surface hydroxyl content of 0.3 and a thickness of 60 nm; the second zinc oxide colloidal solution was coated on the first zinc oxide film, a solvent was removed to obtain a second zinc oxide film with a surface hydroxyl content of 0.7 and a thickness of 20 nm.

The hydroxyl groups in the zinc oxide of the first ETL and the second ETL were detected by XPS, and it was determined that the first ETL had a hydroxyl content of 0.3, and the second ETL had a hydroxyl content of 0.7.

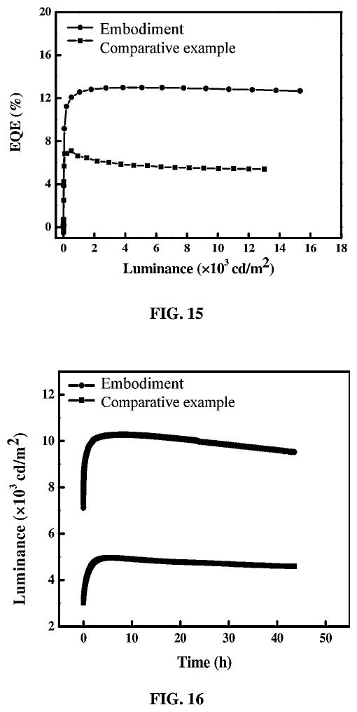

The QLEDs provided in Embodiment 2 and Comparative Example 1 had device EQE test results shown in FIG. 15 and service lifetime test results shown in FIG. 16.

### Embodiment 3

A QLED included an anode substrate and a cathode that were oppositely arranged, a quantum dot luminescent layer arranged between the anode and the cathode, an HTL arranged between the anode and the quantum dot luminescent layer, an HIL arranged between the anode and the HTL, and an ETL between the quantum dot luminescent layer and the cathode. The anode was ITO (55 nm), the HIL was PEDOT:PSS (50 nm), the HTL was TFB (30 nm), the quantum dot luminescent layer was red quantum dots CdₓZn₁₋ₓSe/ZnSe (40 nm), the ETL was a ZnO material prepared by the following method, and the cathode was an Ag electrode (100 nm).

A preparation method of the QLED included the following steps:
the HIL, the HTL, and the quantum dot luminescent layer were sequentially prepared on the anode substrate;
the ETL was prepared on the quantum dot luminescent layer; and
a top electrode was evaporated or sputtered on the zinc oxide ETL or zinc oxide-doped ETL to obtain the QLED.

A preparation method of the ETL included the following steps:

(1): (A) zinc acetate was dissolved in DMSO at room temperature to obtain a zinc salt solution with a concentration of 0.5 mol/L, and sodium hydroxide was dissolved in methanol at room temperature to obtain a alkaline solution with a concentration of 0.85 mol/L, where hydroxide ions and zinc ions were at a molar ratio of 1.7:1;
(B) the zinc salt solution was adjusted to 60° C., the alkaline solution was added dropwise into the zinc salt solution according to a molar ratio of hydroxide ions to zinc ions 1.7:1, and then an obtained mixed solution was continuously stirred for a reaction at 60° C. for 90 min;
(C) a precipitant was added at a volume ratio of 3:1 to a mixed solution obtained after the reaction, such that a white precipitate was formed in the mixed solution; and
(D) the white precipitate was dissolved, and 0.05 mol/L hydrochloric acid was added to the zinc oxide colloidal solution to adjust a pH value to 7.2, to obtain a first zinc oxide colloidal solution with a hydroxyl content of 0.25.

(2): (A) zinc acetate was dissolved in DMSO at room temperature to obtain a zinc salt solution with a concentration of 0.5 mol/L, and sodium hydroxide was dissolved in methanol at room temperature to obtain a alkaline solution with a concentration of 0.85 mol/L, where hydroxide ions and zinc ions were at a molar ratio of 1.7:1;
(B) the zinc salt solution was adjusted to 60° C., the alkaline solution was added dropwise into the zinc salt solution according to a molar ratio of hydroxide ions to zinc ions 1.7:1, and then an obtained mixed solution was continuously stirred for a reaction at 60° C. for 90 min;
(C) a precipitant was added at a volume ratio of 3:1 to a mixed solution obtained after the reaction, such that a white precipitate was formed in the mixed solution; and
(D) the white precipitate was dissolved, and 0.1 mol/L sodium hydroxide was added to the zinc oxide colloidal solution to adjust a pH value to 8, to obtain a second zinc oxide colloidal solution with a hydroxyl content of 0.85.

(3) the second zinc oxide colloidal solution was coated on the quantum dot luminescent layer, a solvent was removed to obtain a second zinc oxide film with a surface hydroxyl content of 0.85; the first zinc oxide colloidal solution was coated on the second zinc oxide film, a solvent was removed to obtain a first zinc oxide film with a surface hydroxyl content of 0.25. The first zinc oxide layer had a thickness of 60 nm, and the second zinc oxide layer had a thickness of 30 nm.

The hydroxyl groups in the first ETL and the second ETL were detected by XPS, and it was determined that the first ETL had a hydroxyl content of 0.25, and the second ETL had a hydroxyl content of 0.85.

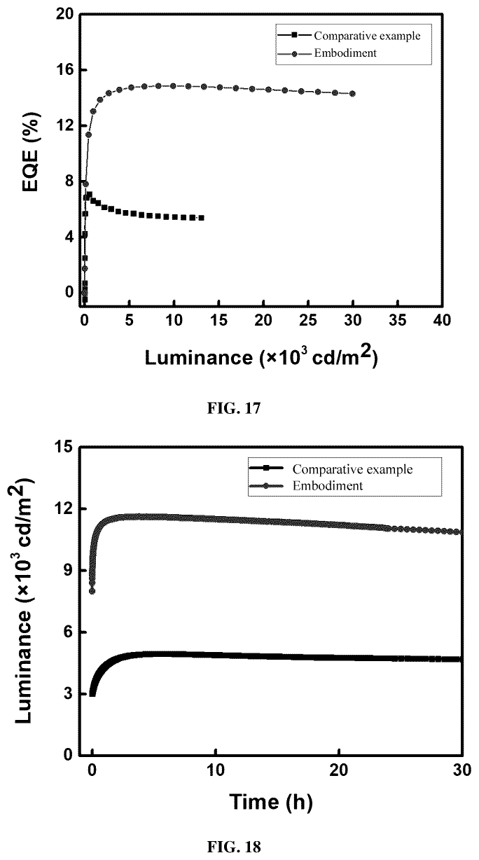

The QLEDs provided in Embodiment 3 and Comparative Example 1 had device EQE test results shown in FIG. 17 and service lifetime test results shown in FIG. 18.

### Embodiment 4

A QLED included an anode substrate and a cathode that were oppositely arranged, a quantum dot luminescent layer arranged between the anode and the cathode, an HTL arranged between the anode and the quantum dot luminescent layer, an HIL arranged between the anode and the HTL, and an ETL between the quantum dot luminescent layer and the cathode. The anode was ITO (55 nm), the HIL was PEDOT:PSS (50 nm), the HTL was TFB (30 nm), the quantum dot luminescent layer was red quantum dots CdₓZn₁₋ₓSe/ZnSe (40 nm), the ETL was a ZnO material prepared by the following method, and the cathode was an Ag electrode (100 nm).

A preparation method of the QLED included the following steps:
the HIL, the HTL, and the quantum dot luminescent layer were sequentially prepared on the anode substrate;
the ETL was prepared on the quantum dot luminescent layer; and
a top electrode was evaporated or sputtered on the zinc oxide ETL or zinc oxide-doped ETL to obtain the QLED.

A preparation method of the ETL included the following steps:
(1): (A) zinc acetate was dissolved in butanol at room temperature to obtain a zinc salt solution with a concentration of 0.5 mol/L, and TMAH was dissolved in butanol at room temperature to obtain a alkaline solution with a concentration of 1 mol/L, where hydroxide ions and zinc ions were at a molar ratio of 2:1;
(B) the zinc salt solution was adjusted to 50° C., the alkaline solution was added dropwise into the zinc salt solution according to a molar ratio of hydroxide ions to zinc ions 2:1, and then an obtained mixed solution was continuously stirred for a reaction at 50° C. for 70 min;
(C) a precipitant was added at a volume ratio of 3:1 to a mixed solution obtained after the reaction, such that a white precipitate was formed in the mixed solution; and (D) the precipitate was washed 2 times with butanol as a reaction solvent, and an obtained white precipitate was dissolved to obtain a first zinc oxide colloidal solution at a concentration of 0.5 mol/L.

(2): (A) magnesium acetate and zinc acetate were dissolved in butanol at room temperature to obtain a mixed salt solution with a concentration of 0.5 mol/L, where a molar ratio of magnesium ions was 5%, and potassium hydroxide was dissolved in ethanol at room temperature to obtain a alkaline solution with a concentration of 1 mol/L;
the zinc salt solution was adjusted to 40° C., the alkaline solution was added dropwise into the zinc salt solution according to a molar ratio of hydroxide ions to zinc ions at 2:1, and then an obtained mixed solution was continuously stirred for a reaction at 40° C. for 90 min; (B) a precipitant was added at a volume ratio of 5:1 to a mixed solution obtained after the reaction, such that a white precipitate was formed in the mixed solution; and (C) the precipitate was washed 2 times with butanol, and an obtained white precipitate was dissolved to obtain a second 5% magnesium-doped zinc oxide colloidal solution with a concentration of 0.5 mol/L.

(3) the first zinc oxide colloidal solution was coated on the quantum dot luminescent layer, a solvent was removed to obtain a prefabricated zinc oxide film; 0.1 mmol/L hydrochloric acid was deposited on a surface of the prefabricated zinc oxide film, where 80 μL of the hydrochloric acid was used for each 5 mg of the prefabricated zinc oxide film for a reaction for 60 min at 70° C., a solvent was removed to obtain a first zinc oxide film with a surface hydroxyl content of 0.3; the second 5% magnesium-doped zinc oxide colloidal solution was deposited on the first zinc oxide film, a solvent was removed to obtain a second 5% magnesium-doped zinc oxide film with a surface hydroxyl content of 0.5; where
the first zinc oxide film had a thickness of 60 nm, and the second 5% magnesium-doped zinc oxide film had a thickness of 30 nm.

The hydroxyl groups in the first ETL and the second ETL were detected by XPS, and it was determined that the first ETL had a hydroxyl content of 0.3, and the second ETL had a hydroxyl content of 0.5.

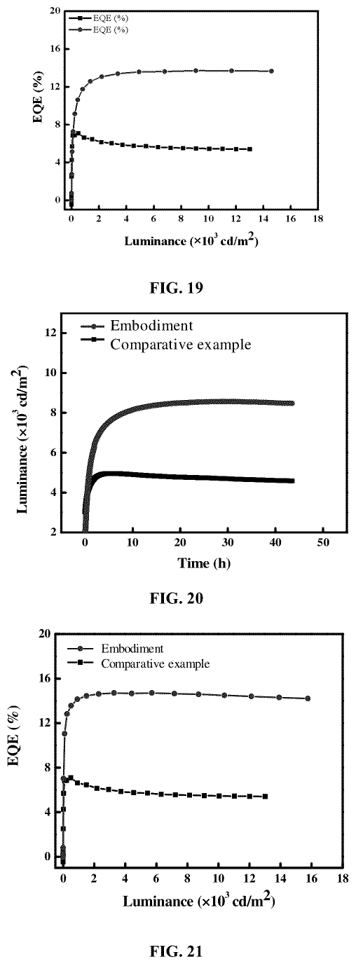

The QLEDs provided in Embodiment 4 and Comparative Example 1 had device EQE test results shown in FIG. 19 and service lifetime test results shown in FIG. 20.

### Embodiment 5

A QLED included an anode substrate and a cathode that were oppositely arranged, a quantum dot luminescent layer arranged between the anode and the cathode, an HTL arranged between the anode and the quantum dot luminescent layer, an HIL arranged between the anode and the HTL, and an ETL between the quantum dot luminescent layer and the cathode. The anode was ITO (55 nm), the HIL was PEDOT:PSS (50 nm), the HTL was TFB (30 nm), the quantum dot luminescent layer was red quantum dots CdₓZn₁₋ₓSe/ZnSe (40 nm), the ETL was a ZnO material prepared by the following method, and the cathode was an Ag electrode (100 nm).

A preparation method of the QLED included the following steps:
the HIL, the HTL, and the quantum dot luminescent layer were sequentially prepared on the anode substrate;
the ETL was prepared on the quantum dot luminescent layer; and
a top electrode was evaporated or sputtered on the zinc oxide ETL or zinc oxide-doped ETL to obtain the QLED.

A preparation method of the ETL included the following steps:

(1): (A) zinc sulfate was dissolved in butanol at room temperature to obtain a zinc salt solution with a concentration of 1 mol/L, and sodium hydroxide was dissolved in ethanol at room temperature to obtain a alkaline solution with a concentration of 1.5 mol/L, where hydroxide ions and zinc ions were at a molar ratio of 1.5:1;
(B) the zinc salt solution was adjusted to 60° C., the alkaline solution was added dropwise into the zinc salt solution according to a molar ratio of hydroxide ions to zinc 1.5:1, and then an obtained mixed solution was continuously stirred for a reaction at 60° C. for 60 min;
(C) a precipitant was added at a volume ratio of 4:1 to a mixed solution obtained after the reaction, such that a white precipitate was formed in the mixed solution; and (D) the precipitate was washed 2 times with ethanol as a reaction solvent, and an obtained white precipitate was dissolved to obtain a first zinc oxide colloidal solution at a concentration of 0.75 mol/L.

(2): (A) yttrium sulfate and zinc sulfate were dissolved in butanol at room temperature to obtain a mixed salt solution with a concentration of 1 mol/L, where a molar ratio of yttrium ions was 10%, and potassium hydroxide was dissolved in ethanol at room temperature to obtain a alkaline solution with a concentration of 2 mol/L; the zinc salt solution was adjusted to 50° C., the alkaline solution was added dropwise into the zinc salt solution according to a molar ratio of hydroxide ions to zinc ions at 2:1, and then an obtained mixed solution was continuously stirred for a reaction at 50° C. for 90 min; (B) a precipitant was added at a volume ratio of 4:1 to a mixed solution obtained after the reaction, such that a white precipitate was formed in the mixed solution; and (C) the precipitate was washed 2 times with ethanol, and an obtained white precipitate was dissolved to obtain a second 10% yttrium-doped zinc oxide colloidal solution with a concentration of 0.75 mol/L.

(3) the first zinc oxide colloidal solution was coated on the quantum dot luminescent layer, a solvent was removed to obtain a prefabricated zinc oxide film; 0.075 mmol/L nitric acid was deposited on a surface of the prefabricated zinc oxide film, and 100 μL of the nitric acid was used for each 5 mg of the prefabricated zinc oxide film for a reaction for 90 min at 80° C., a solvent was removed to obtain a first zinc oxide film with a surface hydroxyl content of 0.35; the second 10% yttrium-doped zinc oxide colloidal solution was deposited on the first zinc oxide film, a solvent was removed to obtain a second 10% yttrium-doped zinc oxide film with a surface hydroxyl content of 0.75; where
the first zinc oxide film had a thickness of 70 nm, and the second 10% yttrium-doped zinc oxide film had a thickness of 15 nm.

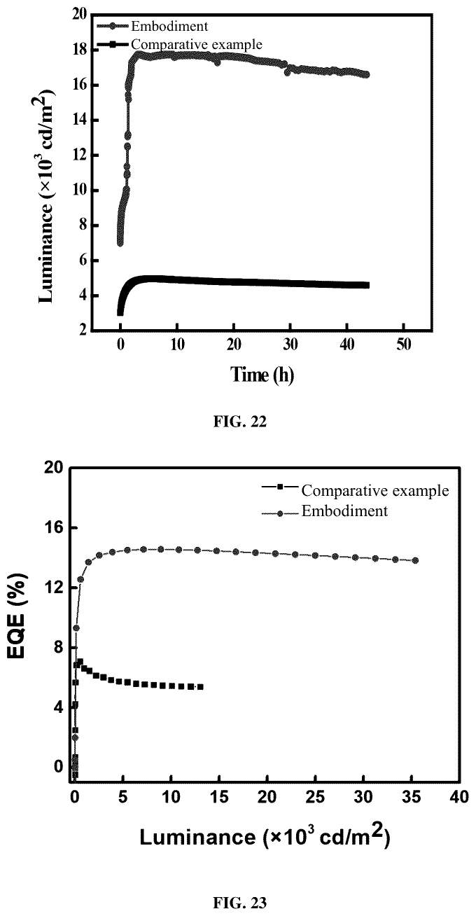

The hydroxyl groups in the zinc oxide colloidal solution or zinc oxide solution of the first ETL, the second ETL, and the third ETL were detected by XPS, and it was determined that the first ETL had a hydroxyl content of 0.35, the second ETL had a hydroxyl content of 0.35, and the third ETL had a hydroxyl content of 0.75. The QLEDs provided in Embodiment 5 and Comparative Example 1 had device EQE test results shown in FIG. 21 and service lifetime test results shown in FIG. 22.

### Embodiment 6

A QLED included an anode substrate and a cathode that were oppositely arranged, a quantum dot luminescent layer arranged between the anode and the cathode, an HTL arranged between the anode and the quantum dot luminescent layer, an HIL arranged between the anode and the HTL, and an ETL between the quantum dot luminescent layer and the cathode. The anode was ITO (55 nm), the HIL was PEDOT:PSS (50 nm), the HTL was TFB (30 nm), the quantum dot luminescent layer was red quantum dots CdₓZn₁₋ₓSe/ZnSe (40 nm), the ETL was a ZnO material prepared by the following method, and the cathode was an Ag electrode (100 nm).

A preparation method of the QLED included the following steps:
the HIL, the HTL, and the quantum dot luminescent layer were sequentially prepared on the anode substrate;
the ETL was prepared on the quantum dot luminescent layer; and
a top electrode was evaporated or sputtered on the zinc oxide ETL or zinc oxide-doped ETL to obtain the QLED.

A preparation method of the ETL included the following steps:

(1): (A) zinc acetate was dissolved in DMSO at room temperature to obtain a zinc salt solution with a concentration of 0.5 mol/L, and sodium hydroxide was dissolved in methanol at room temperature to obtain a alkaline solution with a concentration of 0.85 mol/L, where hydroxide ions and zinc ions were at a molar ratio of 1.7:1;
(B) the zinc salt solution was adjusted to 60° C., the alkaline solution was added dropwise into the zinc salt solution according to a molar ratio of hydroxide ions to zinc ions 1.7:1, and then an obtained mixed solution was continuously stirred for a reaction at 60° C. for 90 min;
(C) a precipitant was added at a volume ratio of 4:1 to a mixed solution obtained after the reaction, such that a white precipitate was formed in the mixed solution; and (D) the precipitate was washed 3 times with methanol as a reaction solvent, and an obtained white precipitate was dissolved to obtain a first zinc oxide colloidal solution with a surface hydroxyl content of 0.15.

(2): (A) zinc acetate was dissolved in DMSO at room temperature to obtain a zinc salt solution with a concentration of 0.5 mol/L, and sodium hydroxide was dissolved in methanol at room temperature to obtain a alkaline solution with a concentration of 0.85 mol/L, where hydroxide ions and zinc ions were at a molar ratio of 1.9:1;
(B) the zinc salt solution was adjusted to 60° C., the alkaline solution was added dropwise into the zinc salt solution according to a molar ratio of hydroxide ions to zinc ions 1.7:1, and then an obtained mixed solution was continuously stirred for a reaction at 60° C. for 90 min;
(C) a precipitant was added at a volume ratio of 3:1 to a mixed solution obtained after the reaction, such that a white precipitate was formed in the mixed solution; and
(D) the white precipitate was dissolved, and 0.3 mol/L TMAH was added to the zinc oxide colloidal solution to adjust a pH value to 8, to obtain a second zinc oxide colloidal solution with a hydroxyl content of 0.70.

(3): (A) zinc acetate was dissolved in DMSO at room temperature to obtain a zinc salt solution with a concentration of 0.5 mol/L, and sodium hydroxide was dissolved in methanol at room temperature to obtain a alkaline solution with a concentration of 0.85 mol/L, where hydroxide ions and zinc ions were at a molar ratio of 1.9:1;
(B) the zinc salt solution was adjusted to 60° C., the alkaline solution was added dropwise into the zinc salt solution according to a molar ratio of hydroxide ions to zinc ions 1.7:1, and then an obtained mixed solution was continuously stirred for a reaction at 60° C. for 90 min;
(C) a precipitant was added at a volume ratio of 4:1 to a mixed solution obtained after the reaction, such that a white precipitate was formed in the mixed solution; and
(D) the white precipitate was dissolved, and 0.1 mol/L sulfuric acid was added to the zinc oxide colloidal solution to adjust a pH value to 7.5, to obtain a third zinc oxide colloidal solution with a hydroxyl content of 0.35.

(4) the first zinc oxide colloidal solution was coated on the quantum dot luminescent layer, a solvent was removed to obtain a first zinc oxide film with a surface hydroxyl content of 0.15; the second zinc oxide colloidal solution was coated on the first zinc oxide film, a solvent was removed to obtain a second zinc oxide film with a surface hydroxyl content of 0.70; the third zinc oxide colloidal solution was coated on the second zinc oxide film, a solvent was removed to obtain a third zinc oxide film with a surface hydroxyl content of 0.35. The first zinc oxide layer had a thickness of 60 nm, the second zinc oxide layer had a thickness of 30 nm, and the third zinc oxide layer had a thickness of 60 nm.

The hydroxyl groups in the zinc oxide colloidal solution or zinc oxide solution of the first ETL, the second ETL, and the third ETL were detected by XPS, and it was determined that the first ETL had a hydroxyl content of 0.15, the second ETL had a hydroxyl content of 0.70, and the third ETL had a hydroxyl content of 0.35.

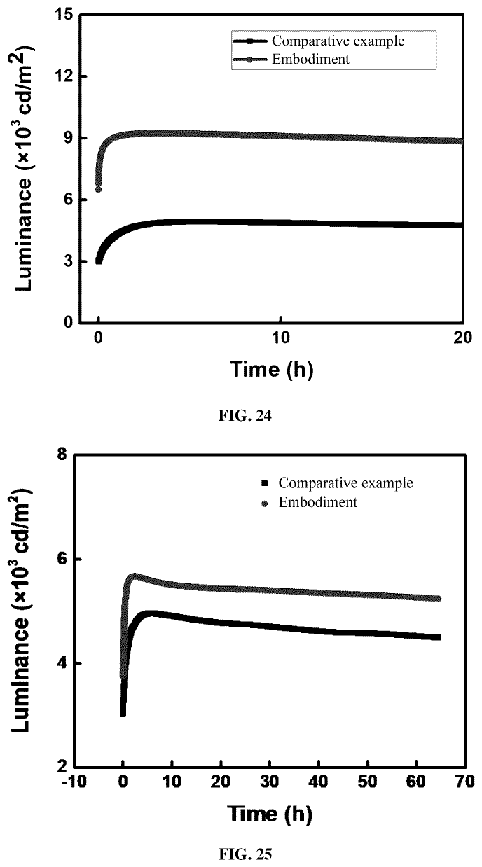

The QLEDs provided in Embodiment 6 and Comparative Example 1 had device EQE test results shown in FIG. 23 and service lifetime test results shown in FIG. 24.

Performance tests were conducted on the QLEDs provided in the above six embodiments and one comparative example, and the test results were shown in Table 2:

TABLE 2

| Sample | EQE (%) | Service life T95@ 1000 nit (h) | ${R}_{OH} = \frac{{A}_{OH}}{{A}_{MO}}$ |
|---|---|---|---|
| Embodiment 1 | | 1403.27 | 0.3 |
| Comparative | 7.09 | 237 | 0.5 |
| Example 1 | | | |
| Embodiment 2 | 12.65 | 2229.78 | |
| Embodiment 3 | 16.46 | 1487 | |
| Embodiment 4 | 13.69 | 2590.08 | |
| Embodiment 5 | 14.4 | 2233.85 | |
| Embodiment 6 | 15.39 | 1250 | |

It should be understood that the service life testing of QLED-based devices was different from the efficiency characterization of QLED-based devices, and the duration of device efficiency testing was generally shorter. Therefore, it was the initial transient state of QLED-based devices that was characterized. The service life of the device was characterized by an ability to maintain an efficiency of the device after the device continued to work and entered a stable state, namely the balance of carrier injection in the device after entering a stable operation state.

### Embodiment 7

A QLED included an anode substrate and a cathode that were oppositely arranged, a quantum dot luminescent layer arranged between the anode and the cathode, an HTL arranged between the anode and the quantum dot luminescent layer, an HIL arranged between the anode and the HTL, and an ETL between the quantum dot luminescent layer and the cathode. The anode was ITO (55 nm), the HIL was PEDOT:PSS (50 nm), the HTL was TFB (30 nm), the quantum dot luminescent layer was red quantum dots CdₓZn₁₋ₓSe/ZnSe (40 nm), the ETL was a ZnO material (50 nm) prepared by the following method, and the cathode was an Ag electrode (100 nm).

A preparation method of the QLED included the following steps:
the HIL, the HTL, and the quantum dot luminescent layer were sequentially prepared on the anode substrate;
the ETL was prepared on the quantum dot luminescent layer; and
a top electrode was evaporated or sputtered on the zinc oxide ETL or zinc oxide-doped ETL to obtain the QLED.

A preparation method of the ETL included the following steps:

(1): (A) zinc acetate dihydrate was dissolved in DMSO at room temperature to obtain a zinc salt solution with a concentration of 0.4 mol/L, and potassium hydroxide was dissolved in isopropanol at room temperature to obtain a alkaline solution with a concentration of 0.7 mol/L, where hydroxide ions and zinc ions were at a molar ratio of 1.75:1;
(B) the zinc salt solution was adjusted to 40° C., the alkaline solution was added dropwise into the zinc salt solution according to a molar ratio of hydroxide ions to zinc ions 1.75:1, a butylamine solution (0.4 mol/L) was added, such that a butylamine ligand added met that the butylamine ligand and a zinc salt in the zinc salt solution were at a molar ratio of 5:1, and then an obtained mixed solution was continuously stirred for a reaction at 40° C. for 120 min;
(C) a precipitant was added at a volume ratio of 5:1 to a mixed solution obtained after the reaction, such that a white precipitate was formed in the mixed solution; and
(D) the white precipitate was dissolved to obtain a zinc oxide colloidal solution at a concentration of 0.6 mol/L.

(2) The zinc oxide colloidal solution was coated on the quantum dot luminescent layer, and dried at 100° C. to obtain a zinc oxide film with a thickness of 50 nm, namely the ETL.

### Comparative Example 2

This comparative example differed from Embodiment 7 in that commercially-available ordinary zinc oxide nanoparticles were used as the ETL material.

FIG. 25 showed a lifetime test result of QLED-based devices provided by Embodiment 7 and Comparative Example 2.

### Embodiment 8

A QLED included an anode substrate and a cathode that were oppositely arranged, a quantum dot luminescent layer arranged between the anode and the cathode, an HTL arranged between the anode and the quantum dot luminescent layer, an HIL arranged between the anode and the HTL, and an ETL between the quantum dot luminescent layer and the cathode. The anode was ITO (55 nm), the HIL was PEDOT:PSS (50 nm), the HTL was TFB (30 nm), the quantum dot luminescent layer was red quantum dots CdₓZn₁₋ₓSe/ZnSe (40 nm), the ETL was a ZnO material prepared by the following method, and the cathode was an Ag electrode (100 nm).

A preparation method of the QLED included the following steps:
the HIL, the HTL, and the quantum dot luminescent layer were sequentially prepared on the anode substrate;
the ETL was prepared on the quantum dot luminescent layer; and
a top electrode was evaporated or sputtered on the zinc oxide ETL or zinc oxide-doped ETL to obtain the QLED.

A preparation method of the ETL included the following steps:

(1): (A) zinc acetate dihydrate was dissolved in DMSO at room temperature to obtain a zinc salt solution with a concentration of 0.4 mol/L, and potassium hydroxide was dissolved in isopropanol at room temperature to obtain a alkaline solution with a concentration of 0.7 mol/L, where hydroxide ions and zinc ions were at a molar ratio of 1.75:1;
(B) the zinc salt solution was adjusted to 40° C., the alkaline solution was added dropwise into the zinc salt solution according to a molar ratio of hydroxide ions to zinc ions 1.75:1, butyric acid (0.4 mol/L) was added, such that a butyric acid ligand added met that the butyric acid ligand and a zinc salt in the zinc salt solution were at a molar ratio of 7:1, and then an obtained mixed solution was continuously stirred for a reaction at 40° C. for 120 min;
(C) a precipitant was added at a volume ratio of 5:1 to a mixed solution obtained after the reaction, such that a white precipitate was formed in the mixed solution; and
(D) the white precipitate was dissolved to obtain a zinc oxide colloidal solution at a concentration of 0.6 mol/L.

(2) The zinc oxide colloidal solution was coated on the quantum dot luminescent layer, and dried at 100° C. to obtain a zinc oxide film with a thickness of 50 nm, namely the ETL.

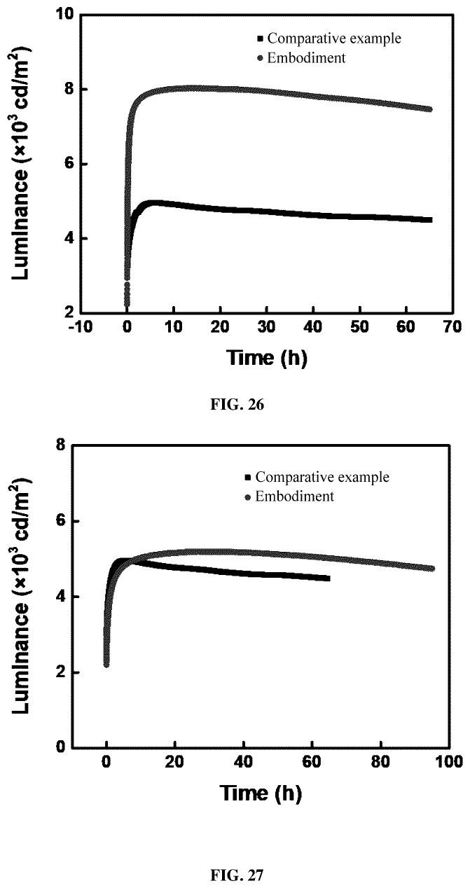

FIG. 26 showed a lifetime test result of QLED-based devices provided by Embodiment 8 and Comparative Example 2.

### Embodiment 9

A QLED included an anode substrate and a cathode that were oppositely arranged, a quantum dot luminescent layer arranged between the anode and the cathode, an HTL arranged between the anode and the quantum dot luminescent layer, an HIL arranged between the anode and the HTL, and an ETL between the quantum dot luminescent layer and the cathode. The anode was ITO (55 nm), the HIL was PEDOT:PSS (50 nm), the HTL was TFB (30 nm), the quantum dot luminescent layer was red quantum dots CdₓZn₁₋ₓSe/ZnSe (40 nm), the ETL was a ZnO material prepared by the following method, and the cathode was an Ag electrode (100 nm).

A preparation method of the QLED included the following steps:
the HIL, the HTL, and the quantum dot luminescent layer were sequentially prepared on the anode substrate;
the ETL was prepared on the quantum dot luminescent layer; and
a top electrode was evaporated or sputtered on the zinc oxide ETL or zinc oxide-doped ETL to obtain the QLED.

A preparation method of the ETL included the following steps:

(1): (A) zinc acetate dihydrate was dissolved in DMSO at room temperature to obtain a zinc salt solution with a concentration of 0.5 mol/L, and potassium hydroxide was dissolved in isopropanol at room temperature to obtain a alkaline solution with a concentration of 0.9 mol/L, where hydroxide ions and zinc ions were at a molar ratio of 1.8:1;
(B) the zinc salt solution was adjusted to 40° C., the alkaline solution was added dropwise into the zinc salt solution according to a molar ratio of hydroxide ions to zinc ions 1.8:1, and then an obtained mixed solution was continuously stirred for a reaction at 30° C. for 80 min;
(C) a precipitant was added at a volume ratio of 4:1 to a mixed solution obtained after the reaction, such that a white precipitate was formed in the mixed solution; and
(D) the white precipitate was dissolved to obtain a zinc oxide colloidal solution at a concentration of 0.6 mol/L.

(2) the first zinc oxide colloidal solution was coated on the quantum dot luminescent layer, a solvent was removed to obtain a prefabricated zinc oxide film; a propylamine solution (0.4 mol/L) was deposited on a surface of the prefabricated zinc oxide film, where 25 μL of the propylamine ligand solution was used for each 5 mg of the prefabricated zinc oxide film for a reaction for 20 min at 120° C., a solvent was removed to obtain a zinc oxide film with a thickness of 60 nm, namely the ETL.

FIG. 27 showed a lifetime test result of QLED-based devices provided by Embodiment 9 and Comparative Example 2.

### Embodiment 10

A QLED included an anode substrate and a cathode that were oppositely arranged, a quantum dot luminescent layer arranged between the anode and the cathode, an HTL arranged between the anode and the quantum dot luminescent layer, an HIL arranged between the anode and the HTL, and an ETL between the quantum dot luminescent layer and the cathode. The anode was ITO (55 nm), the HIL was PEDOT:PSS (50 nm), the HTL was TFB (30 nm), the quantum dot luminescent layer was red quantum dots CdₓZn₁₋ₓSe/ZnSe (40 nm), the ETL was a ZnO material prepared by the following method, and the cathode was an Ag electrode (100 nm).

A preparation method of the QLED included the following steps:
the HIL, the HTL, and the quantum dot luminescent layer were sequentially prepared on the anode substrate;
the ETL was prepared on the quantum dot luminescent layer; and
a top electrode was evaporated or sputtered on the zinc oxide ETL or zinc oxide-doped ETL to obtain the QLED.

A preparation method of the ETL included the following steps:

(1): (A) zinc acetate dihydrate was dissolved in DMSO at room temperature to obtain a zinc salt solution with a concentration of 0.5 mol/L, and potassium hydroxide was dissolved in isopropanol at room temperature to obtain a alkaline solution with a concentration of 0.9 mol/L, where hydroxide ions and zinc ions were at a molar ratio of 1.8:1;
(B) the zinc salt solution was adjusted to 40° C., the alkaline solution was added dropwise into the zinc salt solution according to a molar ratio of hydroxide ions to zinc ions 1.8:1, and then an obtained mixed solution was continuously stirred for a reaction at 30° C. for 80 min;
(C) a precipitant was added at a volume ratio of 4:1 to a mixed solution obtained after the reaction, such that a white precipitate was formed in the mixed solution; and
(D) the white precipitate was dissolved to obtain a zinc oxide colloidal solution at a concentration of 0.6 mol/L.

(2) the first zinc oxide colloidal solution was coated on the quantum dot luminescent layer, a solvent was removed to obtain a prefabricated zinc oxide film; a propionic acid solution (0.4 mol/L) was deposited on a surface of the prefabricated zinc oxide film, where 25 μL of the propionic acid ligand solution was used for each 5 mg of the prefabricated zinc oxide film for a reaction for 20 min at 120° C., a solvent was removed to obtain a zinc oxide film with a thickness of 60 nm, namely the ETL.

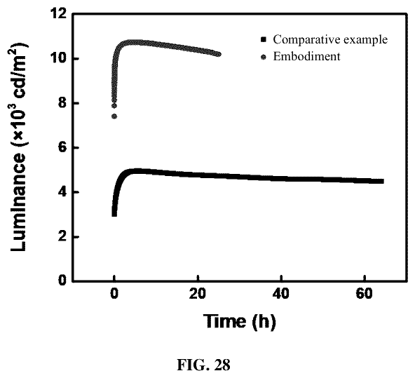

FIG. 28 showed a lifetime test result of QLED-based devices provided by Embodiment 10 and Comparative Example 2.

The QLEDs provided in Embodiments 7 to 10 and Comparative Example 2 were subjected to a device service life performance test. The test adopted a QLED life test system, and details were as mentioned above, and were not repeated here.

The test results of the QLEDs provided by Embodiments 7 to 10 and Comparative Example 2 were shown in Table 3:

TABLE 3

| Sample | Service life T95@1000 nit (h) |
|---|---|
| Embodiment 7 | 893.45 |
| Comparative Example 2 | 250.75 |
| Embodiment 8 | 1925.07 |
| Embodiment 9 | 865.11 |
| Embodiment 10 | 950.81 |

It should be understood that the service life testing of QLED-based devices was different from the efficiency characterization of QLED-based devices, and the duration of device efficiency testing was generally shorter. Therefore, it was an initial transient state of the QLED-based devices that was characterized. The service life of the device was characterized by an ability to maintain an efficiency of the device after the device continued to operate and entered a stable state, namely the balance of carrier injection in the device after entering a stable operation state.

The foregoing merely includes preferable examples of the present application, and is not intended to limit the present application. Any modification, equivalent substitution and improvement which are made without departing from the spirit and principle of the present application should all be included within the protection scope of the present application.

What is claimed is:

1. A quantum dot light-emitting diode (QLED), comprising an anode and a cathode that are oppositely arranged, a quantum dot luminescent layer arranged between the anode and the cathode, and an electron transport layer (ETL) arranged between the quantum dot luminescent layer and the cathode; wherein
the ETL comprises a first ETL, and the first ETL is a zinc oxide film with a surface hydroxyl content of less than or equal to 0.4; or alternatively,
the ETL comprises zinc oxide, and at least a part of a surface of the zinc oxide comprises amino ligands and/or carboxyl ligands with 3 to 7 carbon atoms.

2. The QLED according to claim 1, wherein the ETL comprises the first ETL having the zinc oxide, and a surface of the zinc oxide forming the first ETL comprises the amino ligands and/or the carboxyl ligands with 3 to 7 carbon atoms.

3. The QLED according to claim 1, wherein the ETL is the first ETL, and the zinc oxide in the first ETL is metal-doped or metal-undoped zinc oxide.

4. The QLED according to claim 1, wherein the ETL further comprises a second ETL; the second ETL is arranged on a surface of one side of the first ETL adjacent to the cathode or the quantum dot luminescent layer; and the second ETL is a zinc oxide film or a metal-doped zinc oxide layer with a surface hydroxyl content of greater than or equal to 0.6.

5. The QLED according to claim 4, wherein the ETL comprises the first ETL and the second ETL, and the first ETL is closer to the quantum dot luminescent layer than the second ETL.

6. The QLED according to claim 4, wherein the ETL comprises n film lamination units, each of the film lamination units comprises the first ETL and the second ETL, and n is greater than or equal to 2.

7. The QLED according to claim 4, wherein the ETL further comprises a third ETL.

8. The QLED according to claim 7, wherein the third ETL is the zinc oxide film with the surface hydroxyl content of less than or equal to 0.4.

9. (canceled)

10. The QLED according to claim 7, wherein the third ETL is a zinc oxide film with a surface hydroxyl content of greater than or equal to 0.6.

11. (canceled)

12. The QLED according to claim 7, wherein the third ETL is a metal-doped zinc oxide film.

13-22. (canceled)

23. A preparation method of a QLED, wherein the QLED comprises an anode and a cathode that are oppositely arranged, a quantum dot luminescent layer arranged between the anode and the cathode, and an electron transport layer (ETL) arranged between the quantum dot luminescent layer and the cathode; the ETL comprises a first ETL, and the first ETL is a zinc oxide film with a surface hydroxyl content of less than or equal to 0.4; and
a preparation method of the zinc oxide film with the surface hydroxyl content of less than or equal to 0.4 comprises the following steps:
mixing a zinc salt solution with a alkaline solution for a reaction, adding a precipitant into a mixed solution after the reaction, and collecting a precipitate; cleaning the precipitate using a reaction solvent twice or more than twice, and dissolving an obtained white precipitate to obtain a zinc oxide colloidal solution; and
coating the zinc oxide colloidal solution on a prefabricated substrate for preparing the zinc oxide film with the surface hydroxyl content of less than or equal to 0.4, and removing a solvent to obtain the zinc oxide film with the surface hydroxyl content of less than or equal to 0.4.

24. The preparation method of the QLED according to claim 23, wherein an alkali in the alkaline solution has a K_{b} value of greater than 10⁻¹, and the cleaning is conducted at least 3 times.

25. The preparation method of the QLED according to claim 24, wherein the alkali having a K_{b} value of greater than 10⁻¹ is selected from at least one of potassium hydroxide, sodium hydroxide, and lithium hydroxide; and the alkali having a K_{b} value of less than 10⁻¹ is selected from at least one of tetramethylammonium hydroxide (TMAH), ammonia water, ethanolamine, and ethylenediamine.

26. The preparation method of the QLED according to claim 23, wherein the reaction solvent is selected from at least one of water, an organic alcohol, an organic ether, and a sulfone.

27. The preparation method of the QLED according to claim 26, wherein the reaction solvent is selected from at least one of water, methanol, ethanol, propanol, butanol, ethylene glycol, 2-methoxyethanol, and dimethylsulfoxide (DMSO).

28. The preparation method of the QLED according to claim 27, wherein the zinc salt solution is mixed with the alkaline solution according to a molar ratio of hydroxide ions to zinc ions ranging from 1.5:1 to 2.5:1.

29. A preparation method of a QLED, wherein the QLED comprises an anode and a cathode that are oppositely arranged, a quantum dot luminescent layer arranged between the anode and the cathode, and an ETL arranged between the quantum dot luminescent layer and the cathode; the ETL comprises a first ETL, and the first ETL is a zinc oxide film with a surface hydroxyl content of less than or equal to 0.4; and
a preparation method of the zinc oxide film with the surface hydroxyl content of less than or equal to 0.4 comprises the following steps:
mixing a zinc salt solution with a alkaline solution for a reaction, to obtain zinc oxide nanoparticles; dissolving the zinc oxide nanoparticles to obtain a zinc oxide colloidal solution;
adding an acid solution to the zinc oxide colloidal solution to adjust a pH value of the zinc oxide colloidal solution to 7 to 8, thereby obtaining a zinc oxide solution; and
coating the zinc oxide solution on a prefabricated substrate for preparing the zinc oxide film with the surface hydroxyl content of less than or equal to 0.4, and removing a solvent to obtain the zinc oxide film with the surface hydroxyl content of less than or equal to 0.4.

30. The preparation method of the QLED according to claim 29, wherein during the step of adding the acid solution to the zinc oxide colloidal solution to adjust the pH value of the zinc oxide colloidal solution to 7 to 8, the acid solution is added to the zinc oxide colloidal solution to obtain a mixed solution with a pH value of 7.2 to 7.8.

31. The preparation method of the QLED according to claim 30, wherein during the step of adding the acid solution to the zinc oxide colloidal solution to adjust the pH value of the zinc oxide colloidal solution to 7 to 8, the acid solution is added to the zinc oxide colloidal solution to obtain a mixed solution with a pH value of 7.3 to 7.6.

32. The preparation method of the QLED according to claim 31, wherein an acid in the acid solution is selected from at least one of hydrochloric acid, sulfuric acid, nitric acid, hydrofluoric acid, formic acid, acetic acid, propionic acid, oxalic acid, and acrylic acid.

33-65. (canceled)
